(19) United States
(12) Patent Application Publication
(10) Pub. No.: US 2015/0244619 A1
(43) Pub. Date: Aug. 27, 2015

(54) COMMUNICATION METHODS AND COMMUNICATION DEVICES

(71) Applicant: AGENCY FOR SCIENCE, TECHNOLOGY AND RESEARCH, Singapore (SG)

(72) Inventors: Shoukang Zheng, Singapore (SG); Zhongding Lei, Singapore (SG); Haiguang Wang, Singapore (SG)

(73) Assignee: Agency for Science, Technology and Research, Singapore (SG)

(21) Appl. No.: 14/427,690

(22) PCT Filed: Sep. 12, 2013
(86) PCT No.: PCT/SG2013/000400

§ 371 Date: Mar. 12, 2015

(30) Foreign Application Priority Data
Sep. 12, 2012 (SG) 201206797-1
Oct. 15, 2012 (SG) 201207676-6
Nov. 9, 2012 (SG) 201208310-1
Dec. 12, 2012 (SG) 201209132-8
Mar. 13, 2013 (SG) 201301863-5
May 10, 2013 (SG) 201303655-3
Sep. 9, 2013 (SG) 201306776-4

(51) Int. Cl. H04L 12/741; H04L 12/26; H04L 5/00; H04L 29/08; H04L 12/801; H04L 29/06

(52) U.S. Cl. CPC H04L 45/74; H04L 47/10; H04L 69/22; H04L 5/0055; H04L 69/323; H04L 43/10

(57) ABSTRACT

According to various embodiments, a communication method may be provided. The communication method may include: at least one of sending a data unit or receiving a data unit; wherein the data unit is a null-data packet (NDP) and includes at least a physical layer (PHY) header; wherein the PHY header includes a plurality of fields; and wherein the plurality of fields include a sub-type field with at least 3 bits indicating a NDP sub-type of the data unit.

### CROSS-REFERENCE TO RELATED APPLICATIONS

The present application claims the benefit of the Singapore Patent Application No. 201206797-1 filed on 12 Sep. 2012, the Singapore Patent Application No. 201207676-6 filed on 15 Oct. 2012, the Singapore Patent Application No. 201208310-1 filed on 9 Nov. 2012, the Singapore Patent Application No. 201209132-8 filed on 12 Dec. 2012, the Singapore Patent Application No. 201301863-5 filed on 13 Mar. 2013, the Singapore Patent Application No. 201303655-3 filed on 10 May 2013, and the Singapore Patent Application No. 201306776-4 filed on 9 Sep. 2013, the entire contents of which are incorporated herein by reference for all purposes.

### TECHNICAL FIELD

Embodiments relate generally to communication methods and communication devices.

### BACKGROUND

In wireless communication, a mobile station (which may for example be referred to as a station or STA) may communicate with an access point (AP). In this communication, data may be lost, so there may be a need for an acknowledgement of received data.

### SUMMARY

According to various embodiments, a communication method may be provided. The communication method may include: at least one of sending a data unit or receiving a data unit; wherein the data unit is a null-data packet (NDP) and includes at least a physical layer (PHY) header; wherein the PHY header includes a plurality of fields; and wherein the plurality of fields include a sub-type field with at least 3 bits indicating a NDP sub-type of the data unit.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments are described with reference to the following drawings, in which:

FIG. 1A shows a flow diagram illustration a communication method in accordance with an embodiment;

FIG. 1B shows a communication device in accordance with an embodiment;

FIG. 1C shows a flow diagram illustration a communication method in accordance with an embodiment;

FIG. 2 shows an illustration of a false Short Ack for NDP PS-Poll;

FIG. 3 shows an illustration of a false Short Ack for NDP PS-Poll with two APs;

FIG. 4 shows an illustration of an example of Bit-rotating and CRC Mask;

FIG. 5 shows an illustration of how false Short Ack may be avoided according to various embodiments;

FIG. 6 shows an illustration of the example of false short CTS as medium synchronization frame;

FIG. 7 shows an illustration of the example of false short CTS for medium synchronization frame and RTS/CTS;

FIG. 8 shows an illustration of an example of speed frame exchange using short Ack;

FIG. 9 shows a SIG field format for 1 MHz NDP MAC frame;

FIG. 10 shows a SIG field format for >=2 MHz NDP MAC frame;

FIG. 11 shows an illustration of one example of speed frame exchange using short Ack for STA with uplink/downlink data;

FIG. 12 shows an illustration of a false NDP ACK Case for Concurrent Transmissions of PS-Poll and NDP PS-Poll to an AP;

FIG. 13 shows an illustration of a false NDP ACK case for concurrent transmissions of PS-Poll and NDP PS-Poll to two Aps;

FIG. 14 shows an illustration of a false NDP ACK case for concurrent transmissions of NDP PS-Poll to two APs;

FIG. 15 shows an illustration with a station with UL and DL Data;

FIG. 16 shows an illustration with a station with UL and DL Data;

FIG. 17 shows an illustration of an example of the relay flow control indication according to various embodiments;

FIG. 18 shows an illustration of an example of an alternative option for relay flow control indication;

FIG. 19 shows an illustration of the Downlink TXOP sharing for two-hop Relay with Explicit ACK;

FIG. 20 shows an illustration of uplink TXOP sharing for two-hop Relay using NDP ACK according to various embodiments;

FIG. 21 shows an illustration of an example of EDCA TXOP Truncation for SF Using NDP ACK and CF-End;

FIG. 22 shows an illustration of an example of EDCA TXOP Truncation for SF Using NDP ACK;

FIG. 23 shows an illustration of an example of EDCA TXOP Truncation for SF Using ACK and CF-End;

FIG. 24 shows an illustration of an example of EDCA TXOP Truncation for SF Using ACK;

FIG. 25 shows an illustration of an example of speed frame exchange using NDP PS-Poll and NDP Modified ACK;

FIG. 26 shows an illustration of an example of speed frame exchange using normal frames;

FIG. 27 show an illustration of a STA n disassociated from AP if AP does not received any frame from STA;

FIG. 28 shows an illustration of AP restarting the timer for Max Idle Period if AP received a protected frame or unprotected frame with TA and RA in full MAC addresses format (48 bits) from STA;

FIG. 29 shows an illustration of STA n disassociated from AP if AP only receives unprotected frame with short MAC headers from it; and

FIG. 30 shows an illustration of an example procedure for Max Idle Period reset after AP receives a frame from an associated STA.

### DESCRIPTION

Embodiments described below in context of the devices are analogously valid for the respective methods, and vice versa. Furthermore, it will be understood that the embodiments described below may be combined, for example, a part of one embodiment may be combined with a part of another embodiment.

In this context, the communication device as described in this description may include a memory which is for example used in the processing carried out in the communication device. A memory used in the embodiments may be a volatile memory, for example a DRAM (Dynamic Random Access Memory) or a non-volatile memory, for example a PROM (Programmable Read Only Memory), an EPROM (Erasable PROM), EEPROM (Electrically Erasable PROM), or a flash memory, e.g., a floating gate memory, a charge trapping memory, an MRAM (Magnetoresistive Random Access Memory) or a PCRAM (Phase Change Random Access Memory).

In an embodiment, a “circuit” may be understood as any kind of a logic implementing entity, which may be special purpose circuitry or a processor executing software stored in a memory, firmware, or any combination thereof. Thus, in an embodiment, a “circuit” may be a hard-wired logic circuit or a programmable logic circuit such as a programmable processor, e.g. a microprocessor (e.g. a Complex Instruction Set Computer (CISC) processor or a Reduced Instruction Set Computer (RISC) processor). A “circuit” may also be a processor executing software, e.g. any kind of computer program, e.g. a computer program using a virtual machine code such as e.g. Java. Any other kind of implementation of the respective functions which will be described in more detail below may also be understood as a “circuit” in accordance with an alternative embodiment.

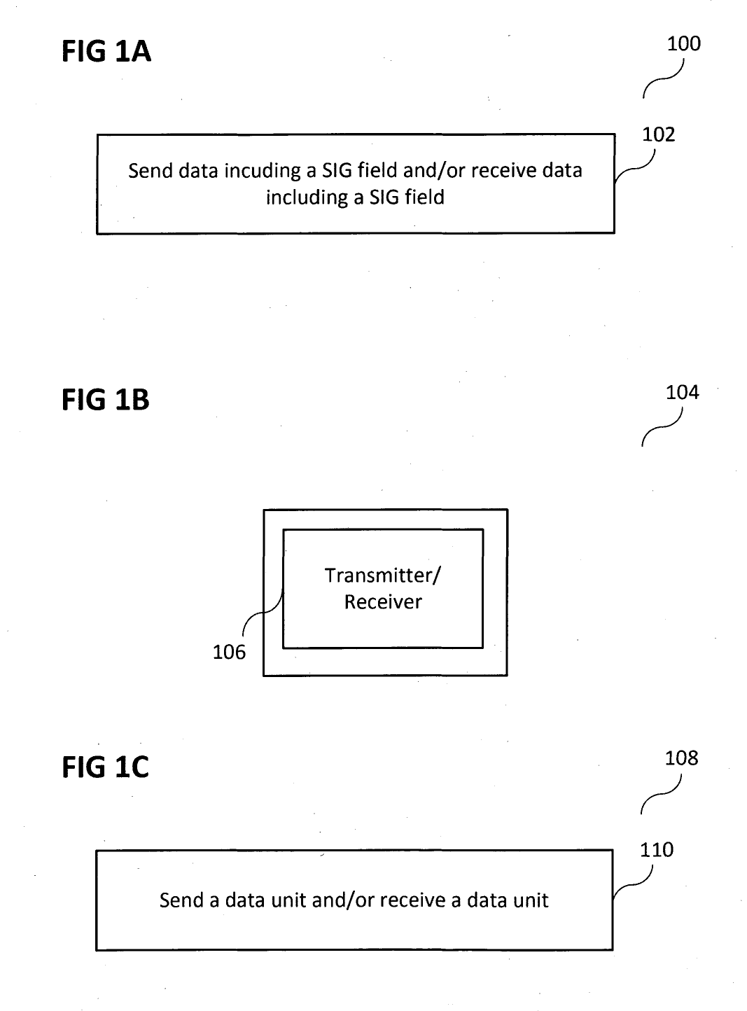

FIG. 1A shows a flow diagram 100 illustrating a communication method. In 102, data including a SIG field may be sent and/or data including a SIG field may be received. The SIG field may include an indication of a type of a null data packet, a null data packet acknowledgement and an identifier of the null data packet.

According to various embodiments, the null data packet acknowledgement may include or may be a null data packet acknowledgement for speed frame exchange or TXOP sharing.

According to various embodiments, the identifier may be determined based on at least one of a receiver address or a transmitter address.

According to various embodiments, the identifier may be determined based on a frame check sequence or cyclic redundancy check.

According to various embodiments, the identifier may be determined based on the bits of the PHY header of a received null data packet type PS-Poll frame to be acknowledged.

According to various embodiments, the identifier may be determined based on a bit-rotation.

According to various embodiments, the identifier may be determined based on a cyclic redundancy checksum mask.

According to various embodiments, the SIG field may include control information for flow control.

According to various embodiments, the SIG field may include duration indication information.

According to various embodiments, the SIG field may include a broadcast address indicator.

FIG. 1B shows a communication device 104 according to various embodiments. The communication device 104 may include a transmitter 106 configured to send data including a SIG field and/or a receiver 106 configured to receive data including a SIG field. The SIG field may include an indication of a type of a null data packet, a null data packet acknowledgement and an identifier of the null data packet.

According to various embodiments, the null data packet acknowledgement may include or may be a null data packet acknowledgement for speed frame exchange or TXOP sharing.

According to various embodiments, the identifier may be determined based on at least one of a receiver address or a transmitter address.

According to various embodiments, the identifier may be determined based on a frame check sequence or cyclic redundancy check.

According to various embodiments, the identifier may be determined based on the bits of the PHY header of a received null data packet type PS-Poll frame to be acknowledged.

According to various embodiments, the identifier may be determined based on a bit-rotation.

According to various embodiments, the identifier may be determined based on a cyclic redundancy checksum mask.

According to various embodiments, the SIG field may include control information for flow control.

According to various embodiments, the SIG field may include duration indication information.

According to various embodiments, the SIG field may include a broadcast address indicator.

FIG. 1C shows a flow diagram 108 illustrating a communication method according to various embodiments. In 110, a data unit may be sent or a data unit may be received. The data unit may be a null-data packet (NDP) (i.e. without MAC header and MAC body) and may include at least a physical layer (PHY) header. The PHY header may include or may be composed of a plurality of fields. The plurality of fields may include a sub-type field with at least 3 bits indicating a NDP sub-type of the data unit.

According to various embodiments, a NDP sub-type may refer to one of the following: NDP CTS, NDP PS-Poll, 1st type of NDP ACK, 2nd type of NDP ACK, NDP Block ACK, NDP beamforming report poll, NDP paging, and NDP probe request.

According to various embodiments, the data unit may either be a first type NDP ACK or second type NDP ACK and the PHY header also includes at least one of the following fields: ACK Identifier, More Data, Duration Indication, Duration, Relayed frame, or Flow Control.

According to various embodiments, the data unit may be a NDP ACK and the PHY header may also include all the following fields: ACK Identifier; More Data; Duration Indication; and Duration.

According to various embodiments, the data unit may be a NDP ACK and the PHY header may also include all the following fields: ACK Identifier; More Data; Duration Indication; Duration; Relayed frame.

According to various embodiments, the PHY header may include at least an ACK identifier that is determined based on at least one of the following information: a receiver address and/or a transmitter address (such an address could be a partial MAC address or partial AID); a frame check sequence or cyclic redundancy check of the frame that elicited the null data packet acknowledgement (for example, the computation method of ACK identifier based on cyclic redundancy check of the received frame is not just applicable to NDP PS-Poll; may be extended to the NDP response to any other NDP frame); or the bits of the PHY header of the received null data packet type PS-Poll frame that elicited the null data packet acknowledgement.

According to various embodiments, the receiver address or the transmitter address is either a full MAC address, a partial BSSID, or a partial AID.

According to various embodiments, the PHY header (for example only applied to first or second type of NDP ACK) may include a field comprising duration indication information (this field may be compulsory for a NDP ACK (which may be mandatory frame in 11ah); details for NDP ACK will be described further below).

According to various embodiments, the PHY header may include a field comprising duration information to indicate an inactivity period, when duration indication is a value of 0 or 1. The indication may be set to “0” to indicate “inactivity”. Then “1” may mean the duration is for NAV setting. Alternatively, the bits can be reversed to indicate the opposite.

According to various embodiments, the inactivity period may indicate the duration that there will be no transmission of the data units for the intended receiver.

According to various embodiments, the PHY header may include a field comprising duration information to indicate a duration for NAV setting, when duration indication is a value different from the value assigned to indicate an inactivity period.

According to various embodiments, the PHY header may include at least a field comprising the information to indicate the data unit is not a response frame for normal data unit or a null data packet type of PS-Poll. A normal data unit is a data unit that is not a null data packet. A null data packet is a PPDU without Data field. As the reserved cases can be applied to Duration Indication field set to 0 or 1 (two fields, i.e. Duration Indication and Duration, are involved). For example the reserved cases in Table 7 or 16 or 17 may be used as the response frame that is not the NDP ACK for normal data unit or NDP Modified ACK for NDP PS-Poll. For example, the NDP ACK with the Duration Indication field set to 0 and the Duration field set to 1 may be defined as e.g. a null data packet of CF-End for TXOP truncation.

According to various embodiments, the duration of the data unit may be set to protect at least the transmission of the response data unit, indicating that the data unit is followed by at least one long response data unit. This may provide processing for the case of when Duration Indication and Duration fields are not used for an indication of the response frame for e.g. No Response/Long Response. Instead, the Duration is used for NAV setting, which is more accurate than the indication of the response frame for No Response/Long Response. Therefore, if the station is able to set its NAV in the Duration field, it should do so. Otherwise it should set the indication of the response frame as Long Response if there is a response data unit. This may not just be applicable to Speed Frame Exchange and TXOP sharing.

According to various embodiments, the PHY header may include at least one field (The control information is based on 3 fields: Relayed Frame, Duration Indication and Duration fields) including control information for flow control. According to various embodiments, the mechanism may be applied to flow control in general.

According to various embodiments, at least one field may include the duration of no transmission data units for flow control. According to various embodiments, the control information may be based on 3 fields: Relayed Frame, Duration Indication and Duration fields.

According to various embodiments, the intended receiver may stop the transmission of data units to the transmitter of the data unit for a duration indicated in one field of the PHY header of the data unit.

According to various embodiments, the data may be a null data packet CTS and the PHY header may include an indication to indicate whether the data is from the access point AP. According to various embodiments, there may be one field (1 bit) that is used to identify whether the Short CTS is from its AP.

According to various embodiments, the PHY header may include an indication of a duration for a network allocation vector.

According to various embodiments, a nonzero valid duration of the data unit may be set to protect at least the transmission of the response data unit, indicating the duration of at least one response data unit.

According to various embodiments, a response data unit may be at least one of a null data packet ACK or a null data packet format of short response frame to null data type PS-Poll and its Duration field for NAV setting may protect the following transmission in one TXOP. This may apply to 1^{St} and 2^{nd} type NDP ACK.

In the following, short frames, for example for IEEE 802.11-based Networks, will be described. Examples of short frame are Short Ack (acknowledgement), Short CTS (clear to send), Short Block Ack, NDP (null data packet) type PS-Poll (power save poll), NDP probe request, NDP sounding, short beamforming report Poll frame and Short MAC (medium access control) header.

Active STAs (stations) with TIM (traffic indication map) bit on may be allowed to poll the AP after receiving the beacon with TIM. A low power/Non-TIM STA may be allowed to transmit PS-Poll to its associated AP (access point) after wakeup without listening to the beacon. Due to the fact that PS-Poll may be widely used for power saving and low power operation, short frame format of ACK and PS-Poll may improve transmission efficiency and reduces power consumption.

In the following, NDP Type Indication will be described.

According to various embodiments, methods to indicate the types of NDP frame in SIG may be provided. More than 8 NDP frames may be provided. Furthermore, a method to indicate the type of NDP frames may be provided.

SIG may mean SIGNAL field of PPDU (physical protocol data unit.

S1G PPDU (i.e. the PPDU format for 11ah) may include:
STF Short Training field;
LTF Long Training field;
SIG SIGNAL field;
SIG-A Signal A field;
D-STF Short Training field for data;
D-LTF Long Training field for data;
SIG-B Signal B field; and
Data.

The Data field may carry the PSDU(s) (Physical layer Service Data Unit).

The null data packet (NDP) may include:
STF Short Training field;
LTF Long Training field; and
SIG SIGNAL field.

The null data packet (NDP) frame has no Data field.

One of PPDU formats that includes PSDU could be:
STF Short Training field;
LTF Long Training field;
SIG SIGNAL field: and
Data.

The Data field may carry the PSDU(s).

For example, for 8 types of NDP frames, a 3-bit NDP-T (NDP Type) field within the SIG bits may be provided. When the AP/STA receives a NDP frame the AP/STA may proceed to obtain the NDP-T field to know the type of NDP frame. If there are more than 8 types (for example assuming less than 16 (in other words: <16)) of NDP frames, a 4-bit NDP-T field within SIG bits may be provided. However, some NDP type frames may have used up all the bits in the SIG and may not support 4-bit NDP-T field, e.g. NDP type PS-Poll uses up all the bits as shown in the following example (for example like illustrated in Table 1).

TABLE 1
Example of NDP Type PS-Poll SIG Design

| Field | Bit width | Comments |
|---|---|---|
| NDP Type Indication | 4 | |
| TA (transmitter address) | 9 | (partial) AID (association |
| | | identifier) |
| RA (receiver address) | 9 | (partial) BSSID (Basic Service |
| | | Set Identification) |
| Preferred MCS | 4 | |
| (Modulation and Coding | | |
| Scheme) | | |
| Tail bits | 6 | TBD (to be determined, for |
| | | example depending on group's |
| | | decision oh tail bit support) |
| CRC (cyclic redundancy | 4 | |
| check) | | |
| TOTAL | 36 | 2 MHz case, there are 12 |
| | | reserved bits |

According to various embodiments, the following options for NDP-T indication may be provided:

In Option 1, a re-design of the fields in NDP type frames may be provided so that 4-bit NDP-T field may be supported in all NDP type frames.

In Option 2, 3-bit NDP-T plus one extended reserved bit that can be accommodated in some NDP types may be used to differentiate more than 8 types of NDP frame, like will be described in more detail below.

In Option 3, some NDP types may not be supported for 1 MHz case, and may be defined 3-bit NDP-T for channel bandwidth equal to 1 MHz and 4-bit NDP-T for channel bandwidth greater or equal to 2 MHz, like will be described in more detail below.

According to various embodiments, for Option 2, 3-bit NDP-T and one extended bit may be used to indicate NDP types. For example, assuming short ACK/CTS has at least one reserved bit and one 3-bit value (e.g. 0b111) may be reserved to identify both short ACK and CTS. By extending one reserved bit (with the same position) in both short ACK and CTS as the extended type identification, it may be possible to determine whether it is a short ACK or short CTS.

According to various embodiments, the protocol to handle NDP-T Field in Option 2 may be as follows: If the AP/STA receives the NDP frames after identifying this NDP frame, the AP/STA may proceed to identify the NDP-T fields so that it can know which NDP type the received frame is. When AP/STA identifies that the NDP-T field value is the defined case for extended indication, it may check the reserved bit (used as extended type identification bit) to further determine which NDP type the frame is.

According to various embodiments, for Option 3, 3-bit NDP-T may be used for 1 MHz channel bandwidth and 4-bit NDP-T may be used for 2 MHz channel bandwidth.

In the 1 MHz case, e.g. NDP sounding may not be applicable. Then 3-bit NDP-T may not be required to cover NDP sounding case, which may mean the NDP-T field value for NDP sounding is not in the range of [0,7]. Assuming that there are 6 NDP types for 1 MHz case, the value 0-5 (0b000-0b101) may be used for 3-bit NDP-T.

In the 2 MHz case, NDP sounding and other NDP type frames that are not supported in 1 MHz may be differentiated with a 4-bit NDP-T value (e.g. large than 7). For example, if there are 2 NDP types (short beamforming report Poll frame and NDP sounding) only defined for 2 MHz case. The value 0-5 (0b000-0b101) may be used for 4-bit NDP-T to indicate 6 NDP types that is supported in 1 MHz case, and the value of (0b1000-0b1001) for 4-bit NDD-T to indicate 2 NDP types that are defined only for 2 MHz case.

According to various embodiments, the protocol to handle NDP-T Field in Option 3 may be as follows: If the AP/STA receives the NDP frames after identifying that it is a NDP frame, the AP/STA may determine that it is for 1 MHz or >=2 MHz channel and proceed to identify the NDP-T fields so that it can know which NDP type the received frame is. For 1 MHz channel, it may only be needed to check 3-bit NDP-T field. For channel bandwidth>=2 MHz, it may be needed to check 4-bit NDP-T field.

In the following, Short Ack for NDP Type PS-Poll according to various embodiments will be described. According to various embodiments, a design of short Ack for NDP type PS-Poll frame may be provided. Short Ack and NDP type PS-Poll may have been accepted into IEEE specification framework (IEEE 802.11-1137-10-00ah-specification-framework-for-tgah, Mingyong Park, “IEEE 802.11ah Specification Framework”). In Section R.4.4.2.1.A thereof, it is specified that the draft specification shall support the following short ACK format with SIG fields that are the same as those in normal SIG: CRC (4 bits) and Tail (6 bits—TBD), and the short ACK SIG shall include an ACK ID field (bits TBD) which use partial FCS and the information from the scrambling seed in the SERVICE field of the frame being acknowledged for the computation of the ACK ID for short ACK frames.

However, upon receiving NDP type PS-Poll frame from the STA, the AP may send a response frame to STA as follows:

(1) Normal DATA/ACK, which requires no change for the protocol;

(2) Short ACK, which requires some modification since there is a very short checksum of the received frame (CRC 4 bits for SIG) and no scrambling seed can be used to compute ACK ID field;

(3) Short Response Frame, which requires that a new rule/protocol shall be defined.

Hence, according to various embodiments, the following options may be provided:

In Option 1, the AP may respond to NDP type PS-Poll with normal ACK.

In Option 2, the AP may respond to NDP type PS-Poll with short ACK but with modification. ACK ID may be computed differently. It will be described in more detail below how to compute ACK ID according to various embodiments.

In Option 3, the AP may respond to NDP type PS-Poll with a new Short Response Frame.

More details on option 2 will be given in the following, where short Ack with modification will be described.

In the following, Short Ack SIG Design according to various embodiments will be described.

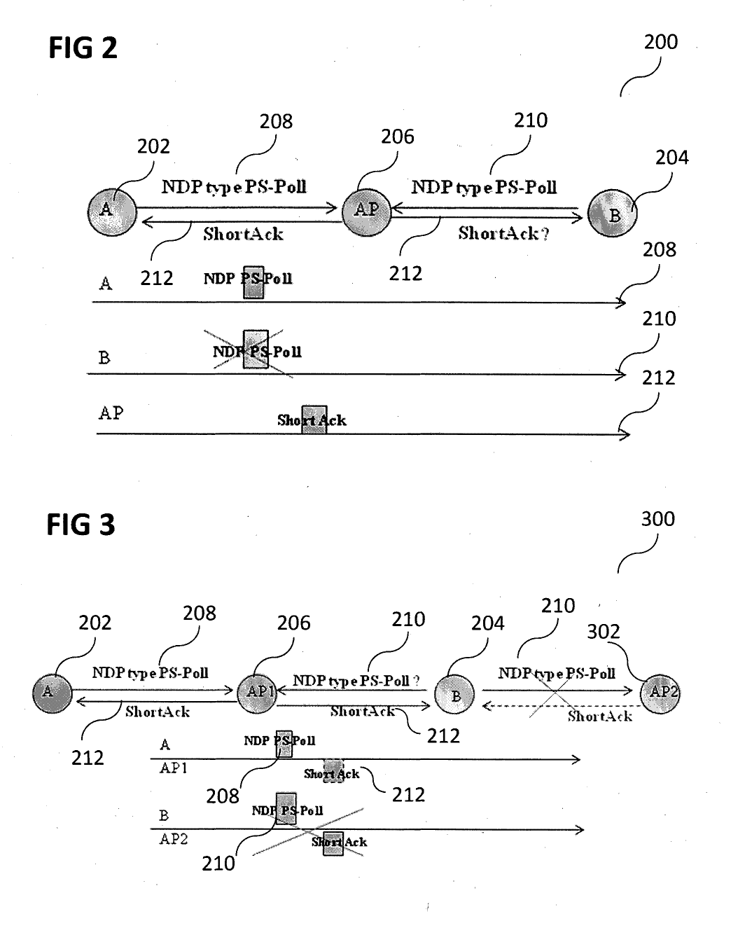

For example, an event that there are two concurrent transmissions of NDP type PS-Poll: A->AP (which for example may mean a transmission from STA A to AP) and B->AP (which for example may mean a transmission from STA B to AP) will be described. Both A and B may expect short Ack from AP. Suppose that AP can only receive a strong signal from A and respond to A's NDP PS-Poll with short Ack that can reach B. B receives AP's short Ack, which should carry identification of STA e.g. partial AID information in short response frame SIG so that the possibility of this false short Ack case should be zero. The example of such false short Ack occurs at one AP is shown in FIG. 2.

FIG. 2 shows an illustration 200 of a false Short Ack for NDP PS-Poll with one AP 206 and a first station 202 (STA A) and a second station 204 (STA B). FIG. 2 illustrates two concurrent transmissions of NDP type PS-Poll: A->AP1 208 (from the first station 202 to a first AP (which may also be referred to as AP1), for example the AP 206) and B->AP2 210 (from the second station 204 to a second AP which may also be referred to as AP2 and which is not shown in FIG. 2). A 202 may expect a short Ack from AP1 and B expects a short Ack from AP2. Suppose that AP1 206 responds to A's 202 NDP PS-Poll with short Ack that can reach B 204, but AP2 can't receive B's 204 NDP PS-Poll. B 204 receives AP1's 206 short Ack. If B 204 has a shorter transmission range when it sends NDP PS-Poll that may reach AP1 206, and AP1 206 may have a longer transmission range when it sends NDP short Ack 212 that can reach B 204, a false short Ack may occur if scrambled PBSSID (partial BSSID) and PAID (partial AID) bits in NDP PS-Poll frame are the same for A 202 and B 204. The possibility of this false short Ack case could be very low because it carries both AP and STA's identification and duplicate probability of same NDP PS-Poll's TA (e.g. scrambled PBSSID) bits may be low due to that B's transmission will likely corrupt A's transmission at AP1, or B's transmission range is long, or B may be able to detect if it can hear AP1's beacon frame. The example of such false short Ack occurs at two APs is shown in FIG. 3.

FIG. 3 shows an illustration 300 of a false Short Ack for NDP PS-Poll with two APs, for example the first access point AP1 206 and the second access point AP2 302. Various devices and signals shown in FIG. 3 are similar or identical to devices and signals shown in FIG. 2, for which the same reference signs may be used and duplicate description may be omitted.

The above examples show that including transmitter and receiver address/identification (for example to an ACK ID (identifier)) according to various embodiments may be helpful to avoid the false short Ack.

Following the same structure of short Ack for non-NDP type frames in Table 2, short Ack for NDP type PS-Poll may have the field ACK ID as the identifier for pairing frame exchange i.e. short Ack for NDP type PS-Poll frame.

TABLE 2
Example of NDP Type Short Ack SIG Design

| Field | Bit width | Comments |
|---|---|---|
| Message type | 4 | Unused MCS field in |
| indicator | | normal data packet |
| ACK ID | >=14? | Based on Partial FCS and |
| | 12 | Scramble Seed of received |
| | | frame |
| DURATION | 6-8 | May be required or may |
| | | not be required |
| More Data | 1 | |
| TBD | TBD | |
| Tail bits | 6 | TBD (Depending on |
| | | group's decision on tail bit |
| | | support) |
| CRC | 4 | |
| TOTAL | 36 | 2 MHz case, there are 12 |
| | | reserved bits |

However, the design of ACK ID may be different (for example different from the example as shown in Table 2), as will be described in more detail in the following.

When the AP uses short Ack as the response frame for the received NDP type PS-Poll, the following information (wherein some information may be included in NDP type PS-Poll) may be used to compute the identifier for the pairing frame exchange i.e. short Ack for NDP type PS-Poll:
information of STA, e.g. MAC address, AID;
SIG bits of received NDP type PS-Poll frame to be acknowledged;
information of AP, e.g. MAC address, timestamp, SQN or (partial) FCS of the beacon, partial SSID; and
hash function of the above information.

According to various embodiments, four options for the short Ack SIG format may be provided, like will be described with reference to Table 3 to Table 6.

TABLE 3
Option 1: Short Ack SIG for NDP Type PS-Poll

| Field | Bit width | Comments |
|---|---|---|
| Message type | 4 | Unused MCS field in |
| indicator | | normal data packet |
| TA | 9 | (partial) AID |
| RA | 9 | (partial) BSSID |
| Preferred MCS | 4 | |
| Tail bits | 6 | TBD (Depending on |
| | | group's decision on tail |
| | | bit support) |
| CRC | 4 | |
| TOTAL | 36 | 2 MHz case, there are 12 |
| | | reserved bits |

According to various embodiments, in Option 1 (compare Table 3 for SIG fields), the fields of RA (receiver address) and TA (transmitter address) may be defined, RA and TA bits may be used as the identifier for pairing frame exchange i.e. short Ack for NDP type PS-Poll.

The probability of exact same RA and TA of short Ack for NDP type PS-Poll may be low due to the design of RA, which may be based on (partial) AID of the STA that sends NDP type PS-Poll and/or CRC bits of NDP type PS-Poll to identify the receiver of Short Ack, and the design of TA, which may be based on partial FCS and Scramble Seed of received beacon frame or RA bits (and possibly CRC bits) of NDP type PS-Poll to identify the transmitter of Short Ack.

TABLE 4
Option 2: Short Ack SIG for NDP Type PS-Poll

| Field | Bit width | Comments |
|---|---|---|
| Identification | 4 | Type ID for Short Ack |
| | | for NDP type PS-Poll. |
| ACK ID | TBD | Based on Partial FCS |
| | | and Scramble Seed of |
| | | received beacon frame, |
| | | or |
| | | RA bits (e.g. PBSSID) |
| | | and/or CRC bits of NDP |
| | | type PS-Poll, as well as |
| | | TA bits (e.g. PAID) of |
| | | NDP type PS-Poll. |
| | | Suggest to use all unused |
| | | bits |
| More Data | 1 | |
| Tail bits | 6 | TBD (Depending on |
| | | group's decision on tail |
| | | bit support) |
| CRC | 4 | |
| TOTAL | 36 | 2 MHz case, there are 12 |
| | | reserved bits |

According to various embodiments, in Option 2 (compare Table 4 for SIG fields), ACK ID may be defined and used as the identifier for pairing frame exchange i.e. short Ack for NDP type PS-Poll. One combined field i.e. ACK ID in SIG to replace RA and TA fields may be designed, but may have different length. It is to be noted that while computation of ACK ID in short Ack for the received frame other than NDP type is based on partial FCS (frame check sequence) and scrambling seed of received frame, computation of ACK ID in short Ack for NDP PS-Poll may be based on the methods shown in the following for ACK ID computation.

The design according to various embodiments may ensure a low duplication probability of RA and TA bits or ACK ID for NDP type and ACK ID for non-NDP type frame, due to the difference between the two computation methods. The identification in SIG bits may be used to differentiate two types of short Ack.

TABLE 5
Option 3: Short Ack for NDP Type PS-Poll

| Field | Bit width | Comments |
|---|---|---|
| Identification | 4 | Type ID for Short Ack for NDP type |
| | | PS-Poll. |
| ACK ID | 12-14 | Based on Partial FCS and Scramble |
| | (Same as defined | Seed of received beacon frame, or RA |
| | in Short Ack for | bits (e.g. PBSSID) and/or CRC bits of |
| | non-NDP frame) | NDP type PS-Poll, as well as TA bits |
| | | (e.g. PAID) of NDP type PS-Poll. |
| | | Suggest to use all unused bits |
| Duration/ | 6-8 | # of bits is same as defined in Short |
| ACK ID | | Ack for non-NDP frame |
| Ext. | | |
| More Data | 1 | |
| Tail bits | 6 | TBD (Depending on group's decision |
| | | on tail bit support) |
| CRC | 4 | |
| TOTAL | 36 | 2 MHz case, there are 12 reserved bits |

According to various embodiments, in Option 3, the same structure as the short Ack for non-NDP type may be used but may have a re-defined DURATION field (if it is defined) or use some reserved bits in current short Ack design (if DURATION field is not defined). The newly defined/redefined field may be ACK ID Ext.

ACK ID and ACK ID Ext fields may be used as the identifier for the pairing frame exchange, where ACK ID may be the resulting bits based on partial FCS and scramble seed of received beacon frame or RA bits of NDP frame being acknowledged, and some TA bits of NDP frame being acknowledged. E.g. 9 RA bits and 3 MSB (most significant bits) of TA field for 12 ACK ID bits, and ACK ID Ext is some (remaining) TA bits of NDP frame being acknowledged. E.g. 6 LSB (least significant bits) of TA field for 6 DURATION/ACK ID Ext bits. If more bits can be used for ACK ID Ext, CRC bits of the received NDP type frame can be used that is being acknowledged. According to various embodiments, other bit arrangement may be provided, dependent on whether to place the above bits into the fields of ACK ID/ACK ID Ext.

According to various embodiments, ACK ID may be used to refer to the combination of ACK ID and ACK ID Ext bits/fields without causing any ambiguity.

TABLE 6
Option 4: Short Ack for NDP Type PS-Poll

| Field | Bit width | Comments |
|---|---|---|
| Identification | 4 | Type ID for Short Ack for NDP type |
| | | PS-Poll. |
| ACK ID | 12-14 | Based on Partial FCS and Scramble |
| | | Seed of received beacon frame, or RA |
| | | bits (e.g. PBSSID) and/or CRC bits of |
| | | NDP type PS-Poll, as well as TA bits |
| | | (e.g. PAID) of NDP type PS-Poll. |
| Duration | 6-8 | |
| More Data | 1 | |
| Tail bits | 6 | TBD (Depending on group's decision |
| | | on tail bit support) |
| CRC | 4 | |
| TOTAL | 36 | 2 MHz case, there are 12 reserved bits |

According to various embodiments, Option 4 may follow the same field structure as the short Ack for non-NDP type. ACK ID may be the identifier for the paring frame exchange, 12-14 bits. ACK ID may be a function of RA and TA bits of NDP type frame. ACK ID may be a function of RA bits of NDP type frame and resulting bits based on partial FCS and scramble seed of received beacon frame. CRC bits of NDP frame may be used as the input for the function to compute ACK ID as well if there is enough bit space.

In the following, ACK ID Computation according to various embodiments will be described.

According to various embodiments, ACK ID may be computed for short Ack as the response to NDP type PS-Poll, for example using STA's information:
MAC address, which only partial MAC address is feasible;
AID,
   Which may be used as receiver address for short Ack
   From which full/partial AID/other equivalent AID-based value can be used to identify AID of the STA
   Of which (partial) AID exists in SIG bits
   Which may be combined with the information of AP that is used as transmitter address for short Ack, as the identifier for pairing frame exchange i.e. short Ack for NDP type PS-Poll frame

According to various embodiments, ACK ID may be computed for short Ack as the response to NDP type PS-Poll, using SIG bits of NDP type PS-Poll, based the example in Table 1:
MCS, which may not be helpful.
RA, e.g. (Scrambled) Partial BSSID, which may be common to all STAs associated with the same AP and can be used to identify different BSSID (APs) with low error probability. It is to be noted that (partial) BSSID can be used as transmitter address for Short Ack. RA field of NDP PS-Poll may be computed by the STA, based on partial FCS and scrambling seed of received beacon from AP.
TA, e.g. (Partial) AID, which is dependent on the number of ACK ID bits in SIG and can be used as receiver address for Short Ack.
CRC bits (4 bits), which may be not sufficient to differentiate the PS-Polls from multiple STAs to avoid the duplicate ACK ID problem, and may be used together with RA bits e.g. Partial BSSID (9 bits in the example in Table 1) to construct an ACK ID with 13 bits.
Tail bits, which may also not be helpful.
Preferred MCS, which may also not be helpful.

ACK ID may be computed for short Ack as the response to NDP type PS-Poll, using the beacon information:
Scramble seed of Service field; and
Partial FCS.

If the RA field of NDP type PS-Poll is based on the above beacon information, due to limited bit space (e.g. 9 bits) for RA field in SIG, RA bits may be expanded into more bits using the beacon info or combined with CRC bits in SIG of the received frame to form an ACK ID. For example, if the number of ACK ID bits is larger than the number of CRC bits and RA bits of NDP type PS-Poll that are used to construct ACK ID field, ACK ID based on CRC bits may be obtained and expanded RA bits (e.g. (scrambled) partial BSSID or the computation results that is based on partial FCS and scrambling seed of the received beacon frame).

When partial BSSID is used for RA field of NDP type PS-Poll frame, expanded RA bits may be computed using some more extra bits of BSSID other than partial BSSID used in NDP PS-Poll. For example, if partial BSSID uses 9 bits, then expanded RA bits (assuming 12 bits) may be obtained by adding three more BSSID bit into partial BSSID. The method may be applicable to scrambled PBSSID as well, as long as scrambling bits are also expanded and known to both AP and STA.

The method may also be applied to the computation results that are based on partial FCS and scrambling seed of the received beacon frame.

For the ACK ID computation for Option 2 according to various embodiments, the field structure may be shown as in Table 4. If RA field of NDP type PS-Poll is not based on partial FCS and Scrambling Seed of the received beacon frame, which are used for ACK ID computation, AP and STA may have to store the info of partial FCS and Scrambling Seed of the beacon frame or the resulting bits (ACK ID) based on the information. The complexity or the cost of this scheme may be higher than Option 1.

The AP may use some or all the following bits in SIG of NDP type PS-Poll (SIG field structure is assumed as in Table 1) to compute ACK ID in short Ack as the response to the received NDP type PS-Poll sent by STA:
RA bits (and possibly CRC bits) of NDP type PS-Poll or Partial FCS and scrambling seed of the received beacon frame; and
STA's (partial) AID or CRC bits of the received NDP type PS-Poll.

For example, ACK ID may include or may consist of some of RA bits and all TA bits of NDP type frame. For example, 14 bits for ACK ID may be considered. For example, the NDP PS-Poll frame structure as in Table 1 with RA=9-bit PBSSID and TA=9-bit PAID may be assumed:
ACK ID use 8 of 9 PBSSID bits. E.g. 8 LSB PBSSID bits;
Divide 9-bit PAID into two parts: PAID-MSB and PAID-LSB. E.g. 3-bit PAID-MSB and 6-bit PAID-MSB;
8 PBSSID bits may be rotated (right or left-shifted) and the rotation counter follows the value of 3-bit PAID-MSB. E.g. if the value of 3 MSB PAID bits is 7, then 8 PBSSID will rotate (right-shift or left-shift) 7 times and the resulting rotated bits are used as MSB of ACK ID; and
the remaining LSB of ACK ID is 6-bit PAID-LSB.

According to various embodiments, the bit-rotating approach of PBSSID bits based on AID value may be used for ACK ID based on scrambled PBSSID bits of NDP type frame. According to various embodiments, the bit-rotating approach of PBSSID bits based on AID value can be used for ACK ID based on TA bits of NDP type frame and resulting bits based on partial FCS and scramble seed of received beacon frame. According to various embodiments, the bit-rotating approach of PBSSID may be generalized as the indexing method where the index is based on some of known AID bits (all these bit positions should be known to both engaging AP and STA) and there may be an array of NDP PS-Poll RA (PBSSID) bits that are permutated by some bit arrangements that are also known to both AP and STA. In the example shown above, the indexing may use 3-bit PBSSID-LSB and the bit-rotation method may be used so that the complexity is low due to that both AP and STA don't need to remember the array of permutated PBSSID.

In the following, identifying ACK ID that is based on bit-rotation will be described. According to various embodiments, to decode ACK ID, the STA

(1) Set test counter as zero;

(2) Test whether 8-bit ACK ID-MSB matches the RA (8-bit PBSSID-LSB) bits in NDP PS-Poll previously sent and waits for acknowledgement;

(3) If matched, test counter is 3-bit AID-MSB and then go to (7). If not matched, decide whether test counter is 7.

(4) If the test counter is 7, declare ACK ID as invalid and end the decoding.

(5) Otherwise, increase the test counter and go to (6).

(6) Rotate (e.g. right-shift) the 8-bit ACK ID-MSB and go to (2) to continue the test.

(7) Obtain 6-bit PAID-LSB from 6-bit ACK ID-LSB and recover 9-bit PAID from 3-bit PAID-MSB and 6-bit PAID-LSB.

(8) Test whether PAID value is valid. If PAID bits are valid, ACK ID is valid. Otherwise, declare ACK ID as invalid.

CRC bits may be masked (bitwise XOR) with some bits of the identifier for pairing frame exchange (e.g. RA/TA/ACK ID bits), i.e. short response frame that acknowledges NDP type PS-Poll. Some of the identifier may be embedded inside CRC mask bits. CRC bits may be computed same as for Short Ack in but mask with some extra bits that are not in the short response frame SIG.

The indexing method (for example including bit-rotation) may be masked and a CRC mask may be used to generate ACK ID with a shorter length. For example, 14-bit ACK ID (option 4) may be considered and it may be assumed that PAID (partial AID) is used as TA for NDP PS-Poll. 9-bit PBSSID and 5-bit PAID-MSB may be used to construct ACK ID for short response frame SIG, and 4-bit PAID-LSB may be used to mask 4-bit CRC. When STA receives response frame SIG for its NDP PS-Poll, it may unmask CRC with its 4-bit PAID-LSB and compare the result with expected CRC bits that can be computed by the STA according to its NDP PS-Poll SIG being acknowledged. If matched, the short frame may be possible for itself and for further processing.

According to various embodiments, the CRC mask and indexing method may be combined to further relax the requirement on the number of ACK ID bits. 12-bit ACK ID (option 4) may be considered and it may be assumed that PAID is used as TA for NDP PS-Poll. 10-bit PBSSID may be used that is expanded by the AP and may also be known by the STA, and 5-bit PAID-MSB may be used to construct ACK ID for short response frame SIG, and 4-bit PAID-LSB may be used to mask 4-bit CRC. For example:
When using 5-bit PAID-MSB, the first two bits may be used in ACK ID in addition to 10-bit PBSSID and the remaining 3 bits of PAID-MSB may be used as the index by AP to obtain the PBSSID.
An array of permutated 10-bit PBSSID may be determined/known by both AP and STA and the indexing method is used.
When STA receives short Ack, it first may unmask CRC bits in SIG with its own 4-bit PAID-LSB and calculate CRC for the remaining bits in SIG before checking the calculated CRC against the unmask CRC. If they are matched, STA may verify whether the received 10-bit PBSSID is correct by comparing it against its resulting 10-PBSSID that are obtained by using the value of its 3^{rd}-5^{th} PAID-MSB as the index to the array of permutated 10-bit PBSSID. Thus, STA may obtain 3^{rd}-5^{th} bit of PAID and 2-bit PAID-LSB from ACK ID in SIG, and verify with its own PAID bits.
The rotating method described above may be used to free AP and STA of storing the array.

In the following, an example will be described in which 12-bit ACK ID is acquired through CRC mask and bit-rotation that includes the information of partial AID (PAID). Firstly the AP may construct SIG with the following bits to compute CRC before CRC mask:
4-bit Type Indication;
ACK ID that is concatenated by rotated scrambled partial BSSID and 2-bit PAID-MSB; and
other SIG bits.

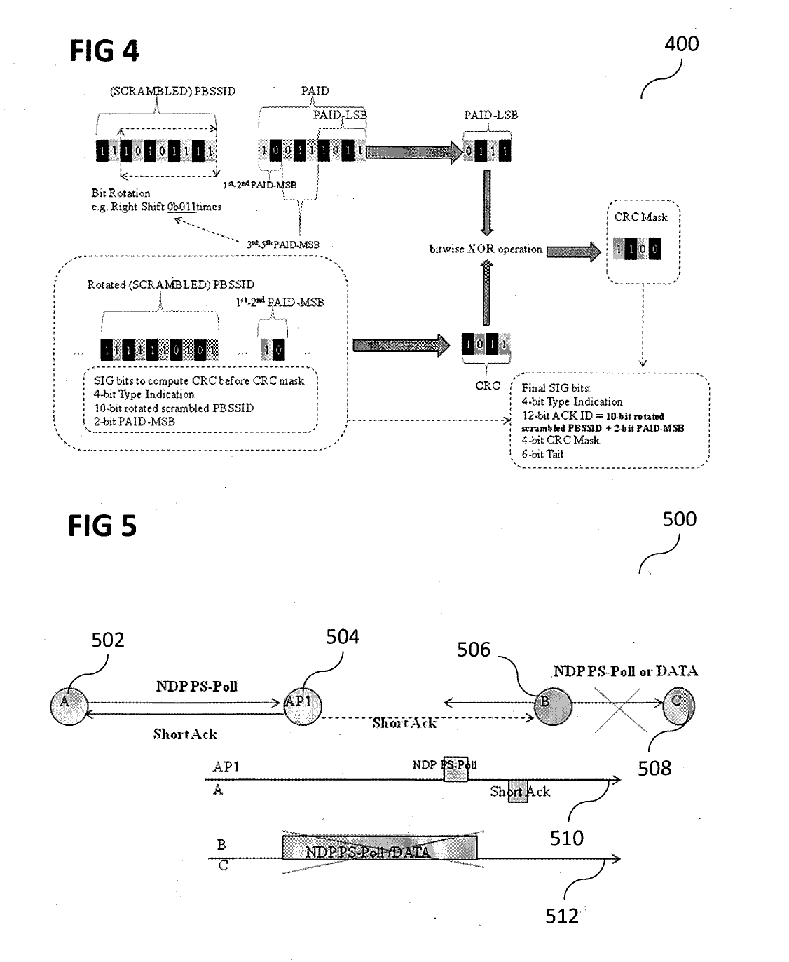

FIG. 4 shows an illustration 400 of an example of Bit-rotating and CRC Mask. As shown in FIG. 4, 10-bit rotated scrambled PBSSID is obtained by AP expanding 9-bit scrambled PBSSID into 10-bit (which is agreed between AP and the STA) of which the first 2-bit scrambled PBSSID remains unchanged while the last 8-bit scramble PBSSID is bit-rotated (e.g. right-shifted) with the times that is determined by the value of 3-bit PAID-MSB i.e. 3^{rd}-5^{th} bits. After CRC is computed for these SIG bits, the 4-bit PAID-LSB is used to mask CRC results i.e. 4-bit PAID-LSB bitwise XOR operation with 4-bit CRC results.

To decode the SIG bits, firstly the STA may check type indication and then may unmask 4-bit CRC mask with its own 4-bit PAID-LSB. After unmasking, the STA may compute whether unmask CRC is correct for the SIG bits. If the CRC result is correct, the STA may proceed to decode ACK ID for scrambled PBSSID which is the first 10-bit of ACK ID. It may determine whether the rotated scrambled PBSSID is matched with its own pre-computed scrambled PBSSID after rotating these rotated scrambled PBSSID with the times that is the value of 3^{rd}-5^{th} bits of its own PAID-MSB. For example, if the value of 3^{rd}-5^{th} bits of its own PAID-MSB is 5, then scrambled PBSSID bits may be right-shifted 5 times by STA (while AP should left-shift 5 times scrambled PBSSID bits). If the above matches, the STA may obtain 11^{th}-12^{th} bits of ACK ID and may verify against its own 1^{st}-2^{nd} bits of PAID-MSB. If the above matches, the ACK ID may be correct and the STA consider it has been acknowledged positively.

In the following, Differentiating Short Acks for NDP Type and Non-NDP Type frames according to various embodiments will be described. According to various embodiments, short Acks for NDP type and non-NDP type may be differentiated through the identification bit(s) in SIG.

FIG. 5 shows an illustration 500 of how false Short Ack may be avoided according to various embodiments. For example a first station 502 may send an NDP PS-Poll to a first AP 504, and this NDP PS-Poll may arrive at the first AP 504. Furthermore, a second station 506 may send another NDP PS-Poll to a further station 508 (for example a second AP), which may not arrive at the further station 508. Then, by differentiating short ACKs according to various embodiments, a short Ack from the first AP 504 to the first station 502 (like indicated by flow 510) may not lead to a false short Ack at the second station 506 (like indicated by flow 512).

ACK ID based on the scheme according to various embodiments may be used to identify short Ack frame to reduce the probability of a false short Ack that may be accepted by a transmitter B 506 if
The intended receiver C 508 does not receive the NDP type PS-Poll or DATA correctly, and does not send short Ack.
Another STA A 502 is transmitting to AP1 504 with transmission ended at exactly the same time when B ends its transmission.
Transmission from B 506 is not able to interfere with the transmission from A 502 to AP1 504, so that AP1 504 may send a short Ack to A 502; while short Ack can arrive at B 506 correctly.
Since B 506 is expecting short Ack from C 508, B 506 may accept the short Ack from AP1 504 by mistake.

Even if B 506 has a much shorter transmission range than AP1 504 and there is no protection for NDP PS-Poll, the probability of exact same ACK ID for NDP type PS-Poll is very low due to the good design of ACK ID.

But the duplication probability of ACK IDs for NDP type and non-NDP type frame may be not low due to the computation methods for these two kinds of ACK ID are different:

(1) Computation of ACK ID in short Ack for the received frame other than NDP type may be based on partial FCS and scrambling seed of received frame.

(2) Computation of ACK ID in short Ack for NDP PS-Poll may be based on partial FCS and scrambling seed of received beacon or RA bits and/or CRC bits of received NDP type PS-Poll frame, as described above.

Further, short Ack for NDP type (PS-Poll) frame may be differentiated from short Ack for non-NDP type frame using some identification bits in SIG so that the probability of confusing other data transmission may be low.

I. Upon receiving NDP type PS-Poll, AP may set the identification bits in short Ack to indicate that the frame is for NDP type PS-Poll, as the response to the PS-Polling STA.

II. Upon receiving short Ack, PS-Polling STA may identify the identification bits that signal the response frame is a short Ack for NDP type frame. It is to be noted that it is assumed the probability of duplicate identifier e.g. ACK ID for NDP type response to NDP type frame is fairly low due to the method for ACK ID computation according to various embodiments.

III. Once AP/STA receives short Ack, in addition to CRC checking, it may proceed with the related protocol as follows:

a. If AP/STA that is involved in the process using NDP type PS-Poll and short Ack receives other AP's short Ack for non-NDP type PS-Poll, it may identify whether it is a short Ack for NDP type frame.

i. If it is a short Ack for non-NDP type frame, AP/STA may discard.

ii. If it is a short Ack for NDP type frame, AP/STA may identify whether it is addressed to itself by using the identifier e.g. ACK ID field and/or other fields to determine whether the short Ack is addressed to it. If it is not addressed to itself, it may discard.

b. If AP/STA that is involved in the process using non-NDP type frame and short Ack receives other AP's short Ack for NDP type PS-Poll, AP/STA may identify whether it is a short Ack for non-NDP type frame.

i. If it is a short Ack for NDP type frame, AP/STA may discard.

ii. If it is a short Ack for non-NDP type frame, AP/STA may identify whether it is addressed to itself by using the identifier e.g. ACK ID field and/or other fields to determine whether the short Ack is addressed to it. If it is not addressed to itself, it may discard.

The method to differentiate short frame (e.g. short Ack) for NDP type and non-NDP type using some SIG bits according to various embodiments may be applied to other short frame similarly, if the design approaches of some of the fields are different.

In the following, Short CTS SIG Design will be described. In a Short CTS, the SIG field may include:
MCS—4 bits (use a different reserved value from short Ack);
Bandwidth (BW)—3 bits;
Duration—TBD bits;
CRC—4 bits;
Tail—6 bits (TBD);
CTS ID—<=9 bits (1 MHz); <=21 bits (2 MHz).

Short CTS may also be used as AP assisted medium synchronization frame, and short CTS frame reserves a time interval for a STA that is scheduled to wake up at the slot boundary (or TWT, i.e. Target Wake Time), with the SIG including RA field i.e. the address of the STA that is scheduled to wake up at the slot boundary.

Short CTS may consider CTS ID to address the receiver. For the case of RTS/CTS, CTS ID may be determined based on Partial FCS and scramble seed information from RTS. For the case of CTS-to-Self, CTS ID may be obtained from partial TA of the transmitter to address both TA and RA. It may be assumed that Short CTS uses RA field to address the receiver. This may create a problem whether we should differentiate the above 3 kinds of short CTS since the duplicate probability of CTS ID may be high.

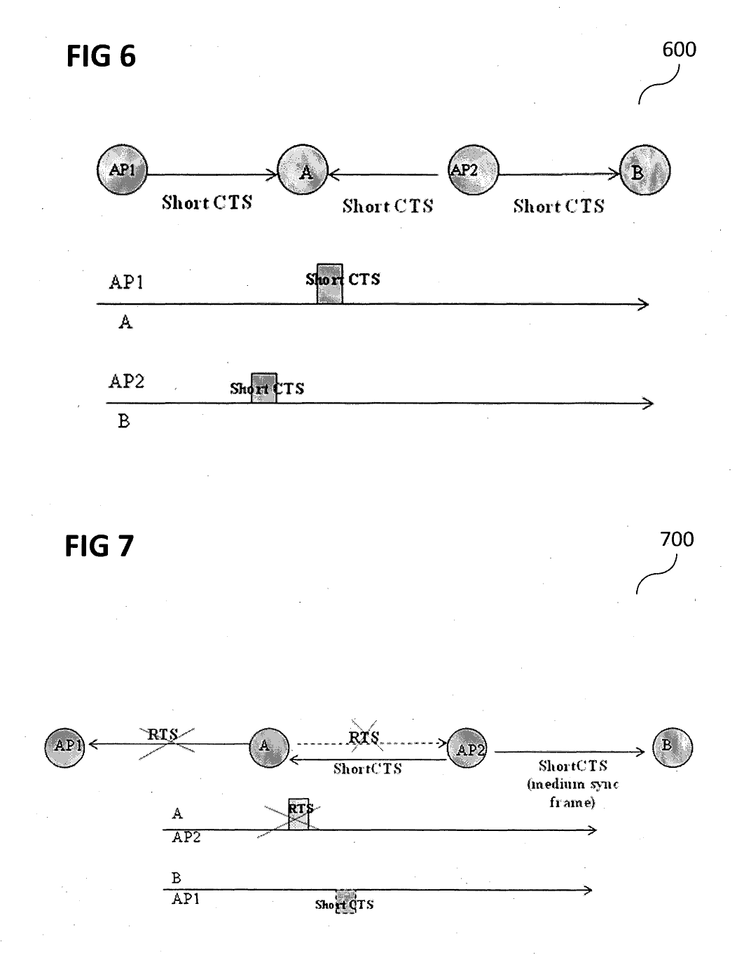

FIG. 6 shows an illustration 600 of the example of false short CTS as medium synchronization frame. Both AP1 and AP2 send short CTS as medium synchronization frame and AP1 is A's associated AP. If short CTS from AP1 and AP2 have the same CTS ID or RA field, false case occurs. STA A can't tell which short CTS is the real medium synchronization frame that it should follow. In FIG. 6, STA A may regard AP2's short CTS addressed to STA B as medium synchronization frame that is addressed to itself from AP1.

FIG. 7 shows an illustration 700 of the example of false short CTS for medium synchronization frame and RTS/CTS. STA A sends RTS to AP1 and expects a short CTS from AP1 as the response to its RTS and STA B expects a short CTS from AP2 as the medium synchronization frame. Suppose that AP1 didn't receive RTS or receive a corrupted RTS that AP2 also can't receive or receive a corrupted version, but AP2 transmits Short CTS to B as the medium synchronization frame. The possibility of this false short CTS case could be high if CTS ID/RA field for RTS/CTS and medium synchronization frame short CTS is identical.

If CTS ID and RA are unified for the above two cases, then only PAID or partial STA's MAC address is possible, since there may be no preceding frame before AP sends medium synchronization frame. When PAID or partial STA's MAC address is used, the duplicate probability is high due to they are not unique among different APs and there are many STAs that may have the same CTS ID or RA field. Another duplicate case is that CTS ID for CTS-to-self may confuse 3^{rd} party STAs doing RTS/CTS handshaking based on short CTS, when partial TA bits are used as CTS ID that is same as that in short CTS for RTS/CTS handshaking.

Type indication may be provided, wherein one bit (TBD) or some reserved case for a field (e.g. BW (bandwidth)) in SIG is used to differentiate two types of short CTS: short CTS as the medium synchronization frame and short CTS for RTS/CTS handshaking and CTS-to-self. For example, notice that BW=1, 2, 4, 8, 16 MHz, only 3 bits are required. 3 unused cases may occur for 3-bit BW and can use one such unused case to indicate that short CTS is used as the medium synchronization frame. Further, unused case may be used for short CTS used as CTS-to-self. There may be a need to define one field to indicate whether short CTS is from AP. There may be one bit defined to differentiate whether short CTS is from AP. This may be accepted in the 802.11ah. If the frame is a broadcast synchronization frame (not addressed to a particular STA), we can set DURATION field value as 0.

Two design options for short CTS SIG may be provided as follows.

Option 1 may be as follows: Short CTS is designed only for >=2 MHz. Define the following fields in SIG: RA and TA, in addition to the fields that may include Type Indication, BW, DURATION, CRC, Tail. E.g. RA is 9 bits, TA is 9 bits. We can define one field to indicate whether short CTS is from AP. For AP, when AP responds to the STA's RTS, use PAID as RA and use Partial BSSID or the computation resulting bits based on Partial FCS and scramble seed information from RTS as TA; when AP sends CTS-to-itself, use a reserved PAID (e.g. 0) as RA and use Partial BSSID as TA; when AP responds to the STA with medium synchronization frame, use PAID as RA and use Partial BSSID as TA; when AP broadcasts medium synchronization frame, use reserved PAID e.g. 0 as RA and use Partial BSSID as TA. For STA, when STA responds to AP's RTS, use PAID as TA and use Partial BSSID or the computation resulting bits based on Partial FCS and scramble seed information from RTS as RA; when STA sends CTS-to-itself, use its PAID as TA and use Partial BSSID as RA. The handling of short CTS should include the step to identify whether the frame is from AP and decide whether it is addressed to itself. There may be one bit defined to differentiate whether short CTS is from AP.

Option 2 may be as follows: Short CTS is designed such that is same for 1 MHz and >=2 MHz case, by embedding the PAID information into CRC bits and CTS ID. If BW field is not used for medium synchronization frame, re-define 3-bit BW for 3-bit PAID-MSB (1^{st}-3^{rd} bit of PAID). Use bit-shifted PBSSID as CTS ID. Note that bit-shifted PBSSID is the value of PBSSID right or left-shifted X times, where X is the value of 2-bit PAID-MSB (4^{th} and 5^{th} bit of PAID). Mask (bitwise XOR) CRC with 4-bit PAID-LSB (6^{th}-9^{th} bit of PAID). The above methods of CRC mask and bit-rotation operation have been described above. The handling protocol for CTS ID is similar to that for ACK ID that is based on CRC mask and bit-rotation as described above.

a) When the frame is a broadcast synchronization frame (not addressed to a particular STA), we can set DURATION field value as 0 and set PAID as 0 to compute CTS ID. The approach can be applied to the case of short CTS for CTS-to-self, where the STA/AP will set its partial MAC address as CTS ID and the STA use its PAID to do CRC mask and bit-rotation while the AP use 0 as PAID to do CRC mask and bit-rotation. Note that in these cases, the STA with the same partial MAC address may be required to send non-NDP CTS frame rather than short CTS. This can be done when the STA perform authentication/association or through other frame exchange between AP and STA.

b) When the frame is a synchronization frame addressed to a specified STA, the DURATION field value may be set as the estimated time interval reserved for that STA and use the STA's PAID to compute CTS ID. The approach can be applied to the case of short CTS for RTS/CTS handshaking.

c) The problem with this design is that direct RTS/CTS handshaking between two STAs may not be supported, as PBSSID may mix up with the PAID, if it is unable to tell the difference between two CTS IDs from the STA and the AP respectively. In this case, we can avoid this duplicate case by reserving the PAID value that is same as PBSSID. This reserved PAID value is not assigned to any STA. Alternatively, if AP allocates the PAID value that is identical to PBSSID to a STA, AP should request the STA to send normal CTS rather than NDP short CTS.

In the following, speed frame exchange using short frame according to various embodiments will be described. Speed frame exchange may provide functionality that may enable an AP and non-AP STA to exchange a sequence of uplink and downlink frames during a reserved time (for example TXOP). This operation mode may reduce the number of contention-based channel accesses, improve channel efficiency by minimizing the number of frame exchanges required for uplink and downlink data frames, and may enable stations to extend battery lifetime by keeping Awake times short. This continuous frame exchange may be done both uplink and downlink between the pair of stations.

Speed frame exchange may require the use of normal ACK, where More Data field in MAC header and response frame bits (2-bit Ack Indication) in SIG field may be used. Retrieving downlink buffered unit based on NDP type PS-Poll or transmitting buffered uplink data based on trigger frame or NDP frame carrying uplink data indication is also possible for speed frame exchange. Since short frames are transmitted with lower MCS and shorter duration, it is more efficient and robust to use short frames for speed frame exchange. Transmitting buffered uplink data based on trigger frame or NDP frame carrying uplink (UL) data indication for speed frame exchange can first let STA A send frame X (e.g. trigger frame or NDP frame carrying UL data indication) with More Data field set as 1 in SIG or MAC header and the peer STA B involved in speed frame exchange can send downlink (DL) data frame Y with More Data field set as 1 and 2-bit Ack Indication set as b11. 2-bit Ack Indication with the value b11 indicates STA A will send further UL data to STA B immediately following data frame Y.

In the speed frame exchange based on normal ACK, the unintended STA that can decode SIG correctly but decode MAC header wrongly may not be able to retrieve the More Data field in MAC header. If the 2-bit Ack Indication value is b00 (the response type is Ack), the unintended STA sets its NAV or defers its channel access corresponding to that for short Ack, which is wrong, as it shall actually identify there will be a normal ACK rather than short Ack immediately following current transmission. A data frame with More Data field set as 1 in MAC header and 2-bit Ack Indication set as b00 cannot make the unintended STA set its NAV or deferred channel access time correctly because the unintended STA can only decide that a short Ack is used immediately following the current data frame if it chooses not to decode or decode the MAC header wrongly.

According to various embodiments, two approaches based on short frames for speed frame exchange, like will be described in more detail in the following, may be provided. It is to be note that short Ack need not have response frame bits (2-bit Ack Indication). This embodiment may help replace the case of using normal ACK (if speed frame exchange is the only case using normal ACK) so that 2-bit Ack Indication may be re-designed, for example include 2-bit Ack Indication (00: short frame e.g. short Ack/short BA/short CTS; 01: normal BA; 10: No Ack; 11: a frame that is not ACK, BA or CTS) in SIG, by combining the indication for short Ack/short BA and excluding the use of normal ACK (but we can allow to use normal BA for the case where the preceding frame immediately followed with normal BA should set Ack Indication to b11, for example when normal BA is not with a fixed length or is transmitted with a rate different from the rate of the received frame that elicited the response).

In a first option, STA may set Duration field in Short Ack SIG to indicate whether there will be a frame from the peer STA immediately following current transmission. For example,
Duration=0 may indicate there will no frame immediately following current transmission from the peer STA;
Duration=x>0, e.g. aSIFSTime or (aPPDUMaxTime+2*aSIFSTime+aPHY-RX-START-Delay) (other value is also possible, as long as it makes clear that there will be some frame immediately following this Short Ack. If the unit is not microsecond, the value of Duration should be based on the time unit used.), indicates there will a frame (transmitted by the peer STA) immediately following current transmission.

In a second option, if Duration field in Short Ack SIG (for NDP PS-Poll) is not defined or not allowed to use, define one available bit (defined as Immediately Following Frame Indication, i.e. IFFI) to indicate whether there will be a frame from the peer STA immediately following current transmission.

The first option may be likely for using PS-Poll/Short Ack to complete speed frame exchange and the second option may be likely for using NDP PS-Poll/Short Ack to complete speed frame exchange.

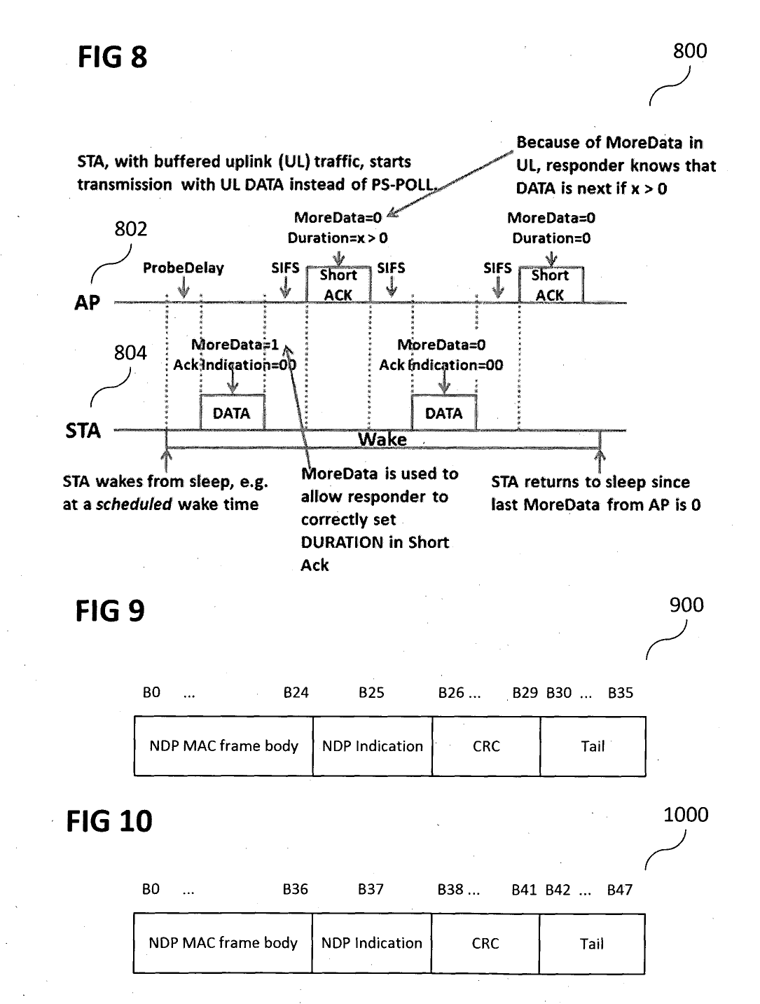

FIG. 8, like will be described also in more detail further below, shows an illustration 800 of an example of speed frame exchange using short Ack.

As shown in FIG. 8, speed frame exchange is based on short Ack (assume 2-bit Ack Indication as specified in IEEE 802.11-1137-11-00ah-specification-framework-for-tgah, Mingyong Park, “IEEE 802.11ah Specification Framework”). Station (non-AP STA or simply STA) has only uplink data to transmit to AP. STA sends first its uplink (UL) data with More Data field in MAC header set as 1 and 2-bit Ack Indication in SIG set as b00 to indicate the presence of short Ack immediately following current transmission. The unintended STA that can decode SIG and MAC header correctly will set its NAV or deferred channel access time to (aPPDUMaxTime+2*aSIFSTime+aPHY-RX-START-Delay). If the unintended STA can decode SIG correctly but is not able to decode MAC header correctly, it can set its NAV or deferred channel access time to the value corresponding to that for short Ack i.e. (short Ack duration+2*aSIFSTime+aPHY-RX-START-Delay). In the current 802.11 standard, it applies EIFS protection rule to set its NAV.

3^{rd} party STA receiving short Ack with DURATION=x>0. 3^{rd} party STA should wait at least a period of x before transmitting.
If x=aSIFSTime, early Ack indication design principle is not applied unless the unintended STA regards this as the indication that there will be a presence of a frame immediately following current transmission. The unintended STA can set NAV or deferred channel access time as the value of aPPDUMaxTime+2*aSIFSTime+aPHY-RX-START-Delay.
If x=aPPDUMaxTime+2*aSIFSTime+aPHY-RX-START-Delay, early Ack indication design principle is applied. The approach is exactly same as using response frame bits (0b11). The intended STA involved in speed frame change will access the channel. However, the unintended STA can set its NAV or deferred channel access time to the value of the Duration field in short Ack SIG but this kind of NAV setting is not very helpful for those unintended STAs that can receive the following frame (immediately after short Ack) as they may not be able to set a new NAV after acquiring that following frame due to the new NAV is likely smaller than current NAV.

The specific protocol is addressed in the above embodiments. The general protocol/procedure for handling Ack Indication can be summarized as follows:
The transmitting STA (transmitter) may set Ack Indication and may set the response type accordingly.
Upon receiving the SIG with IFFI or 2-bit Ack indication or 3-bit Ack indication or other indication that can be used to infer the response type and whether it is short frame or normal frame, the receiver (the intended STA) shall follow the instruction as indicated to transmit the corresponding response type and 3^{rd} party STA shall set its NAV or deferred channel access time according to the response type and whether it is short frame or normal frame:
o) If a short frame is used, its duration is fixed.
o) If a normal frame is used, the duration can be calculated based on the length (e.g. the length of BA is 32 bytes) and expected transmission rate (equivalent to the data transmission rate).
o) If the response type is not ACK, BA or CTS, the duration can be regarded as (aPPDUMaxTime+2*aSIFSTime+aPHY-RX-START-Delay), as shown in the case of speed frame exchange.

Including 2-bit Ack Indication (00: short Ack/short BA; 01: normal BA; 10: No Ack; 11: a frame that is not ACK, BA or CTS) in SIG may not be sufficient to support different options for the response type to PS-Poll. If the response to PS-Poll is short Ack or polling response, we can set 2-bit Ack Indication in the SIG of PS-Poll as the value b00 and b11 respectively.

If normal ACK has the same length as polling response, we can define 2-bit Ack Indication (00: short Ack/short BA; 01: polling response/normal ACK; 10: No Ack; 11: a frame that is not ACK, BA, CTS and polling response). Normal BA is used only in TXOP, where the value b11 can be used to indicate.

The solution to solve the problem of insufficient bits for Ack Indication or ambiguity caused by 2-bit Ack Indication can combine the techniques or the steps in various embodiments.

In the following, a method for fast frame forwarding according to various embodiments will be described.

In the current IEEE 802.11 standard, when the data packets are long, the RTS/CTS messages may be used to reserve the media for transmission. However, it is performed within one hop.

When relay is introduced, if the current design is used, two RTS/CTS transactions may be required. The overhead could be heavy and it may also lower down the media transmission efficiency. According to various embodiments, various RTS/CTS message exchange methods are provided to protect two-hop transmissions that involves relay.

For example, and without loss of generality, it may be assumed that the STA is two hops away from the AP.

According to various embodiments, processing as will be described in the following may be provided. One of the relaying scenarios considered in the 802.11ah standard is that both AP and station can hear each other. However, to save transmission power of STA, a relay station may be used by STA for uplink data forwarding. In such scenario, the STA may send RTS to AP directly but the reserve media duration includes both transmission durations required by STA and relay. After receiving the CTS from AP, waiting for a short duration such SIFS (Short Interframe Spacing), STA started to transmit data packet to relay, with relay indication in the data frame, either in the MAC frame control header or in the SIG. Relay may forward the packet to AP using the reserved channel time by STA using the RTS/CTS.

When the relay station receives RTS from STA, it may check the TA and RA field of the RTS and know whether the STA is served by the relay at the moment.

The STA may use some bits in the SIG/FC to indicate whether frame forwarding time required by relay is included in the RTS duration. If time is included, the relay station of the STA which sends the RTS shall update its NAV and also aware that it is required to use the reserved media to forward data frame from STA to AP if CTS is sent out by the AP to confirm the media reservation. It may not be allowed to use the reserved time to transmit frames other than the frame from STA that shall be forwarded to the AP later.

The relay station may verify whether the CTS received is the one replied to the RTS send by its subordinate STA. If CTS is a full CTS, the relay can derive the CTS is for the RTS sent by its subordinate STA earlier. If CTS is a short CTS, the station shall verify the CTS ID in short CTS to determine whether it is the one reply to the RTS from its STA.

According to various embodiments, processing as will be described in the following may be provided. The STA sends RTS to the relay and the relay further send an RTS to AP. For example, after receiving RTS from relay, AP reply with CTS to relay and relay further send CTS to STA. Most of the fields such as source and destination address, or CTS ID (when short CTS is used) can be reused. One bit in the RTS from STA to relay may indicate that a relaying of RTS may happen. The destination address in the RTS can be either the MAC address of relay or the MAC address of the AP. The source address in the RTS from relay to AP may be the MAC address of relay or the MAC address of STA. When short CTS is used, for the CTS from AP to STA, a relay bit may be set so that relay station will send the CTS to STA.

According to various embodiments, processing as will be described in the following may be provided. In case STA can hear from AP directly, RTS/CTS procedure defined as described in the following may be used. The STA may send RTS to relay first and relay may send a second RTS to AP. After receiving RTS from relay stations, the AP may send CTS to media. After receiving the CTS, the STA may send data over the reserved media.

According to various embodiments, processing as will be described in the following may be provided. In case STA can hear from AP directly, the RTS/CTS procedure defined as described in the following may also be used. STA may send RTS to relay first and relay may send CTS with relay bit to AP. After receiving CTS from Relay stations, AP may send CTS message to media. The CTS sent by the AP can be the same one as received from relay. After receiving the CTS, the STA can send data over the reserved media.

To realize the above described embodiments, it may be necessary to define one Relay bit or indication in RTS SIG/Frame Control field in MAC header to indicate that this RTS is required to be relayed to AP or being replied by Relay e.g. with (short) CTS.

The CTS sent can be a short CTS or other format with transmitted address and receiver address. Ack Indication in RTS (from STA to Relay) SIG may be set to a specified value e.g. b00 (indicating a short CTS frame is the immediate response).

For short CTS from Relay to AP, one IRFI (Immediate Response Frame Indication; the function may be similar to ACK Indication or IFFI) field may be defined to indicate where there will be a short frame following Short CTS. IRFI=0 may indicate there will be a short frame (e.g. short CTS) following Short CTS. IRFI=1 indicates there will be a Data frame (non-NDP) following Short CTS. For CTS from relay to AP, IRFI is set to 0. Duration is set to the Duration field value in RTS-SIFS-Short CTS duration. CTS ID may be based on the scrambling seed and FCS of received RTS and/or STA's AID and/or Partial BSSID or AID of Relay as well as AP's BSSID. For example, bitwise XOR operation on the computation results of the scrambling seed and FCS of received RTS, partial BSSID of Relay and partial BSSID of AP can create CTS ID carrying three parties' information.

Once STA receives Short CTS (sent by Relay), if IRFI=0, STA may defer channel access after SIFS+Short CTS Duration. Once AP receives Short CTS (sent by Relay) and if IRFI=0 and CTS ID is matched, AP will send short CTS.

For Short CTS from AP to Relay/STA, IRFI may be set to 1 and Duration may be extended according to its knowledge on the data rate between AP and Relay.

In the following, speed frame exchange using short Ack according to various embodiments will be described. According to various embodiments, an approach based on NDP frames for speed frame exchange may be provided. The current problem for speed frame exchange may be that NDP frames such as short Ack reloads 2-bit Ack Indication.

FIG. 8 shows speed frame exchange using short Ack according to various embodiments. Data processing 802 of an access point (AP) and data processing 804 of a station STA are shown.

According to various embodiments, as a first option, the duration field in Short Ack SIG may be set to indicate whether there will be data frame following current transmission:
Duration=0 indicates there will no data frame following current transmission;
Duration=x>0, e.g. aSIFSTime or (aPPDUMaxTime+aSIFSTime) (other value is also possible, as long as it makes clear that there will be some data frame following this Short Ack) indicates there will data frame following current transmission.

According to various embodiments, as a second option, if a duration field in Short Ack SIG (for NDP PS-Poll) is not defined or allowed to be used, one available bit (Immediate Response Frame Indication, IRFI) may be defined to indicate whether there will be data frame following current transmission.

According to various embodiments, as a third option, if both duration and IRFI fields are available, the following may be applied:
IRFI=1 indicates there will be a following frame, Duration field=0 if the frame duration is unknown or Duration=the frame duration+aSIFSTime if the frame being acknowledged contains NAV information or deferred channel access time or the duration of the frame following Short Ack is known;
IRFI=0 and Duration>0 indicates that short Ack is a timer/time indication;
IRFI=0 and Duration=0 indicates that short Ack is not a timer/time indication.

According to various embodiments, as a fourth option, 2-bit Ack Indication may be defined (or may not be reloaded).

Uplink data indication or More Data bit may be used indicate uplink buffered data and can be used as the first frame for speed frame change. According to various embodiments, uplink data indication or More Data bit may be used to indicate whether there is uplink data in PS-Poll which can be used as the first frame for speed frame change.

According to various embodiments, setting NAV or deferred channel access time to defer channel access may be provided as will be described in the following.

According to various embodiments: in the first option, if IRFI is not defined:
3rd party STA receiving short Ack with DURATION=x>0. 3rd party STA should defer channel access after at least a period of x before transmitting;
If x=aSIFSTime, early indication design principle is not applied;
If x=aPPDUMaxTime+aSIFSTime, early indication design principle is applied. The approach may be the same as using Ack Indication bits 0b11;
The STAs involved in speed frame change will access the channel.

According to various embodiments, in the second option, if IRFI is defined, the duration field may not be used and the following may apply:
IRFI=1 indicates there is an immediate following frame, same as 0b11;
IRFI=0 indicates there is no immediate following frame, same as No Ack (b10).

According to various embodiments, in the third option, the following may apply:
IRFI=1 and Duration field=0 indicates there is an immediate following frame, same as using Ack Indication bits 0b11;
IRFI=1 and Duration field=X>0 indicates there will be a following frame with duration X-aSIFSTime;
IRFI=0 indicates there is no immediate following frame, same as No Ack (b10).

According to various embodiments, in the fourth option, the duration field may not be required.

According to various embodiments, channel access upon receipt of short Ack may be provided as described in the following.

According to various embodiments, in the first option, a 3rd party STA may defer channel access after the period of time=(equal to) DURATION field value in Short Ack SIG upon receiving Short Ack.

According to various embodiments, in the second option, the 3rd party STA may defer channel access after aPPDUMaxTime+aSIFSTime upon receiving Short Ack with IRFI=1, or start channel access immediately for the case of IRFI=0.

According to various embodiments, in the third option, the 3rd party STA may defer channel access after the period of time=(equal to) DURATION field value in Short Ack SIG upon receiving Short Ack with IRFI=1, or start channel access immediately for the case of IRFI=0.

According to various embodiments, in the fourth option, the same as that in speed frame exchange using normal ACK may be applied.

According to various embodiments, other NDP frame as the response frame may include the fields of More Data and IRFI. The procedure using this kind of NDP CTS may be similar to that for using short Ack.

In the following, CRC Mask for NDP frames will be described.

CRC mask is a bitwise XOR operation of CRC bits with a priori information bits. The transmitter generates CRC and masks it with some bits (a priori information bits) and the expected receiver unmasks with the bits with a priori information bits.

One of the embodiment to use CRC mask is for NDP frames which is without MAC header/frame and only consists SIG fields (in additional to pre-amble). According to various embodiments, 4-bit CRC mask may be used to replace 4-bit CRC for all NDP frames, e.g. assume there is one RA (receiver address that is used to identify the receiver of NDP PS-Poll) field in NDP type PS-Poll. The receiver (AP) of NDP PS-Poll can determine the value before receiving, and use these information bits to perform CRC mask:
Transmitter (non-AP STA): Some bits (e.g. 4-bit) from Receiver Address field can bitwise XOR with CRC bits and the CRC mask results can be used to replace CRC field such that RA field can save some bits (4-bit) for NDP type PS-Poll;
Receiver (AP): unmask CRC field with those bits not in RA field but as part of Receiver Address identifier (the receiver address identifier can be part or full (scrambled) MAC address and the scrambling is pre-determined and known to both AP and its associated STAs) of NDP type PS-Poll and verify whether the Receiver Address field is matched with its own information and then compute/verify the CRC for the received NDP frame.

CRC mask approach may be used for

1. Short ACK to obtain the ACK ID which can be computed by the transmitter of the frame being acknowledged. If the generated ACK ID is 14-bit, after CRC mask operation, only a 10-bit ACK ID field is required and the remaining 4-bit can bitwise XOR with CRC bits. Note that ACK ID can be pre-computed by the receiver.

2. Short CTS to obtain the CTS ID which can be computed by the transmitter of the frame (RTS) being acknowledged. CTS ID field requires fewer bits (4-bit fewer).

3. Short BA to obtain the BAID and/or Start Sequence Control field which can be computed by the transmitter of the frames being BLOCK-ACKed.

4. NDP type PS-Poll to obtain Receiver Address identifier such that RA field requires fewer bits or TA field can be extended (e.g. 13-bit AID).

The revised NDP frame formats with CRC mask are as follows. Assume NDP frame type indication uses 4-bit for both 1 MHz and >=2 MHz cases. Total is 36 bits for 1 MHz. There are 12 reserved bits for the case>=2 MHz.

The Short ACK frame as the response frame for non-NDP frame is as follows:

| Field | Bit-length | Comment |
|---|---|---|
| NDP Indication | 1 | Indicate NDP frame |
| NDP frame type | 3 | Indicate Short ACK for |
| | | non-NDP frame |
| ACK ID | 12 | Based on Partial FCS and |
| | | Scramble Seed of received |
| | | frame (excluding 4-bit ACK |
| | | ID that is masked with |
| | | CRC) |
| More Data | 1 | Indicate whether there is |
| | | buffered data |
| ACK Indication | 1 | 1: there is a immediately |
| | | following data frame |
| | | 0: no immediately following |
| | | frame |
| Duration | 8 | |
| CRC mask | 4 | CRC bits masked with 4-bit |
| | | ACK ID that are not |
| | | included in ACK ID field |
| Tail | 6 | |

Total may be 36 bits for 1 MHz. There are 12 reserved bits for the case>=2 MHz.

The Short ACK frame as the response frame for NDP PS-Poll is as follows:

| Field | Bit-length | Comment |
|---|---|---|
| NDP Indication | 1 | Indicate NDP frame |
| NDP frame type | 3 | Indicate Short ACK for |
| | | NDP PS-Poll frame |
| ACK ID + ACK ID | TBD | Based on the fields of |
| Extention | | received NDP PS-Poll (e.g. |
| | | Partial BSSID and AID) |
| More Data | 1 | Indicate whether there is |
| | | buffered data |
| ACK Indication | 1 | 1: there is a immediately |
| | | following data frame |
| | | 0: no immediately |
| | | following frame |
| CRC mask | 4 | CRC bits masked with 4- |
| | | bit ACK ID that are not |
| | | included in ACK ID field |
| Tail | 6 | |

The NDP PS-Poll frame is as follows:

| Field | Bit-length | Comment |
|---|---|---|
| NDP Indication | 1 | Indicate NDP frame |
| NDP frame type | 3 | Indicate NDP PS-Poll frame |
| TA | 13 | Transmitter Address, based |
| | | on Partial or full AID |
| RA | 9 | Receiver Address, based on |
| | | Partial BSSID, excluding |
| | | those Receiver Address |
| | | identifier bits that are |
| | | masked with CRC bits. |
| CRC mask | 4 | CRC bits masked with 4-bit |
| | | Receiver Address identifier |
| | | that are not included in RA |
| | | field |
| Tail | 6 | |

The Short BA frame is as follows:

| Field | Bit-length | Comment |
|---|---|---|
| NDP Indication | 1 | Indicate NDP frame |
| NDP frame type | 3 | Indicate NDP Short BA |
| | | frame |
| BAID (Block ACK ID, | TBD | Excluding 4-bit BAID bits |
| Starting Sequence Control) | | that are not included in |
| | | BAID field |
| Block Ack Bitmap | TBD | |
| CRC mask | 4 | CRC bits masked with 4-bit |
| | | BAID bits that are not |
| | | included in BAID field |
| Tail | 6 | |

The Short CTS frame is as follows:

| Field | Bit-length | Comment |
|---|---|---|
| NDP Indication | 1 | Indicate NDP frame |
| NDP frame type | 3 | Indicate Short CTS |
| CTS ID | TBD | Based on Partial FCS and |
| | | Scramble Seed of received |
| | | frame (excluding 4-bit CTS |
| | | ID that is masked with CRC |
| | | bits) |
| Duration | TBD | |
| CRC mask | 4 | CRC bits masked with 4-bit |
| | | CTS ID that are not |
| | | included in CTS ID field |
| Tail | 6 | |

In the following, NDP ACK and NDP Modified ACK according to various embodiments will be described.

A design for short ACK and modified short ACK (i.e. NDP ACK and Modified ACK) may be provided. The SIG field formats of NDP MAC frames may be as in FIG. 9 and in FIG. 10.

FIG. 9 shows a SIG field format 900 for 1 MHz NDP MAC frame.

FIG. 10 shows a SIG field format 1000 for >=2 MHz NDP MAC frame.

An NDP MAC frame may be a NDP frame with the NDP Indication field of the SIG field set to 1 (or 0) to differentiate from non-NDP MAC frame. Several NDP MAC frame formats are defined to decrease MAC protocol overhead in IEEE 802.11ah.

The fields for NDP ACK/NDP modified ACK may contain an identifier that is used to differentiate from other NDP ACK/NDP modified ACK. They may contain Duration field and Duration Indication field. Since the Duration field should be enough to cover a long time period and resolution should be as small as possible, it is reasonable to have enough bits defined for the Duration field. For example, if 9 bits are used for Duration field, a Time Unit (TU) of millisecond must be used fore the Duration field in order to cover 512 milliseconds. However, a large TU may cause unnecessary earlier wakeup for a power saving STA if the Duration field is used to indicate the sleep time during which there is no transmission for the STA. The Duration Indication field is 1 bit in length. It is used to indicate whether the duration is the time of no data transmission (i.e., wakeup timer) for the STA (Duration Indication=1) or the channel access reservation time following current NDP ACK (Duration Indication=0). When the Duration field is used to indicate the channel access reservation time (i.e. the duration for all the transmissions for the STA) and also used by 3^{rd} party STA for NAV setting or deferred channel access time, the coarse TU may waste the channel access time unnecessarily. To reuse the Duration field for the above two purposes i.e., sleep time and channel access time. The time unit for two purposes may be different.

In the following expressions for the duration, without causing ambiguity, we can denote the duration for the transmission of maximum size of PPDU i.e. aPPDUMaxTime by MAX_PPDU, the duration for the transmission of ACK frame by ACK and aSIFSTime by SIFS.

For speed frame exchange based on NDP ACK as described herein, since Duration field is available for NDP ACK/Modified ACK, we can (1) set Duration Indication field to 0 which means the Duration field is used for the duration for frame transmission and Duration field is used to indicate the channel access reservation time for the transmission following current NDP ACK/modified ACK, e.g. to indicate there will be an immediate frame following NDP ACK. If the frame duration is known from immediate previous frame, Duration field for NDP ACK is set to (the corresponding duration indicated in the immediate previous frame−NDP ACK−SIFS)/TU (TU is the time unit for Duration field when Duration Indication=0). If the frame duration is unknown, Duration field is set to SIFS/TU (i.e. an equivalent value based on Time Unit for Duration field) in NDP ACK/modified ACK. A Duration field value corresponding to the duration of SIFS (or a non-zero value smaller than SIFS) has a special meaning here. It is indicated that there will be an immediate following frame (SIFS after current NDP ACK/Modified ACK). To know the exact transmission, the unintended STA has to listen to the immediate next frame or defer channel access for NDP ACK+2*SIFS after receiving the frame that elicited the NDP ACK frame. A Duration field value of 0 means there is no immediate following frame. (2) Duration Indication field is set to 1 which means a wakeup timer and there is no immediate frame following current NDP ACK/Modified ACK, and Duration field is set to the sleep duration for the STA being acknowledged.

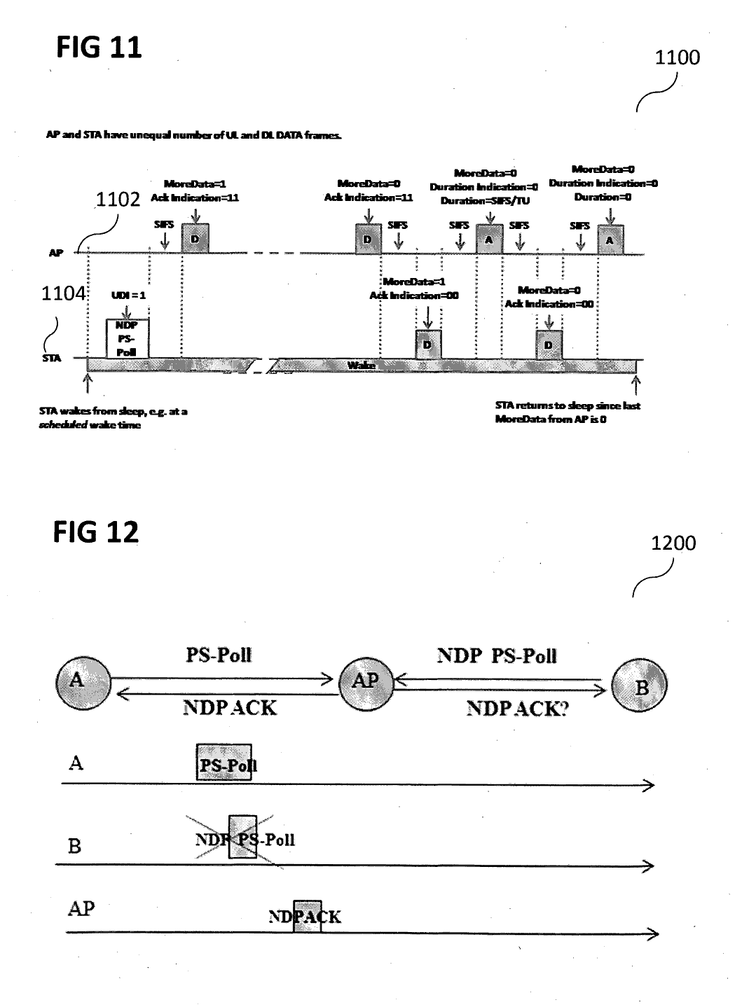

FIG. 11 shows an illustration 1100 of one example of speed frame exchange using short Ack for STA with uplink/downlink data. Processing 1102 of an AP and processing 1104 of a STA are shown.

3^{rd} party STA upon receiving Short Ack/modified short Ack:
defers before next event for a duration=Duration field value in short Ack/modified short Ack*TU if Duration Indication=0 and Duration>SIFS/TU;
defers before next event for a duration=aPPDUMaxTime aSIFSTime if Duration Indication=0 and 0<Duration<=SIFS/TU; and
defers SIFS before next event if Duration Indication=0 and Duration=0 or Duration Indication=1.

If Duration field (or Duration bits that can be unmasked from other fields in NDP ACK/Modified ACK) is available for short Ack/modified short Ack, we can let
Duration Indication=0 indicates there could be an immediate frame following short Ack/modified short Ack
o) Duration=0 is equivalent to No Response (equivalent to Ack Indication bits=10);
o) Duration=SIFS/TU is equivalent to Long Response with unknown length/duration (equivalent to Ack Indication bits=11), suitable for DATA without Duration field; Long Response means the response data unit is a data frame;
o) Duration>SIFS/TU is equivalent to long Response with known length/duration (Ack Indication bits=11) indicates channel access reservation time for the transmissions following current short Ack/modified short Ack, suitable for DATA with Duration field;
Duration Indication=1 indicates that Duration field is a wakeup timer and there is no immediate frame following current short Ack/modified short Ack
o) Duration=0 is equivalent to No sleep time;
o) Duration>0 indicates a wakeup timer.

TABLE 7
Usage of Duration Indication and Duration fields in NDP
ACK/Modified ACK

| Duration | | |
|---|---|---|
| Indication | Duration | Description |
| 0 | 0 | Ack Indication = 10 (No |
| | | response), which means |
| | | there will no response |
| | | frame. |
| 0 | SIFS/TU | Ack Indication = 11 |
| | | (long response, unknown |
| | | length/duration), which |
| | | means there will be a |
| | | data frame with unknown |
| | | duration as the long |
| | | response. |
| 0 | >SIFS/TU (SIFS/TU may be round | Ack Indication = 11 |
| | up/off. Other suitable value is also | (long response, known |
| | possible, as long as it is smaller | length/duration), which |
| | than SIFS/TU and larger than 0) | means there will be a |
| | | data frame with known |
| | | duration as the long |
| | | response. |
| 1 | 0 | No sleep time |
| 1 | Nonzero | Wakeup timer |

The reason why we can set Duration Indication to 0 and Duration to a value<=SIFS/TU to indicate the equivalent indication of Ack Indication bits set to 11 (long response with unknown duration) is that the STA is only allowed to access the channel after SIFS upon receiving the frame such as NDP ACK or ACK. Thus, any value smaller or equal to SIFS/TU is not meaningful to the receiving STA or not allowed in the baseline (IEEE 802.11-2012). We can reserve all these values to represent the special indication. For example, if SIFS=4*TU, any value of 1, 2, 3 and 4 can be used to indicate the equivalent indication of Ack Indication bits set to 11.

Table 7 shows the usage of Duration Indication and Duration fields for NDP ACK/Modified ACK, illustrating the equivalent indication of ACK Indication bits based on the Duration Indication and Duration fields of NDP ACK. The NDP (Modified) ACK frame with the reserved value for the Duration field that is smaller than SIFS/TU can be used to indicate other NDP frames (e.g. when Duration Indication is set to 0). When SIFS is 160 millisecond and TU is 40 millisecond, there are at least 3 reserved values (1, 2, 3) that can be used to indicate other NDP frames. For example, a NDP (Modified) ACK with the Duration Indication field set to 0 and the Duration field set to 1 can be used to indicate a null data packet of CF-End that is used to truncate the TXOP. In this case, ACK ID of this NDP frame can be computed as if the transmitter were the intended recipient. Alternatively, ACK ID of this NDP frame can be computed based on the partial AID (PAID) of the transmitter STA or the partial BSSID of the AP with which the transmitter STA is associated. The intended receiver should regard this special NDP frame as the truncation of the current TXOP. 3^{rd} party STA should regard this special NDP frame as a CF-End frame.

The ACK ID of NDP modified ACK may be determined by the following method. AP can concatenate the Partial AID (PAID) of the STA whose NDP PS-Poll is being acknowledged and its Partial BSSID (PBSSID) and use the partial 4-bit CRC of the received NDP PS-Poll or full result of the modulo X operation the 4-bit CRC value of the received NDP PS-Poll being acknowledged as the circular bit shift counter initial value (X=16 if total number of PBSSID and PAID bits is 18). For example, if the 4-bit CRC is 3, the concatenated bits will be right-shifted/left-shifted 3 times circularly to generate the ACK ID. Incorporating the 4-bit CRC of the received NDP PS-Poll can help giving additional information to identify the NDP Modified ACK so that the false case probability may be reduced. Another embodiment could be that using the partial 4-bit CRC of the received NDP PS-Poll or full result of the modulo X operation on the 4-bit CRC of the received NDP PS-Poll as the circular bit shift counter initial value (X=8 if total number of PBSSID bits is 9) to right-shift the PBSSID bits before concatenating with PAID bits to construct ACK ID.

Since there are fewer available bits e.g. for 1 MHz NDP MAC frames, the Duration field may not be included fully or partially. For example, if ACK ID is 18-21 bits for NDP Modified ACK, it is unlikely to have a separate field for Duration. According to various embodiments, partial/full Duration bits may be masked with the partial/full ACK ID bits. There may be Duration field including partial Duration bits. In this case, the construction of Duration bits shall consider both Duration field and those bits masking with partial/full ACK ID bits. The originator (transmitter) of NDP Modified ACK generates the real ACK ID (for example, following the methods in the previous paragraph) first and mask (bit-wise XOR operation) with Duration bits (after converted to the value in terms of Time Unit that could be 1 millisecond, SIFS, a Slot Time or other unit) to obtain the final ACK ID. The intended receiver of the NDP Modified ACK will unmask (bit-wise XOR operation) with the real ACK ID which is known to obtain the Duration bits. For example, assume that the length of the real ACK ID is 18 bits and the length of Duration is 9-bits, then the 9 most significant bits of the final ACK ID can be generated at the originator by the 9 most significant bits of the real ACK ID masking with 9-bit Duration value and the 9 least significant bits of the real ACK ID. Whether to mask with Duration bits with the partial/full real ACK ID bits may be dependent on Duration Indication. When Duration Indication is set to 0, as the 3^{rd} party STA may not receive the immediate previous frame being acknowledged, it is not feasible to mask the real ACK ID with Duration bits. When Duration Indication is set to 1, as the 3^{rd} party STA may not care about the wakeup timer, it is feasible to mask the real ACK ID with Duration bits.

Since there are only 4-bit CRC in NDP MAC frame to protect the error, NDP MAC frame may be error-prone due to the bad channel. According to various embodiments, a FEC (forward error correction) e.g. parity check bits or repetition coding for the Duration field may be used. Since if the Duration field is corrupted and CRC is not able to report the error, the STA may use the Duration wrongly, either with a wrong sleep time or with a wrong channel access time. There may be many FEC (forward error correction) coding methods on Short BA (BlockAck). One embodiment of FEC could be a repetition coding. Simply, we can repeat the Duration field bits and mask (bit-wise XOR) with the real ACK ID in NDP ACK/modified ACK so that the final ACK ID is a masked ACK ID i.e. the computation of real ACK ID bits XOR FEC coding bits for Duration field. For the intended STA, it knows how to verify the ACK ID since it can use the received Duration field bits in NDP ACK/modified ACK to unmask the received ACK ID so that it can compare the unmasked results with the real ACK ID that it has already known. Note that the ACK ID bits and FEC coding bits for Duration field are not necessary equal. We can simply mask partial or full ACK ID field with partial or full Duration field. Alternatively, we can apply a mapping function for FEC coding bits for Duration field and then mask with ACK ID field to generate masked ACK ID results. The mapping function is pre-defined. For example, we can generate CRC (secondary CRC in addition to 4-bit CRC field in NDP MAC frame) for the protected Duration field bits and use the CRC results as the mapping function input. The mapping function can use the above CRC results as the initial counter for circular bit-shift (either right-shift or left-shift) operation on the FEC coding bits for the Duration field that are used to mask with real ACK ID. The intended receiver will unmask the ACK ID field with the bits generated by circular bit-shifting the FEC coding bits for Duration field with the initial counter value as the generated CRC results from the received Duration field bits, and compare with the real ACK ID that it has already known. For example, if the 4-bit CRC are used for the FEC coding bits for Duration field and the result is b0101 (i.e. 3) which is used as the initial counter for the bit right-shifting, the transmitter of NDP ACK/modified ACK frame will right-shift the FEC coding bits for Duration field circularly 3 times to obtain the results for the masking with real ACK ID. If there is one bit available for FEC coding in NDP ACK/Modified ACK, we can even use one bit for parity check on Duration bits or field.

The above techniques can be used separately or combined together to achieve the design objective.

In the following, NDP ACK and Modified NDP ACK according to various embodiments will be described.

ACK ID for NDP ACK is based on partial FCS and scramble seed (service field) of the eliciting frame (the received frame being acknowledged by the receiver). But the frame such as PS-Poll may generate the partial FCS that is almost fixed. To achieve the randomization for the frame without almost fixed partial FCS bits, the ACK ID computation shall include the randomized bits (e.g. in the scramble seed) as many as possible. The randomization of ACK ID generated by the concatenation of the partial FCS and service field bits is not better than that of ACK ID generated by XOR operation on both the partial FCS and service field bits, as the number of randomized bits will be reduced if partial FCS bits are concatenated. Note that service field bits and partial FCS are considered to be independent. Therefore, according to various embodiments, the XOR operation both the partial FCS and service field bits to compute ACK ID for NDP ACK may be provided. The XOR operation retains both information bits of partial FCS and service field as many as possible.

Can we unify NDP ACK (the NDP response frame for non-NDP-PS-Poll frame) and Modified NDP ACK (the NDP response frame for NDP-PS-Poll frame) without extra indication bit? In the following discussion, we show that we need to define one bit to differentiate NDP ACK and Modified NDP ACK if unifying NDP ACK and Modified NDP ACK but this approach is not favorable since there is very limited bits for 1 MHz case. Therefore, the best way is to define two different NDP types for NDP ACK and modified NDP ACK.

It is to be noted that there are two different computation methods for ACK ID in the response frame (NDP ACK and Modified NDP, ACK):
ACK ID in the NDP ACK is based on FCS field of eliciting frame could be almost fixed (e.g. PS-Poll) and the number of used scramble seed bits is at most 7;
ACK ID in the Modified NDP ACK is based the eliciting NDP PS-Poll could be never randomized.

It may be assumed that NDP ACK and Modified NDP ACK are unified without differentiation (see the following for false case study).

FIG. 12 shows an illustration 1200 of a false NDP ACK Case for Concurrent Transmissions of PS-Poll and NDP PS-Poll to an AP. FIG. 12 shows one example of false NDP ACK case, where there are concurrent transmissions of PS-Poll and NDP PS-Poll. One transmission of PS-Poll is from A to AP and the other transmission of NDP PS-Poll is from B to AP. Both A and B can't hear each other and expect NDP ACK from AP. Suppose that AP can only receive a strong signal from A and respond to A's PS-Poll with NDP ACK that can reach B. B receives AP's NDP ACK, which may carry the same ACK ID in short response frame SIG so that the possibility of this false NDP ACK case could be high. This is because ACK ID in the response frame to PS-Poll could be fixed. FCS field of PS-Poll frame could be almost fixed (no randomization is provided) and only SERVICE field (scramble seed) provides randomization for ACK ID. If 6 LSBs of SERVICE field are used for ACK ID computation, the false case probability (duplication probability) could be as high as 1/64.

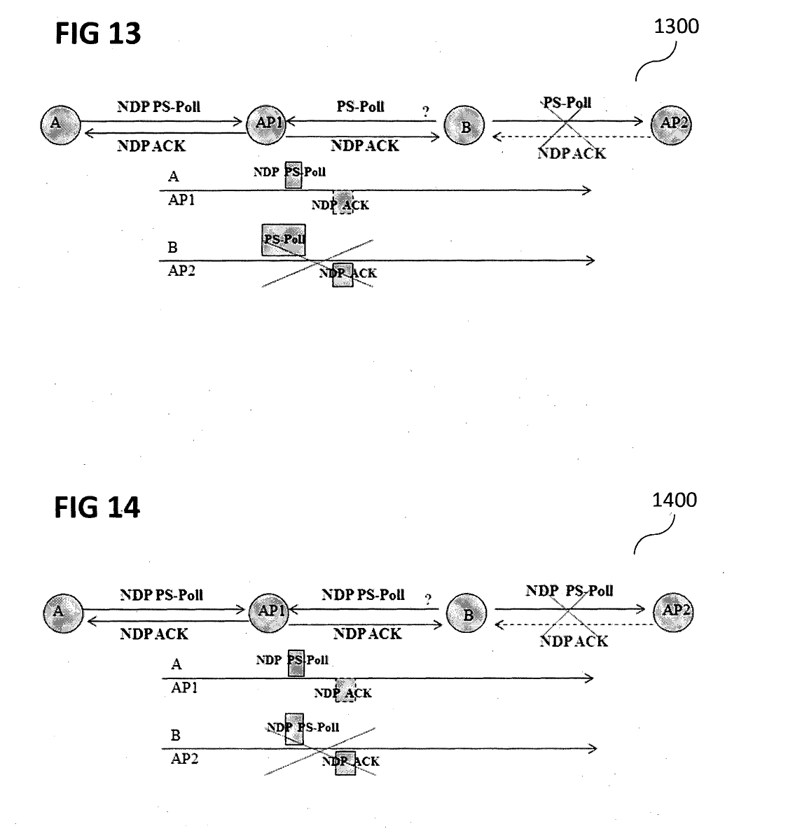

FIG. 13 shows an illustration 1300 of a false NDP ACK case for concurrent transmissions of PS-Poll and NDP PS-Poll to two APs. FIG. 13 shows an example of false NDP ACK case, where there are concurrent transmissions: One transmission of NDP PS-Poll is from A to AP1 and the other transmission of PS-Poll is from B to AP2 (A is associated with AP1 and B is associated with AP2). A expects a NDP ACK from AP1 and B expects a NDP ACK from AP2. Suppose that AP1 responds to A's NDP PS-Poll with NDP ACK that can reach B, but AP2 can't receive B's PS-Poll. B receives AP1's NDP ACK. If AP1 have a longer transmission range when it sends NDP ACK that can reach B, false NDP ACK occurs if ACK ID in the response frame to NDP PS-Poll and PS-Poll frame are same for A and B. The possibility of this false NDP ACK case could be high (˜1%) because FCS field of PS-Poll could be fixed and the number of the used SERVICE field bits for ACK ID computation is at most 7 and ACK ID in the response frame to NDP PS-Poll could be fixed.

FIG. 14 shows an illustration 1400 of a false NDP ACK case for concurrent transmissions of NDP PS-Poll to two APs. FIG. 14 shows an example of false NDP ACK case if ACK ID for NDP PS-Poll is based on TA field and CRC field of the eliciting NDP PS-Poll, where there are concurrent transmissions: One transmission of NDP PS-Poll is from A to AP1 and the other transmission of NDP PS-Poll is from B to AP2 (A is associated with AP1 and B is associated with AP2). A expects a NDP ACK from AP1 and B expects a NDP ACK from AP2. Suppose that AP1 responds to A's NDP PS-Poll with NDP ACK that can reach B, but AP2 can't receive B's NDP PS-Poll. B receives AP1's NDP ACK. If B have a shorter transmission range when it sends NDP PS-Poll that can reach AP1, and AP1 have a longer transmission range when it sends NDP ACK that can reach B, false NDP ACK occurs if ACK ID in the response frame to these two NDP PS-Polls are the same for A and B. The possibility of this false NDP ACK case could be high if ACK ID in the response frame to NDP PS-Poll is simply based on CRC bits and TA bits of NDP PS-Poll. Note that the STAs with the different AP may have the same TA bits for their NDP PS-Poll if the TA bits are obtained Partial AID bits (i.e. bitwise XOR operation on (partial) AID and some bits of its AP's BSSID.

Suppose both APs have only a very smaller number of STAs (e.g. 1 STA). For the false case shown in FIG. 14, ACK ID duplication occurs with high probability due to that TA (PAID) bits could be the same for the case of only 1 STA associating with each AP. Please note that in this case only CRC bits can tell the difference. But what if CRC bits are the same? The duplication probability is too high.

For >=2 MHz case, if ACK ID is computed with some RA bits, TA and CRC bits of NDP PS-Poll, but these RA bits could be identical for both APs and TA (PAID) bits are likely identical (e.g. when there is only 1 STA associating with each AP), duplication probability (false case probability) depends on CRC bits only.

To determine the ACK ID bit length, we have to balance between the bit length of ACK ID and Duration field. The longer ACK ID, the lower duplication probability (assume randomization is achieved); The More Duration bits, higher resolution time unit for channel access (NAV setting or deferred channel access time)/sleep duration, i.e. no/little time is wasted for channel access and more energy could be saved for long sleeper.

To keep both information from partial FCS and scramble seed for a ACK ID field with very limited space, according to various embodiments, ACK ID may be computed for non NDP-PS-Poll frame by XOR operation on both partial FCS and some or all the bits of Service fields of the eliciting frame. For example, ACK ID Computation (FCS and Service fields are from Received frame)
1M Hz: FCS[0:8] XOR (Service [0:6]∥Service [0:1]) or FCS[0:8] XOR Service [0:6];
>=2M Hz: FCS[0:15] XOR (Service [0:6]∥Service [0:6]∥Service[0:1]) or FCS[0:15] XOR Service [0:6])

where field[x:y] indicates the bits from position x to y in the field, XOR is the bitwise XOR operation and ∥ is the bit concatenation operation. Sometimes, when XOR operation on the bits with the unequal length, the MSBits should be set to 0's for the bits with the shorter length. Similarly the computation of ACK ID for NDP PS-Poll can be based on the XOR operation as well. For example, ACK ID computation is based on the following (CRC and RA fields are from the received NDP PS-Poll frame).

A first option may be as follows: ACK ID[0:8]=RA[0:8] and ACK ID[9:17]=Bit right/left-shift PAID with the counter that is some of MSBits or LSBits of 4-bit CRC of received NDP PS-Poll.

A second option may be as follows: ACK ID[9:17]=some of PAID bits XOR with 4-bit CRC of received NDP PS-Poll:
ACK ID[0:17]=RA[0:8])∥((CRC[0:3]∥CRC[0:3]∥CRC[0]) XOR TA [0:8]) or RA[0:8])∥(CRC[0:3] XOR TA [0:8]), where RA, TA and CRC fields are from received NDP PS-Poll frame being acknowledged.

The following tables may show embodiment of NDP ACK and Modified NDP ACK frames.

NDP MAC frame body of NDP ACK frame contains the information listed in Table 8 NDP MAC frame body of NDP ACK (1 MHz) and Table 9 NDP MAC frame body of NDP ACK (The NDP ACK frame used to respond to all frames other than a NDP PS-Poll frame is described in the following.

The NDP MAC frame body of NDP ACK for 1 MHz has the structure defined in Table 8 (NDP MAC frame body of NDP ACK (1 MHz)).

TABLE 8
NDP MAC frame body of NDP ACK (1 MHz)

| | Size | |
|---|---|---|
| Field | (bits) | Description |
| NDP MAC | 3 | NDP MAC Frame Type field is set to 2 |
| Frame | | |
| Type | | |
| ACK ID | 9 | The ACK ID field is 9 bits in length and computed |
| | | based on the partial FCS and the information from the |
| | | scrambling seed in the SERVICE field of the frame |
| | | being acknowledged for the computation of the ACK |
| | | ID for NDP ACK frame. ACK ID[0:8] = FCS[0:8] |
| | | XOR (Service[0:6] \|\| Service[0:1]), where FCS and |
| | | Service fields are from received frame being |
| | | acknowledged. Service field is obtained before |
| | | descramble. |
| More Data | 1 | The More Data field is described in 8.2.4.1.8. |
| Duration | 1 | The Duration Indication field is 1 bit in length. It is |
| Indication | | used to indicate whether the duration is the time of no |
| | | data transmission (i.e., wakeup timer) for the STA |
| | | (Duration Indication = 1) or the channel access |
| | | reservation time following current NDP ACK |
| | | (Duration Indication = 0). |
| Duration | 10 | The Duration field is 10 bits in length for 1 MHz. It is |
| | | used to indicate either the period of time, starting from |
| | | the end of the current frame transmission, that there |
| | | will be no data transmission for the STA being |
| | | acknowledged if Duration Indication is set to 1, or the |
| | | duration for all frames transmitted during CP, and |
| | | under HCF for frames transmitted during the CFP, if |
| | | Duration Indication is set to 0. The time unit for |
| | | wakeup timer is 1 millisecond, for transmission |
| | | duration is 40 microseconds. |
| | | Equivalent ACK Indication(if Duration Indication = 0): |
| | | Duration = 0 indicate that there is no frame |
| | | immediately following this frame, equivalent to No response |
| | | Duration = 1 indicate that there is a frame with |
| | | unknown frame duration immediately following this frame |
| | | Duration = 2 indicate that there is CF-End frame |
| | | immediately following this frame |
| | | Duration = 3 and 4 are reserved. |
| Relayed | 1 | This bit indicates the Relay shall share the TXOP and |
| Frame | | continue to transmit the frame over the next hop after SIFS |

The NDP MAC frame body of NDP ACK for >=2 MHz may have the structure defined in Table 9.

TABLE 9
NDP MAC frame body of NDP ACK (≧2 MHz)

| | Size | |
|---|---|---|
| Field | (bits) | Description |
| NDP MAC | 3 | NDP MAC Frame Type field is set to 2 |
| Frame Type | | |
| ACK ID | 16 | The ACK ID field is 16 bits in length and computed |
| | | based on the partial FCS and the information from the |
| | | scrambling seed in the SERVICE field of the frame |
| | | being acknowledged for the computation of the ACK |
| | | ID for NDP ACK frame. |
| | | ACK ID[0:15] = FCS[0:15] XOR (Service[0:6] |
| | | \|\|Service[0:6] \|\|Service[0:1]), where FCS and Service |
| | | fields are from received frame that elicited the |
| | | response. Service field is obtained before descramble. |
| More Data | 1 | The More Data field is described in 8.2.4.1.8. |
| Duration | 1 | The Duration Indication field is 1 bit in length. It is |
| Indication | | used to indicate whether the duration is the time of no |
| | | data transmission (i.e., wakeup timer) for the STA |
| | | (Duration Indication = 1) or the channel access |
| | | reservation time following current NDP ACK |
| | | (Duration Indication = 0). |
| Duration | 17 | The Duration field is 17 bits in length for the |
| | | bandwidth equal or larger than 2 MHz. It is used to |
| | | either indicate the period of time, starting from the end |
| | | of the current frame transmission, that there will be no |
| | | data transmission for the STA being acknowledged if |
| | | Duration Indication is set to 1, or the duration for all |
| | | frames transmitted during CP, and under HCF for |
| | | frames transmitted during the CFP, if Duration |
| | | Indication is set to 0. The time unit is described in Table 8. |
| Relayed Frame | 1 | The Relayed Frame field is described in Table 8. |

NDP MAC frame body of NDP Modified ACK frame contains the information listed in Table 10 NDP MAC frame body of NDP Modified ACK (1 MHz) and Table 11 NDP MAC frame body of NDP Modified ACK. The NDP Modified ACK frame used to respond to a NDP PS-Poll frame is described in the following. The NDP MAC frame body of NDP Modified ACK for 1 MHz has the structure defined herein.

TABLE 10
NDP MAC frame body of NDP Modified ACK (1 MHz)

| | Size | |
|---|---|---|
| Field | (bits) | Description |
| NDP MAC | 3 | NDP MAC Frame Type field is set to 3 |
| Frame Type | | |
| ACK ID | 18 | The ACK ID field is 18 bits in length and |
| | | computed based on RA, TA and |
| | | CRC fields of received NDP PS-Poll frame. |
| | | ACK ID[0:17] = RA[0:8] \|\| (CRC[0:3] \|\| |
| | | CRC[0:3] \|\| CRC[0]) XOR TA [0:8]), where RA, |
| | | TA and CRC fields are from received NDP |
| | | PS-Poll frame being acknowledged. |
| More Data | 1 | |
| Reserved | 3 | Set to 1 |

The NDP MAC frame body of NDP Modified ACK for >=2 MHz has the structure defined herein.

TABLE 11
NDP MAC frame body of NDP Modified ACK for (≧2 MHz)

| | Size | |
|---|---|---|
| Field | (bits) | Description |
| NDP MAC | 3 | NDP MAC Frame Type field is set to 3 |
| Frame | | |
| Type | | |
| ACK ID | 18 | The ACK ID field is 18 bits in length and computed |
| | | based on RA, TA and CRC fields of received NDP |
| | | PS-Poll frame. |
| | | ACK ID[0:17] = RA[0:8] \|\| (CRC[0:3] \|\| |
| | | CRC[0:3] \|\| CRC[0]) XOR TA[0:8]), where |
| | | RA, TA and CRC fields are from received NDP |
| | | PS-Poll frame being acknowledged. |
| More Data | 1 | |
| Duration | 1 | The Duration Indicate field is described in Table 8 |
| Indication | | |
| Duration | 16 | The Duration field is described in Table 8 |

In the following, more details an NDP ACK will be given.

NDP MAC frame body of NDP ACK frame may contain the information listed in Table 12 and Table 13. The NDP ACK frame used to respond to all frames other than a NDP PS-Poll frame will be described in the following.

The NDP MAC frame body of NDP ACK for 1 MHz may have the structure defined in Table 12.

TABLE 12
NDP MAC frame body of NDP ACK (1 MHz)

| | Size | |
|---|---|---|
| Field | (bits) | Description |
| NDP MAC | 3 | NDP MAC Frame Type field is set to 2 |
| Frame | | |
| Type | | |
| ACK ID | 9 | The ACK ID field is computed based on the partial |
| | | FCS and the information from the scrambling seed in |
| | | the SERVICE field of the frame being acknowledged |
| | | for the computation of the ACK ID for NDP ACK frame. |
| | | ACK ID[0:8] = FCS[0:8] XOR (Service[0:6] \|\| |
| | | Service[0:1]), where FCS and Service fields are from |
| | | the received frame that elicited the NDP ACK frame. |
| | | Service field is obtained before descramble. |
| More Data | 1 | |
| Duration | 1 | It is used to indicate whether the duration is the time of |
| Indication | | no data transmission (i.e., wakeup timer or flow |
| | | suspend duration) for the STA (Duration Indication = |
| | | 1) or the channel access reservation time following |
| | | current NDP ACK (Duration Indication = 0). |
| Duration | 10 | The Duration field is used to indicate either the period |
| | | of time, starting from the end of the current frame |
| | | transmission, that there will be no data transmission for |
| | | the STA being acknowledged if Duration Indication is |
| | | set to 1, or the duration for all frames transmitted |
| | | during CP, and under HCF for frames transmitted |
| | | during the CFP, if Duration Indication is set to 0. The |
| | | time unit for the case of Duration Indication set to 1 is |
| | | 1 millisecond, for the case of Duration Indication set to |
| | | 0 is 40 microsecond. |
| | | Duration Indication = 0 and Duration = 0 indicates No |
| | | Response; Duration Indication = 1 and Duration = 0 indicates |
| | | Long Response. |
| Relayed | 1 | The Relayed Frame field when set to 1 indicates the |
| Frame | | STA starts the transmission for TXOP sharing or a |
| | | Flow Suspend duration for the recipient STA to stop |
| | | further data frames for a flow control if the Duration |
| | | Indication field is set to 1 and the Duration field is a |
| | | nonzero valid value. |

The NDP MAC frame body of NDP ACK for >=2 MHz may have the structure defined in Table 13.

TABLE 13
NDP MAC frame body of NDP ACK (≧2 MHz)

| | Size | |
|---|---|---|
| Field | (bits) | Description |
| NDP MAC | 3 | NDP MAC Frame Type field is set to 2 |
| Frame | | |
| Type | | |
| ACK ID | 16 | The ACK ID field is computed based on the partial |
| | | FCS and the information from the scrambling seed |
| | | in the SERVICE field of the frame being |
| | | acknowledged for the computation of the ACK ID |
| | | for NDP ACK frame. |
| | | ACK ID[0:15] = FCS[0:15] XOR (Service[0:6] |
| | | \|\|Service[0:6] \|\|Service[0:1]), where FCS and |
| | | Service fields are from the received frame that |
| | | elicited the NDP ACK frame. Service field is |
| | | obtained before descramble. |
| More Data | 1 | |
| Duration | 1 | The Duration Indication field is described as in NDP |
| Indication | | ACK frame (1 MHz). |
| Duration | 14 | The Duration field is described in as in NDP ACK |
| | | frame (1 MHz). |
| Relayed | 1 | The Relayed Frame field is described in as in NDP |
| Frame | | ACK frame (1 MHz). |
| Reserved | 1 | Set to 1 |

In the following, NDP Modified ACK will be described.

NDP MAC frame body of NDP Modified ACK frame may contain the information listed in Table 14 and Table 15. The NDP Modified ACK frame used to respond to a NDP PS-Poll frame is described in this sub-clause.

The NDP MAC frame body of NDP Modified ACK for 1 MHz may have the structure defined in Table 14.

TABLE 14
NDP MAC frame body of NDP Modified ACK (1 MHz)

| | Size | |
|---|---|---|
| Field | (bits) | Description |
| NDP | 3 | NDP MAC Frame Type field is set to 3 |
| MAC | | |
| Frame | | |
| Type | | |
| ACK ID | 18 | The ACK ID field is computed based on RA, TA and |
| | | CRC fields of received NDP PS-Poll frame. ACK ID |
| | | is the bit sequence of the concatenation of some or full |
| | | RA, TA and CRC field bits. For example, |
| | | ACK ID[0:17] = RA[0:4] \|\| CRC[0:3] \|\|TA [0:8], |
| | | where RA, TA and CRC fields are from the |
| | | received NDP PS-Poll frame that elicited the NDP |
| | | Modified ACK, \|\| is the bit concatenation operation. |
| More Data | 1 | |
| Duration | 1 | The Duration Indication field is described in as in |
| Indication | | NDP ACK frame (1 MHz). |
| Duration | 1 | The Duration field is described in as in |
| | | NDP ACK frame (1 MHz). |
| Reserved | 1 | Set to 1 |

The NDP MAC frame body of NDP Modified ACK for >=2 MHz may have the structure defined in Table 15.

TABLE 15
NDP MAC frame body of NDP Modified ACK (≧2 MHz)

| | Size | |
|---|---|---|
| Field | (bits) | Description |
| NDP | 3 | NDP MAC Frame Type field is set to 3 |
| MAC | | |
| Frame | | |
| Type | | |
| ACK ID | 18 | The ACK ID field is computed based on RA, TA and |
| | | CRC fields of received NDP PS-Poll frame. ACK |
| | | ID is the bit sequence of the concatenation of some |
| | | or full RA, TA and CRC field bits. For example, |
| | | ACK ID[0:17] = RA[0:4] \|\| CRC[0:3] \|\|TA [0:8], |
| | | where RA, TA and CRC fields are from the |
| | | received NDP PS-Poll frame that elicited the NDP |
| | | Modified ACK, \|\| is the bit concatenation operation. |
| More Data | 1 | |
| Duration | 1 | The Duration Indication field is described in as in NDP |
| Indication | | ACK frame (1 MHz). |
| Duration | 14 | The Duration field is described in as in |
| | | NDP ACK frame (1 MHz). |

When there is an upper limit of TXOP time, if the duration that is larger than this upper limit can be used as reserved cases as well. For the duration that is smaller than the smallest possible value (e.g. SIFS or SIFS+NDP ACK) can be used as reserved cases. Thus, the reserved cases of Duration field that are used for equivalent ACK Indication are indicated by the most or least significant bits of Duration field.

In another embodiment for equivalent ACK Indication, we can make use of the following reserved values to indicate equivalent ACK Indication for No Response and Long Response with unknown duration for early ACK indication. For example, Duration Indication=0 and Duration=0 indicates the equivalent ACK Indication of No Response and Duration Indication=1 and Duration=0 indicates the equivalent ACK Indication of Long Response with unknown duration.

In this case, the least significant bit of Duration is reserved for equivalent ACK Indication.

The reserved values that are smaller than or equal to floor (SIFS/TU) (where floor(x) is the floor function, indicating the largest integer not greater than x)) can be used to indicate other cases e.g. the following response frame is CTS (CTS-to-self). The reserved case may be extended to the duration that is smaller than (SIFS+NDP ACK)/TU, as the shortest frame length is NDP frame and SIFS is the shortest inter-frame space. For example of 1 MHz, if NDP frame is 6 OFDM symbols and each OFDM symbol is 40 microsecond, the shortest frame duration is 560 microsecond (taking into account the preamble which is 320 microsecond). Thus, if TU is 160 microseconds, we have four reserved cases 0, 1, 2 and 3. If (SIFS+NDP ACK)/TU is round up, we can have one more reserved value which is 4. In this case, the 2 least significant bit of Duration is reserved for equivalent ACK Indication when Duration Indication is set to 1.

In addition to the above embodiment for equivalent ACK Indication, we can also reverse the values of Duration field that are smaller than a minimum wakeup timer value and use them to indicate the equivalent ACK Indication. For example, if minimum wakeup timer is at least 2 with a time unit TU e.g. 1 millisecond, we can reserve the case of Duration=1 and Duration=1 as well to indicate e.g. the following immediate response frame is CF-End. In this case, the least significant bit of Duration is reserved for equivalent ACK Indication when Duration Indication is set to 1 when Duration Indication is set to 1.

Duration/NAV Setting for the normal frame in current 802.11 with Duration field still can follow the convention. When RTS/CTS or other protection mechanism for channel access protects a TXOP, even TXOP originator/holder transmits the frame with a short MAC header that has no Duration field for NAV setting, the TXOP responder can still set the Duration field in the response frame either NDP ACK or modified NDP ACK (wherein modified NDP ACK may be identical to NDP Modified ACK, which in turn may be identical to the short response frame to NDP PS-Poll) after receiving the eliciting frame as the MCS and length (number of the OFDM symbols or number of bytes, dependent on Aggregation bit in SIG field) in the SIG field of the eliciting frame can be used to determine the value of Duration field in the response frame. For example, if the remaining NAV before the transmission of the eliciting frame is X and the duration for eliciting frame is Y, the Duration field should be set as ceil((X-SIFS-Y)/TU), where TU is the time unit for Duration field when Duration Indication is 0 and ceil(x) is the ceiling function of x that is used to round up for the setting of Duration field/NAV. X, SIFS and Y are assumed with the same time unit. Otherwise, they should be converted before Duration field setting is set. Y is obtained by dividing the length of the eliciting frame by the data rate corresponding to the MCS value in the SIG field of the eliciting frame and round up the time unit used for Duration setting.

In the following, TXOP Termination for Speed Frame Exchange Using (NDP) ACK according to various embodiments will be described.

Assume that Duration field is available for NDP ACK/modified NDP ACK. One of the possible embodiments for equivalent ACK indication can be as follows.

Duration Indication=0 indicates there could be an immediate frame following NDP ACK/modified NDP ACK.
Duration=0 is equivalent to No Response (Ack Indication bits=10);
Duration=a reserved value<=floor(SIFS/TU) is equivalent to Long Response with unknown length/duration (Ack Indication bits=11), suitable for DATA without Duration field;
The value<floor(SIFS/TU) is reserved as STA is allowed to access the channel after SIFS
Duration>floor(SIFS/TU) is equivalent to long Response with known length/duration (Ack Indication bits=11) indicates TXOP for the transmissions following current NDP ACK/modified NDP ACK, suitable for DATA with Duration field.

Duration Indication=1 indicates that Duration field is a wakeup timer and there is no immediate frame following current NDP ACK/modified NDP ACK.

Duration=0 is equivalent to no sleep time.

NDP PS-Poll frame with UDI can be used as the first frame for speed frame change and is responded with modified NDP ACK or DATA:
If it is responded by modified NDP ACK, Duration field is set to
o) a reserved value for unknown length/duration case since AP doesn't know the STA's frame length;
o) Otherwise the value determined by Preferred MCS and UDI.

3^{rd} party STA upon receiving NDP ACK/modified NDP ACK, before next event, it can
defer for a duration=Duration field value in NDP ACK/modified NDP ACK*TU+aSIFSTime if Duration Indication=0 and Duration>SIFS/TU;
defer for a duration=aPPDUMaxTime+2*aSIFSTime if Duration Indication=0 and 0<Duration<=SIFS/TU;
defer aSIFSTime if Duration Indication=0 and Duration=0 or Duration Indication=1.

It is to be noted that aSIFSTime is 160 microseconds in 802.11ah and SIFS=aSIFSTime.

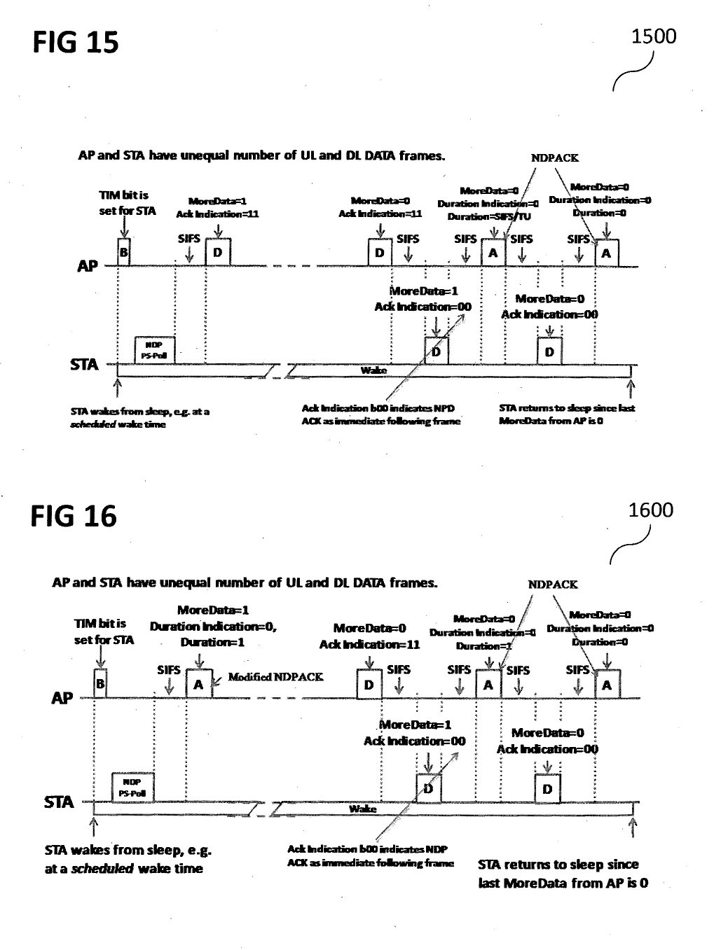

FIG. 15 shows an illustration 1500 with a station with UL and DL Data.

FIG. 16 shows an illustration 1600 with a station with UL and DL Data.

FIG. 15 and FIG. 16 illustrate two examples for speed frame exchange using (Modified) NDP ACK.

FIG. 15 illustrates an example that an non-AP TIM STA listens to the beacon and finds its TIM bit is set to 1 and then sends NDP PS-Poll to AP but UDI=0. AP responds with the buffered data from downlink delivery to the STA. During the speed frame exchange, upon there is no further DL frame to the STA, the AP will indicate More Data=0 in the last DL frame to the STA and the STA also sends uplink data frame to the AP by setting ACK indication to 00 (expecting NDP ACK from the AP) to acknowledge its reception of DL frame from the AR After that, AP sends NDP ACK by setting Duration Indication=0 and Duration=1 i.e. a reserved value to indicate a long response with unknown duration (if UL frame duration is unknown).

FIG. 16 illustrates another example that an non-AP TIM STA listens to the beacon and finds its TIM bit is set to 1 and then sends NDP PS-Poll to AP but UDI>0. AP responds with the Modified NDP ACK and indicates. More Data=0.1 and Duration Indication is set to 0 and Duration is set to 1 i.e. a reserved value to indicate a long response with unknown duration (if UL frame duration is unknown). If NDP PS-Poll with UDI>1 (for 2 MHz) and the non-AP STA sets UL frame duration in UDI, Duration Indication can be set to 0 and Duration can set to a known value in the responding Modified NDP ACK by the AP, since the AP may estimate or know both DL and UL frame duration (MCS is determined by the rule for the response frame).

TABLE 16
Equivalent ACK Indication

| Duration Indication | Duration | Description |
|---|---|---|
| 0 | 0 | Ack Indication = 10 (No response) |
| 0 | 1 | Ack Indication = 11 (long response, |
| | | unknown duration) |
| 0 | 2 | Ack Indication = 11(CF-End as the |
| | | Response with known duration) |
| 0 | 3 | TBD |
| 0 | 4 | TBD |
| 0 | >4 | Ack Indication = 11(long response, |
| | | known duration) |
| 1 | 0 | No sleep time |
| 1 | Nonzero | Wakeup timer |

In the following, TXOP Termination for Speed Frame Exchange using NDP ACK according to various embodiments will be described.

Assume that SIFS=160 μs and TU=40 μs for Duration field of NDP ACK when Duration Indication=0 (indicates Duration is the period of channel access reservation time for the frame transmission, for NAV setting). There are four reserved values 1, 2, 3, 4. For example, we can use 1 to indicate unknown long response, and use other values (i.e. 2, 3 and 4) to indicate the responses with known duration e.g. 2 is used to indicate CF-End. (see Table 11 for more details).

If TXOP holder knows there is no more data between itself and TXOP responder and it sends the last response frame (NDP ACK) before terminating current TXOP, it shall set Duration Indication to 0 and Duration to 0.

Otherwise, when the TXOP responder detects that More Data bit is set to 0 and/or EOSP=1 in the immediate previous received frame from the TXOP holder, and has no more data to transmit to TXOP holder, then the following method can be used, dependent on whether TXOP holder will terminate TXOP with CF-End after speed frame exchange is done. Whether TXOP holder will terminate TXOP with CF-End after speed frame exchange is finished or not can be setup as a rule, or negotiated during association (or other management exchange or explicit/implicit indication in speed frame exchange if possible).

If TXOP holder will terminate TXOP with CF-End after speed frame exchange is done, TXOP responder shall acknowledge by setting Duration Indication=0 and Duration=2 (or a reserved value to indicate CF-End is the following immediate response frame) in NDP ACK to indicate there will be an immediate CF-End frame following current NDP ACK. Other frame terminating TXOP may be possible. The Duration setting in the above suggests that the TXOP will be ended or truncated. A non-zero reserved value is set for Duration field to indicate there will be an immediate CF-End frame.

If TXOP holder will not terminate TXOP with CF-End after speed frame exchange is done (or no more data frame between TXOP holder and TXOP responder), then TXOP responder shall set Duration Indication is set to 0 and Duration is set to 0 (or a reserved value to indicate there is no immediate response frame) if TXOP responder knows there is no more immediate following frame. A rule should be set up to allow TXOP responder to release the channel access time if TXOP responder understands it can truncate the remaining channel access time.

In the following, TXOP Termination for Speed Frame Exchange using ACK according to various embodiments will be described.

If TXOP holder knows there is no more data between itself and TXOP responder and it sends the last response frame (ACK) before terminating current TXOP, it shall set Ack Indication to 10 (No Response) and Duration field to 0.

Otherwise, when the TXOP responder detects that More Data bit is set to 0 and/or EOSP=1 in the immediate previous received frame from the TXOP holder, and has no more data to transmit to TXOP holder, then the following method can be used, dependent on whether TXOP holder will terminate TXOP with CF-End after speed frame exchange is done. Whether TXOP holder will terminate TXOP with CF-End after speed frame exchange is finished or not can be setup as a rule, or negotiated during association (or other management exchange or explicit/implicit indication in speed frame exchange if possible).

If TXOP holder will terminate TXOP with CF-End after speed frame exchange is done, TXOP responder shall acknowledge by setting ACK Indication to 10 (No response) to indicate no response and Duration is set to a reserved value that is smaller than floor(SIFS/TU) to indicate there will be a frame terminating TXOP. For example, if SIFS=160 μs and TU=40 μs for Duration field, then there are 4 reserved values i.e. 1, 2, 3 and 4. The Duration setting in the above suggests that the TXOP will be ended or truncated. Ack Indication of ACK is set to 10 (No response) but a non-zero reserved value is set for Duration field of ACK to indicate there will be an immediate CF-End frame following current ACK.

Whether TXOP holder will terminate TXOP with CF-End after speed frame exchange is finished or not can be setup as a rule, or negotiated during association (or other management exchange or explicit/implicit indication in speed frame exchange if possible).

If TXOP holder will terminate TXOP with CF-End after speed frame exchange is done (or no more data frame between TXOP holder and TXOP responder), then the above given method can be used.

If TXOP holder will not terminate TXOP with CF-End after speed frame exchange is done, then TXOP responder shall set AckIndication=10 (No response) and Duration is set to a value equal to ACK Time+SIFS (or a reserved value to indicate there will be no immediate following response frame). A rule should be set up to allow TXOP responder to release the channel access time if TXOP responder understands it can truncate the remaining channel access time.

For TXOP truncating for speed frame exchange using either NDP ACK or ACK, if 3^{rd} party STA receives (NDP) ACK that indicates there will an immediate CF-End frame following current (NDP) ACK to terminate current TXOP, 3^{rd} party STA may defer channel access until the duration corresponding to (NDP) ACK+2*SIFS or receive CF-End to confirm the termination of TXOP.

In the following, a relay protocol according to various embodiments will be described.

In the following, relay flow control according to various embodiments will be described.

To suspend frame transmissions to Relay, a Relay may send a unicast or broadcast Relay Flow Suspend action frame, and Suspend Duration>0.
STAs may not transmit data frames to the STA addressed in the TA for the amount of time indicated in Suspend Duration field.
STAs may resume normal procedure for data frame transmission when the Suspend Duration time has expired.

To restart frame transmissions to Relay, a Relay may send a unicast or broadcast Relay Flow Resume action frame.
STAs may cancel the flow suspend time, and resume normal procedure for data frame transmissions to the STA addressed in the TA.
The sending of Relay Flow Resume action frame by the Relay is optional, and may be used by the Relay to cancel an existing Suspend Duration.

In R.4.5.C of IEEE 802.11-1137-15-00ah-specification-framework-for-tgah, Mingyong Park, “IEEE 802.11ah Specification Framework” (which may be referred to as the “draft specification” herein), the draft specification may define a flow control mechanism at the relay.
To suspend frame transmissions to Relay, a Relay may send a unicast or broadcast Relay Flow Suspend action frame, and Suspend Duration>0:
   STAs may not transmit data frames to the STA addressed in the TA for the amount of time indicated in Suspend Duration field;
   STAs may resume normal procedure for data frame transmission when the Suspend Duration time has expired.
To restart frame transmissions to Relay, a Relay may send a unicast or broadcast Relay Flow Resume action frame:
   STAs may cancel the flow suspend time, and resume normal procedure for data frame transmissions to the STA addressed in the TA;
   The sending of Relay Flow Resume action frame by the Relay is optional, and may be used by the Relay to cancel an existing Suspend Duration.
The draft specification may define a 1-bit field in FC (Frame Control) field in one of the S1G control response frame which includes a time field for Relay flow control signaling. S1G may mean Sub-1 Giga hertz. This is the term for 802.11ah as its operating frequency is below 1 GHz, different from the current WLAN (802.11a/b/g/n) operating at 2.4/5 GHz. Alternatively, S1G may be referred to as IEEE 802.11ah.

When a Relay receives a valid frame, the Relay may respond with:
An Implicit ACK in next-hop transmission after SIFS, if Relay has received Relayed Frame bit set to 1;
An ACK after SIFS with Relayed Frame bit set to 1, and continue with next-hop DATA transmission after SIFS;

An ACK after SIFS with Relayed Frame bit set to 0, and does not continue to use the remaining TXOP.

A relay may set Relayed Frame bit to 1 only if it has received a More. Data bit set to 0.

The above may be provided for relay flow control and TXOP sharing for two-hop Relay.

According to various embodiments, the Duration Indication and Duration field of NDP ACK issued by the Relay upon receiving the frame to be relayed may be redefined, i.e. Duration Indication=(equal to) 1 may indicate the Duration subfield value equal to a Suspend Duration in the response NDP ACK frame issued by the Relay. This definition implies that Duration for NAV setting or deferred channel access is 0 for the STA receiving the NDP ACK frame with a Suspend Duration indication.

To suspend frame transmissions to Relay, a Relay may send a unicast or broadcast NDP ACK, by setting Duration Indication to 1 to indicate a valid non-zero Suspend Duration that is indicated by the Duration field of NDP ACK, STAs shall not transmit data frames to the STA with the matching ACK ID for the amount of time indicated in Duration field of NDP ACK. STAs may resume normal procedure for data frame transmission when the amount of time as indicated in Duration field of NDP ACK has expired.

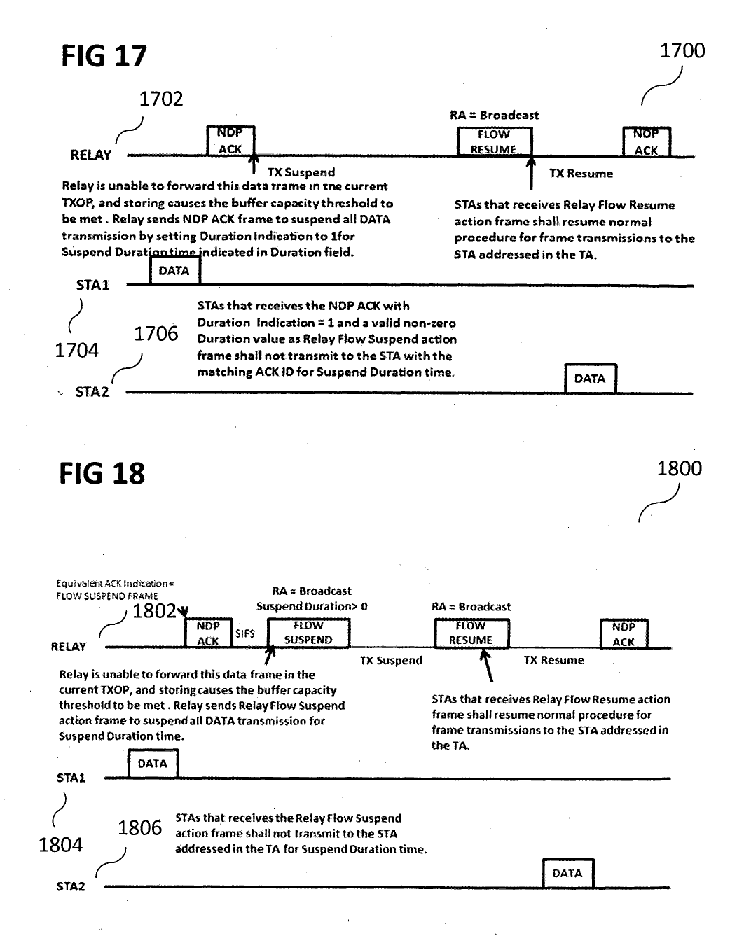

FIG. 17 shows an illustration 1700 of an example of the relay flow control indication according to various embodiments. Processing of a relay 1702, processing of a first station 1704 (STA1), and processing of a second station 1706 (STA2) are shown. As shown in FIG. 14, the STA1 with the data frames may stop the further transmission for a duration (as indicated in Duration field of NDP ACK) after receiving the response frame NDP ACK with Relayed Frame field set to 1 and Duration Indication set to 1, from the RELAY. The STA1 may resume the suspended transmission to the RELAY after the flow suspend duration expires and/or it received the FLOW RESUME frame from the RELAY.

To restart frame transmissions to Relay, a Relay may send a unicast or broadcast NDP ACK, by setting Duration Indication=0 to indicate a Resume Normal Procedure Action can be done, STAs may start to transmit data frames to the STA with the matching ACK ID.

According to various embodiments, an equivalent broadcast address for NDP ACK may be defined, for example ACK ID=all 1's or all 0's or a reserved case defined as broadcast address.

If the ACK ID computation results are identical to the broadcast address for NDP ACK, there is an ambiguity on whether the responding NDP ACK frame is for the frame to be relayed.

The Relayed Frame field of NDP ACK may be set to 1 to differentiate the following two cases (Alternatively, the Relay may determine whether it is the recipient STA of the received frame by checking the information (e.g. Address 1 and/or Address 2) in the MAC header.):
If the frame is sent to the Relay but not for relaying, Relayed Frame field of NDP ACK is set to 0. In this case, Duration Indication=1 and Duration=a valid nonzero value indicates a wakeup timer for the STA.
If the frame is sent to the Relay for relaying, Relayed Frame field of NDP ACK is set to 1. In this case, Duration Indication=(is equal to) 1 and Duration=(is equal to) a valid nonzero value indicates a Suspend Duration for the STA.

NDP ACK includes Duration Indication and Duration field. The usage of the Duration Indication and Duration fields of NDP ACK may be defined for the Relay flow control when Relayed Frame field of NDP ACK is set to 1: Duration Indication=1 indicates a Suspend Duration in the response NDP ACK frame by the Relay. To suspend frame transmissions to Relay, a Relay may send a NDP ACK, by setting both Relayed frame and Duration Indication fields to 1 to indicate a valid non-zero Suspend Duration that is indicated by the Duration field of NDP ACK, the STA may not transmit data frames to the Relay or the amount of time indicated in Duration field of NDP ACK. The STA may resume normal procedure for data frame transmission when the amount of time as indicated in Duration field of NDP ACK has expired.
A Relay AP may set both the Relayed Frame and Duration Indication fields to 1 and Duration field to a nonzero value equal to Flow Suspend duration in the response NDP ACK frame to request the STA that elicited the response to stop transmitting any data frames to the Relay AP. The Duration field of NDP ACK frame indicates the duration of time STAs are not permitted to transmit data frames to the Relay AP.
A STA that elicited the response receives an NDP ACK frame that has a matching ACK ID field and both the Relayed Frame and Duration Indication fields set to 1 shall not transmit any data frames to the AP for the amount of time indicated in the Duration field that is a nonzero value.
A STA may resume regular channel access procedure to transmit data frames addressed to the Relay AP after the expiration of the time indicated in the Duration field of NDP ACK frame.

Flow Control may be extended to a general case of data frame transmission between two STAs. Flow Control field may be included in NDP ACK frame. Upon receiving the data frame, the responding STA may set the both Flow Control and Duration Indication fields to 1 and the Duration subfield to a nonzero value equal to Flow Suspend duration in the response frame NDP ACK to indicate the Flow Suspend duration such that the STA that elicited the response frame is not allowed to transmit to the responding STA. If Relayed Frame field is set to 1, the responding STA is a Relay; otherwise the responding STA is a non-Relay STA.
An AP may set the Flow Control field to 1, the Duration Indication field to 1 and Duration field to a nonzero value equal to Flow Suspend duration in the response NDP ACK frame to request the STA that elicited the response to stop transmitting any data frames to the AP. The Duration field of NDP ACK frame indicates the duration of time STAs are not permitted to transmit data frames to the AP.
A STA that elicited the response receives an NDP ACK frame that has a matching ACK ID field and both the Flow Control and Duration Indication fields set to 1 shall not transmit any data frames to the AP for the amount of time indicated in the Duration field that is a nonzero value.
A STA may resume regular channel access procedure to transmit data frames addressed to the AP after the expiration of the time indicated in the Duration field of NDP ACK frame.

The alternative option to implement the flow control may be as follows:

Upon receiving the data frame, the responding STA may set the Duration Indication field to 1 and the Duration field to a reserved value for the indication of the response frame being FLOW SUSPEND in the response frame NDP ACK to indicate the inactivity duration during which the STA that elicited the response frame is not allowed to transmit to responding STA. The FLOW SUSPEND frame is transmitted SIFS after receiving NDP ACK by the STA which elicited the response frame. An advantage of this embodiment is that the responding STA will send out the FLOW SUSPEND frame SIFS after it transmits NDP ACK. In this case, the responding STA is not required to contend the channel access DIFS and if necessary, some back-off time after transmitting the response frame, which reduces the waiting time of the STA which elicited the response frame. It is to be noted that the STA eliciting the response frame may go to sleep without receiving the flow control signaling if the responding STA does not indicate in the preceding frame exchange.

FIG. 18 shows an illustration 1800 of an example of an alternative option for relay flow control indication. Processing of a relay 1802, processing of a first station 1804 (STA1), and processing of a second station 1806 (STA2) are shown. In the example shown in FIG. 18, the STA1 eliciting the response frame may stop the further transmission for a duration equal to Suspend Duration (as indicated in FLOW SUSPEND frame) after receiving the FLOW SUSPEND frame from the RELAY. The FLOW SUSPEND frame may be transmitted by the RELAY SIFS (Short Interframe Spacing) after the reception of NDP ACK with equivalent ACK Indication equal to the FLOW SUSPEND frame (for example assuming that there are some reserved values that can be used for such equivalent ACK Indication. For example, we may use Duration Indication=0 and Duration=1 to indication the following response frame is FLOW SUSPEND frame). The STA1 may resume the suspended transmission to the RELAY after the flow suspend duration expires and it received the FLOW RESUME frame from the RELAY.

In the following, TXOP sharing for two-hop relay according to various embodiments will be described.

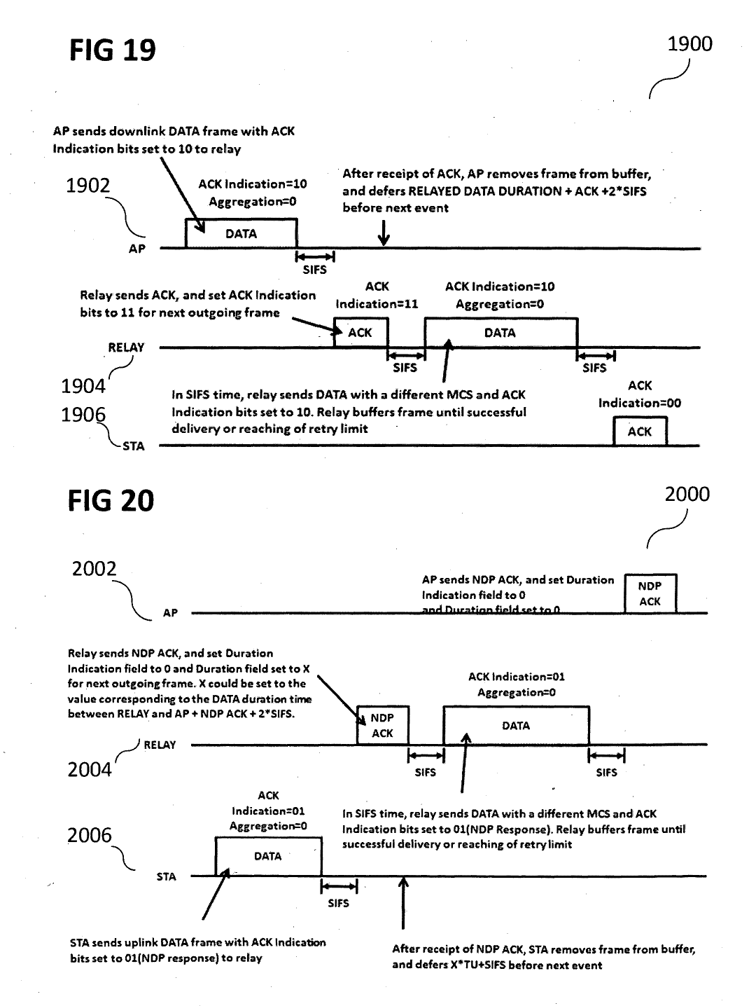

FIG. 19 shows an illustration 1900 of the Downlink TXOP sharing for two-hop Relay with Explicit ACK, wherein processing of an AP 1902, a RELAY 1904, and a STA 1906 are shown, and where after AP 1902 transmits DATA to the RELAY 1904 and receives ACK from the RELAY 1904, AP 1902 removes frame from buffer and defers some time X before next event or until a valid PHY-RXSTART.indication, whichever comes first. If X is set to MAX_PPDU+ACK+2*SIFS, the deferred time setting is not accurate as RELAY can calculate the correct duration to be included in ACK, even for DATA without Duration field (e.g. DATA with a short MAC header), simply based on the information in SIG field of DATA frame such as LENGTH/DURATION (which is the number of symbols when aggregation is 1, is in number of bytes when aggregation is 0, Mandate AMPDU for packet sizes>511 bytes and for MU). The Duration setting and/or deferred time to next event is subject to TXOP constraint (they can't go beyond TXOP).

According to various embodiments, devices and methods may be provided wherein after AP transmits DATA to the RELAY and receives ACK (Duration field is set to X) from the RELAY, AP removes frame from buffer and defers before next event a time of (X*TU−ACK−SIFS) where TU is time unit for Duration field of ACK and ACK indicates ACK frame duration time before next event, or until a valid PHY-RXSTART.indication, whichever comes first. If NDP ACK/NDP Modified ACK is used, the deferred time is the duration value equal to X*TU−NDP ACK−SIFS. If DATA is a baseline (802.11-2012) frame format with Duration/ID field, the Duration field setting in AP for DATA frame is based on the data rate between AP and RELAY as well as RELAY and STA. X can also be set according to DATA transmission time between RELAY and STA for the relayed DATA frame+ACK+2*SIFS for the case of using ACK. The similar approach applies to the case of using NDP ACK/NDP Modified ACK. This change may improve the accuracy of NAV setting or deferred channel access time for the STA. The unintended STA is able to set an accurate NAV or deferred channel access time so that it may be able to save the power further. The above method is also valid for uplink TXOP sharing for two-hop relay.

If DATA is without Duration field (e.g. DATA is with a short MAC header) but with LENGTH/DURATION in PHY SIG field, the LENGTH/DURATION in SIG field and data rate between RELAY and the intended receiver can be used to determine the Duration field value of ACK sent by RELAY. In downlink TXOP sharing for two-hop relay, after AP transmits DATA to the RELAY and receives ACK (Duration field is set to X) from the RELAY, AP removes frame from buffer and defers before next event for a time of (X*TU−ACK−SIFS) where TU is time unit for Duration field of ACK and ACK indicates ACK frame duration time, or until a valid PHY-RXSTART.indication, whichever comes first. If NDP ACK/NDP Modified ACK is used, the deferred time is the Duration field value of the transmitted DATA−NDP ACK−SIFS. The Duration field setting in RELAY for ACK is based on the data rate between RELAY and STA and the information on LENGTH/DURATION in PHY SIG fields. X should be set according to DATA transmission time between RELAY and STA for the relayed DATA frame+ACK+2*SIFS. The similar approach applies to NDP ACK/NDP Modified ACK.

FIG. 20 shows an illustration 2000 of uplink TXOP sharing for two-hop Relay using NDP ACK according to various embodiments. Processing of an AP 2002, a RELAY 2004, and a STA 2006 are shown.

According to various embodiments, devices and methods may be provided which use NDK ACK/NDP Modified ACK in the TXOP sharing for two-hop relay procedure to further improve the efficiency. FIG. 17 illustrates an example of uplink TXOP sharing for two-hop relay with Explicit ACK using NDP ACK. The usage of Duration Indication and Duration fields for NDP ACK/NDP Modified ACK can be seen in Table 17. The NDP (Modified) ACK frame with the reserved value for the Duration field that is smaller than SIFS/TU can be used to indicate other NDP frames (e.g. when Duration Indication is set to 0). TU is the unit for the duration of the transmission when the Duration Indication is set to 0. When SIFS is 160 millisecond and TU is 40 millisecond, there are 3 reserved values (1, 2, 3) that can be used to indicate other NDP frames. A NDP (Modified) ACK with the Duration Indication field set to 0 and the Duration field set to 1 can be used to indicate a null data packet of CF-End that is used to truncate the TXOP. In this case, ACK ID of this NDP frame can be computed as if the transmitter were the intended recipient. Alternatively, ACK ID of this NDP frame can be computed based on the partial AID (PAID) of the transmitter STA or the partial BSSID of the AP with which the transmitter STA is associated. The intended receiver should regard this special NDP frame as the truncation of the current TXOP. 3^{rd} party STA should regard this special NDP frame as a CF-End frame.

TABLE 17
Duration Indication and Duration fields for Equivalent ACK Indication

| Duration Indication | Duration | Description |
|---|---|---|
| 0 | 0 | ACK Indication = No |
| | | Response, which means there |
| | | will no response frame. |
| 1 | 0 | ACK Indication = Long |
| | | Response, which means there |
| | | will be a data frame with |
| | | unknown duration as the long |
| | | response. |

In the example shown in FIG. 17, the STA 1702 may send DATA with ACK Indication field value set to NDP Response firstly to RELAY and receives from RELAY an NDP ACK where Duration Indication field is set to 0 (i.e. indicating Duration field is for the Duration for the frame transmission time), Duration field is set to X, i.e. the duration value corresponding to either the DATA duration time between RELAY and AP+2*SIFS+NDP ACK or the duration value corresponding to the Duration/ID field of received DATA−NDP ACK−SIFS. It is to be noted that the duration of NDP ACK should consider the rounding effect as the Duration field of NDP ACK may have a larger time unit than data frame or other frame with Duration for NAV setting or deferred channel access time. Upon receipt of NDP ACK, after SIFS the STA 1706 may remove frame from buffer and defers X*TU-NDP ACK-SIFS before next event, or until a valid PHY-RXSTART.indication, whichever comes first. Immediately after NDP ACK, RELAY sends DATA with a different MCS and ACK Indication field set to NDP Response. Relay buffers frame until successful delivery or reaching of retry limit. Upon receiving the DATA from RELAY, AP sends NDP ACK with Duration Indication field set to 0 (i.e. indicating Duration field is for the Duration for the frame transmission time), Duration field set to 0 (i.e. indicating no immediate following frame after NDP ACK, equivalent to ACK Indication set to No Response). Table 17 shows the Duration Indication and Duration fields for Equivalent ACK Indication in NDP ACK/NDP Modified ACK.

In the example shown in FIG. 17, the STA 1702 may send DATA with ACK Indication field value set to NDP Response and Relayed Frame field set to 1 firstly to RELAY and receives from RELAY an NDP ACK where Duration Indication field is set to 1 and Duration field is set to 0 to indicate Long Response. Immediately after NDP ACK, RELAY sends to AP the DATA with ACK Indication field set to NDP Response.

In the example shown in FIG. 17, when the STA 1702 may send DATA with ACK Indication field value set to Long Response and Relayed Frame field set to 1 firstly to RELAY. SIFS after receiving DATA, RELAY may not respond with an NDP ACK and may forward to AP the received DATA frame with ACK Indication field set to NDP Response.

In the above procedure of TXOP sharing for two-hop Relay, the STA that transmitted the data frame for relaying elicited the response from the Relay may set its NAV or deferred channel access time and/or RID value properly.

For the case of frame transmission with Duration, the STA may set a correct RID value when ACK_INDICATION of the received frame is 3. For example shown in FIG. 16, when the AP receives the ACK from the Relay and also the SIG field of the relayed frame, it may derive the accurate NAV or deferred channel access time and/or RID value based on LENGTH and MCS subfield of SIG field of the received frame. Therefore, instead of using MAX_PPDU+ACK+2*SIFS for deferred time setting upon receipt of ACK with ACK Indication field equal to Long Response from the RELAY, AP may set the NAV or deferred channel access time based on the Duration field of ACK that is set to DATA transmission time between RELAY and STA for the relayed DATA frame+ACK+2*SIFS and reset the RID value to zero.

For example shown in FIG. 17, when the STA receives the NDP ACK from the Relay, it may derive the accurate NAV or deferred channel access time and/or RID value based on Duration subfield of the received NDP ACK frame. Therefore, instead of using MAX_PPDU+NDP ACK+2*SIFS for deferred time setting upon receipt of NDP ACK with ACK Indication equal to Long Response from the RELAY, STA may set the NAV or deferred channel access time based on the Duration subfield of NDP ACK that is set to DATA transmission time between RELAY and AP for the relayed DATA frame+NDP ACK+2*SIFS and reset the RID value to zero.

Therefore, the Duration for NAV setting and NAV and RID update rule in TXOP sharing for two-hop relay is as follows:

In response to the relayed frame, the relay STA may set Duration to the transmission time between the relay and the next hop STA for the relayed frame that elicited the response.

The STA that elicited the response from the relay may set the NAV based on the Duration field of the response frame+the response (NDP ACK or ACK)+2*SIFS and reset the RID value to zero.

Whether to proceed with TXOP sharing for two-hop relaying, we may setup the following rule:

When AP is busy in transmission or other operation (NAV counter is nonzero), the Relay is not able to forward to the AP the frame received from the non-AP STA if the Relay has its nonzero NAV counter. Similarly, when a non-AP STA is busy in transmission or other operation (NAV counter is nonzero), the Relay is not able to forward to the non-AP STA the frame received from the AP if the Relay has its nonzero NAV counter. In this situation, the Relay may respond with (NDP) ACK with equivalent ACK INDICATION value or ACK_INDICATION set to No Response to stop TXOP sharing for two-hop relaying. The Relay shall not update its NAV counter when it receives the frame for TXOP sharing for two-hop relaying.

Another embodiment may be as follows:

A non-AP STA starts a frame exchange by sending a Short Data frame addressed to the relay STA with the TXVECTOR parameter ACK_INDICATION (assume that the TXVECTOR parameter ACK_INDICATION is the defined parameter that is used to indicate the response frame) set to NDP Response. The relay STA may set the Duration Indication field to 1 and Duration field to 0 in the NDP ACK frame that is transmitted to the non-AP STA to indicate Long Response. In addition it shall set the Relayed Frame field of the NDP ACK frame to 1.

When the direction of the frame is from the AP to the non-AP STA, the AP starts a frame exchange by sending a Short Data frame addressed to the relay STA with the TXVECTOR parameter ACK_INDICATION set to NDP Response. The relay STA shall set the Duration Indication field to 1 and the Duration field to 0 in the NDP ACK frame that is transmitted to the AP to indicate Long Response. In addition it may set the Relayed Frame field of the NDP ACK frame to 1.

In the following, ACK indication and NAV setting for speed frame exchange and TXOP will be described.

After a successful reception of a frame requiring acknowledgment, transmission of the (NDP) ACK frame shall commence after a SIFS, without regard to the busy/idle state of the medium. However, whether or not to continue the speed frame exchange may be based on the NAV setting in the STA.

For whether to proceed with speed frame exchange, we may setup the following rule:

If the responding STA receives a frame (e.g. short data frame without Duration field in MAC header) from its peer STA in speed frame exchange with ACK_INDICATION set to 3 (i.e. Long Response) in RXVECTOR parameter, if NAV counter is nonzero due to the other reception that it has received at the earlier time, the responding STA shall not transmit a data frame as the response frame (i.e. Long Response). Instead, the responding STA may transmit an NDP ACK with an (equivalent) ACK INDICATION value equal to 0 (No Response) or transmit an ACK with ACK_INDICATION field set to 0 (No Response) to stop further frame exchange. The responding STA may not update its NAV counter upon receiving the frame for speed frame exchange.

In the following, NAV and equivalent ACK Indication setting for Speed frame exchange (SF) will be described.

If NDP ACK is used as the immediate response frame by the responding STA for the preceding frame that elicited the response in SF,
when the preceding frame has More Data set to 0 and ACK Indication set to NDP response, if NDP ACK has More Data set to 1 (i.e. the responding STA has buffered frame to the STA that elicited the response), the responding STA shall set equivalent ACK Indication to Long Response in the immediate response NDP ACK frame;
when the preceding frame has More Data set to 0 and ACK Indication set to NDP response, if NDP ACK has More Data set to 0 (i.e. the responding STA has no buffered frame to the STA that elicited the response), the responding STA shall set equivalent ACK Indication to No Response in the immediate response NDP ACK frame.

In the following, SF (speed frame) using NDP frames (1 MHz) will be described.

When 1 MHz NDP PS-Poll is used, as there is no Duration field in 1 MHz NDP PS-Poll, there may be the question what ACK Indication field value shall the response frame set. It may be dependent on whether the response frame is DATA or NDP Modified ACK.

If UDI is set to 0 or 1 in NDP PS-Poll, when the response frame is DATA, ACK Indication field value may be set to any value. If UDI=0, ACK Indication=1 (NDP ACK) or 2 (ACK). If UDI=1, ACK Indication is set to 3 (Long Response). Duration field of DATA can be set to SIFS+NDP ACK (1 MHz). The duration of NDP ACK should consider the rounding effect.

For SF,

1. If UDI is set to 1 in NDP PS-Poll, when the response frame is NDP Modified ACK, a reserved value equivalent to ACK Indication=Long Response shall be set. If the duration for UL transmission can be predicted, AP may set the Duration field for NAV setting.

2. If UDI is set to 0 in NDP PS-Poll, when the response frame is NDP Modified ACK, a value equivalent to ACK Indication=No Response shall be set if there is no buffered frame delivery to the STA from an AP (More Data is set to 0 in NDP Modified ACK).

3. If UDI is set to 0 in NDP PS-Poll, when the response frame is NDP Modified ACK, a reserved value equivalent to ACK Indication=Long Response (e.g. Duration Indication=1 and Duration=0) shall be set if there is buffered frame delivery to the STA from an AP (More Data is set to 1 in NDP Modified ACK). However, a better method for NDP ACK frame is that Duration Indication shall be set to 0 and Duration shall be set to the value for NAV setting that covers the transmission of buffered frame delivery to the STA, i.e. buffered frame duration+SIFS.

However, if there is no speed frame exchange,

1. If UDI is set to 1 in NDP PS-Poll, when the response frame is NDP Modified ACK, a reserved value equivalent to ACK Indication=No Response shall be set if there is no buffered frame delivery to the STA from an AP (More Data is set to 0 in NDP Modified ACK). For RAW operation, the frame of NDP PS-Poll and NDP Modified ACK is finished within a small slot duration that does not allow the transmission of uplink data from STA to its AP. The uplink frame is scheduled in a different RAW that allows a larger slot duration.

2. If UDI is set to 0 in NDP PS-Poll, when the response frame is NDP Modified ACK, a reserved value equivalent to ACK Indication=No Response (e.g. Duration Indication=0 and Duration=0) shall be set if there is buffered frame delivery to the STA from an AP (More Data is set to 1 in NDP Modified ACK). The STA either shall keep awake if the buffered frame from AP will be delivered soon or can go to sleep if the buffered frame from AP will be delivered at a different schedule time that is known to the STA (e.g. the STA is aware of the RAW operation indicated in RPS IE and can identify its downlink data delivery).

In the following, SF using NDP frames (>=2 MHz) will be described.

When >=2 MHz NDP PS-Poll is used, as there is UDI with Duration value in NDP PS-Poll, what ACK Indication field value shall the response frame set? It is dependent on whether the response frame is DATA or NDP Modified ACK.

When UDI is a nonzero positive value, if the response frame is DATA, ACK Indication field value shall be set to 3 (Long Response) though the uplink data is known. If More Data field in DATA frame is set to 0, Duration field of DATA can be set to either UDI value (converted to the corresponding time unit)+SIFS or 0. If More Data field in DATA frame is set to 1, Duration field of DATA can be set to UDI value (converted to the corresponding time unit)+SIFS or Downlink data duration for next frame+UDI value (converted to the corresponding time unit)+2*SIFS.

If the response frame is NDP Modified ACK, a reserved value equivalent to ACK Indication=Long Response with known duration shall be set, e.g. Duration Indication=0 and Duration=UDI value (converted to the corresponding time unit)+SIFS or Downlink data duration+UDI value (converted to the corresponding time unit)+2*SIFS, since the uplink data duration is given by UDI field value of NDP PS-Poll.

For SF,

1. If UDI is set to a nonzero positive value in NDP PS-Poll, when the response frame is NDP Modified ACK, if UDI is a Duration value for NAV setting, Duration Indication is set to 0 and Duration is set to UDI value (converted to the corresponding time unit)+SIFS if there is no buffered frame delivery to the STA from an AP (More Data is set to 0 in NDP Modified ACK), or Downlink data duration+UDI value (the corresponding time unit)+2*SIFS if there is buffered frame delivery to the STA from an AP (More Data is set to 1 in NDP Modified ACK). Otherwise, if UDI is not a Duration value for NAV setting, Duration Indication is set to 1 and Duration is set to 0 (equivalent ACK Indication=Long Response) regardless of whether there is buffered frame delivery to the STA from an AP.

2. If UDI is set to 0 in NDP PS-Poll, when the response frame is NDP Modified ACK, a value equivalent to ACK Indication=No Response shall be set if there is no buffered frame delivery to the STA from an AP (More Data is set to 0 in NDP Modified ACK).

3. If UDI is set to 0 in NDP PS-Poll, when the response frame is NDP Modified ACK, Duration Indication is set to 0 and Duration is set to Downlink data duration+SIFS if there is buffered frame delivery to the STA from an AP (More Data is set to 1 in NDP Modified ACK).

However, if there is no speed frame exchange,

1. If UDI is set to a nonzero positive value in NDP PS-Poll, when the response frame is NDP Modified ACK, a reserved value equivalent to ACK Indication=No Response shall be set if there is no buffered frame delivery to the STA from an AP (More Data is set to 0 in NDP Modified ACK). For RAW operation, the frame of NDP PS-Poll and NDP Modified ACK is finished within a small slot duration that does not allow the transmission of uplink data from STA to its AP. The uplink frame is scheduled in a different RAW that allows a larger slot duration.

2. If UDI is set to 0 in NDP PS-Poll, when the response frame is NDP Modified ACK, a reserved value equivalent to ACK Indication=No Response (e.g. Duration Indication=0 and Duration=0) shall be set if there is buffered frame delivery to the STA from an AP (More Data is set to 1 in NDP Modified ACK). The STA either shall keep awake if the buffered frame from AP will be delivered soon or can go to sleep if the buffered frame from AP will be delivered at a different schedule time that is known to the STA (e.g. the STA is aware of the RAW operation indicated in RPS IE and can identify its downlink data delivery).

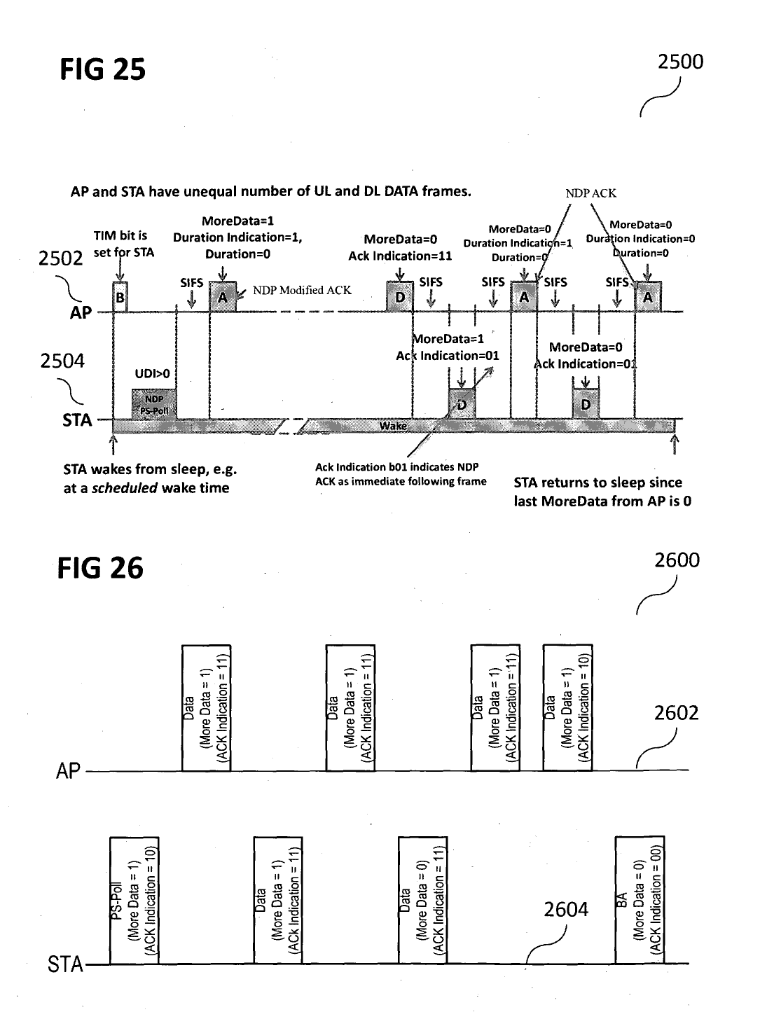

FIG. 25 shows an illustration 2500 of an example of speed frame exchange using NDP frames (i.e. NDP PS-Poll, NDP ACK and/or NDP Modified ACK) based on Table 17. Data processing 2502 of an access point (AP) and data processing 2504 of a station STA are shown. The station (non-AP STA or simply STA) may have uplink data to transmit to AP. Firstly, STA sends its NDP PS-Poll with UDI field in SIG set to 1 to indicate that it has buffered frame for the AP. Therefore the NDP Modified ACK frame is sent by the AP SIFS time after the reception of NDP PS-Poll, with the Duration Indication field set to 1 and the Duration field set to 0 to indicate Long Response. Upon receiving the NDP Modified ACK frame, the STA can transmit the buffered frame to the AP. After some frame exchange, when the AP sends Data frame with ACK_INDICATION (which is assumed to be a TXVECTOR parameter for the indication of the response frame, or a field in SIG field if there is such a field in SIG field to indicate the response frame) set to 11 (indicating a data frame as the long response) and More Data set to 0, the STA shall send Data frame with ACK_INDICATION set to 01 (indicating a NDP ACK frame as the response) and More Data set to 1 as it still has a buffered frame for the AP. When there is no more buffered frame for the STA at the AP, AP transmits an NDP ACK frame with the Duration Indication field set to 1 and the Duration field set to 0 to indicate Long Response. Once the STA sends its last Data frame with ACK_INDICATION set to 01 and More Data set to 0, the AP shall respond with an NDP ACK frame with the Duration Indication field set to 1 and the Duration field set to 0 to indicate No Response.

Speed frame (SF) exchange allows an AP and non-AP STA to exchange a sequence of uplink and downlink PPDUs separated by SIFS. This operation combines both uplink and downlink channel access into a continuous frame exchange sequence between a pair of STAs. The objective of this operation is to minimize the number of contention-based channel accesses, improve channel efficiency by reducing the number of frame exchanges, and reduce STA power consumption by shortening Awake times.

One of the various embodiments for the rule of speed frame exchange will be described in the following.

An AP may send any frame as the initial frame of a SF exchange. An AP may set the ACK Indication field of the PLCP signal field to Normal Response or NDP Response for the initial frame of a SF exchange.

A non-AP STA may send a trigger frame or a (NDP) PS-Poll frame as the initial frame of a SF exchange. A non-AP STA shall set the ACK Indication field of the PLCP Signal field to Long Response in a frame that initiates an SF exchange if the initial frame is not a NDP PS-Poll frame.

A STA sending an immediate response that is not an NDP frame to a frame that had the More Data field set to 1 shall set the ACK Indication field to Long Response. A STA sending an immediate response NDP (Modified) ACK frame to a frame that had the More Data field set to 1 shall set the Duration Indication field to 1 and Duration field to 0 to indicate Long Response or set the Duration field for NAV setting for a SF exchange.

A non-AP STA sending an immediate response that is an ACK frame or a BlockAck frame after receiving a frame that had the More Data field set to 0 shall set the ACK Indication field to No Response. A non-AP STA sending an immediate response NDP ACK frame after receiving a frame that had the More Data field set to 0 shall set the Duration Indication and Duration fields to 0 to indicate No Response.

An AP sending an immediate response that is an ACK frame or a BlockAck frame after receiving a frame that had the More Data field set to 0 shall set the ACK Indication field to Long Response if it will send a data frame SIFS time after the end of the immediate response transmission or No Response if it will not send a data frame SIFS time after the end of immediate response transmission. An AP sending an immediate response that is either an NDP ACK after receiving a frame that had the More Data field set to 0 or an NDP Modified ACK after receiving an NDP PS-Poll that had UDI field set to 0 shall set the Duration Indication and Duration fields to 0 to indicate No Response if it will not send a data frame SIFS time after the end of the NDP (Modified) ACK frame transmission, or the Duration Indication field to 1 and Duration field to 0 to indicate Long Response if it will send a data frame SIFS time after the end of the NDP (Modified) ACK frame transmission (1 MHz).

A STA that receives a frame with a unicast MAC address in the Address 1 field that matches its MAC address, or a unicast AID in the Address 1 field matching to its AID and a unicast MAC address in Address 2 field matching its AP's BSSID, or a NDP (Modified) ACK frame with a matching ACK ID within SIFS after the transmission of a frame accepts the reception as an acknowledgement for its immediately previous transmission.

A STA sending an immediate response that is not an NDP (Modified) ACK and has the More Data field set to 1 and the ACK Indication field set to Long Response shall transmit a frame to the STA that elicited the response, SIFS after the transmission of the response frame if the More Data field was set to 0 in the frame most recently received from the STA, and set the Duration field to an estimated time to protect the remaining transmissions if there is a Duration field in the response frame.

A STA sending an immediate response that is an NDP ACK frame and had the More Data field set to 1 shall transmit a frame to the STA that elicited the response, SIFS after the transmission of the response frame in which the Duration Indication field shall be set to 0 and the Duration field shall be set to an estimated time to protect the remaining transmissions if the More Data field was set to 0 in the frame most recently received from the STA in a SF exchange.

An AP sending an immediate response that is an NDP Modified ACK frame and has the More Data field set to 1 shall transmit a frame to the STA that elicited the response, SIFS after the transmission of the response frame in which the Duration Indication field shall be set to 0 and the Duration field shall be set to an estimated time to protect the remaining transmissions if the UDI field was set to 0 in the NDP PS-Poll frame (>=2 MHz) most recently received from the non-AP STA in a SF exchange.

A STA sending an immediate response that is not an NDP (Modified) ACK and had the More Data field set to 1 and the ACK Indication field set Long Response shall not transmit a frame to the STA that elicited the response, SIFS after the transmission of the response frame in which the Duration field shall be set to a value equal to the time that is set by the Duration field in the frame that elicited the response, minus aSFISTime and a duration for the response frame transmission if there is a Duration field in both the response frame and the frame that elicited the response, or if there is a Duration field in the response frame and there is a NAV setting in the beginning of TXOP, if the More Data field was set to 1 in the data frame most recently received from the STA in a SF exchange.

A STA sending an immediate response that is an NDP ACK frame shall not transmit a frame to the STA that elicited the response, SIFS after the transmission of the response frame in which the Duration Indication field shall be set to 0 and the Duration field shall be set to a value equal to the time that is set by the Duration field in the frame that elicited the response, minus aSFISTime and a duration for the response NDP ACK frame transmission if there is a Duration field in the frame that elicited the response or if there is NAV setting in the beginning of TXOP, if the More Data field was set to 1 in the data frame most recently received from the STA in a SF exchange.

An AP sending an immediate response NDP Modified ACK frame shall not transmit a frame to the STA that elicited the response, SIFS after the transmission of the response frame in which the Duration Indication field shall be set to 1 and the Duration field shall be set to 0 to indicated Long Response, if the UDI field was set to a nonzero value in the NDP PS-Poll frame most recently received from the non-AP STA in a SF exchange.

Without the setup of Block Ack, a STA shall not use (NDP) BA for a SF exchange. With the set up of Block Ack, in response to the received frame with the More Data field set to 0 from the other STA that elicited the response in a SF exchange, a STA sending an immediate response that is not an NDP (Modified) ACK and had the More Data field set to 1 and the ACK Indication field set to Long Response shall continue to transmit its frames, until the last frame with the More Data field set to 0 and the ACK Indication field set to either Normal Response to request a (NDP) BA frame or NDP Response to NDP Response to request a NDP ACK frame, SIFS time after each transmission of the response frame in which the Duration field shall be set to a value equal to the time that is set by the Duration field in the frame that elicited the response, minus aSFISTime and a duration for the response frame transmission if there is a Duration field in both the response frame and the frame that elicited the response, or if there is a Duration field in the response frame and there is a NAV setting in the beginning of TXOP.

A STA sending an immediate response with the More Data field set to 1 and the TXVECTOR parameter ACK_INDICATION set to No Response shall transmit a frame to the STA that elicited the response within the current TXOP, but not SIFS after the transmission of the response frame.

A STA either sending an immediate response that sets the More Data field 0 and the TXVECTOR parameter ACK_INDICATION set to No Response shall not transmit a frame within the current TXOP to the STA that elicited the response.

A non-AP STA shall remain in the Awake state until the end of the current TXOP if it receives a frame with the More Data field set to 1 from either the AP addressed to itself or a NDP ACK (Modified) frame with a matching ACK ID.

A non-AP STA may transition to the Doze state if it receives a frame with the More Data field set to 0 either from the AP addressed to itself or in a NDP (Modified) ACK frame with a matching ACK ID.

In a TXOP, in order to disallow the peer STA (e.g. B) sending data frame as the long response, a STA (e.g. A) may send its data frame with ACK_INDICATION set to NDP frame (or Normal Response) to solicit a NDP ACK (Normal ACK) as the response frame for its transmitted data frame. Even if STA B responds with a NDP ACK frame with the More Data field set to 1 to indicate that it has buffered frame for STA A, STA A may send its data frame with ACK_INDICATION set to NDP frame (or Normal Response) to continue to solicit a NDP ACK (or Normal ACK) frame instead of a data frame as the long response from STA B. This means the More Data field in the response frame transmitted by STA B is ignored by the TXOP holder/initiator (STA A). In this case, STA A continues to transmit its data frames without allowing the transmission of data frame from STA B as the response frame in the speed frame exchange.

When there are multiple frame transmissions for speed frame exchange in a TXOP that is limited by a value, the speed frame exchange may be stopped in order to limit the transmission within the TXOP limit. For example, when a data frame is requested as the long response frame, the responding STA may ignore the ACK_INDICATION setting in the received frame that elicited the response, and transmit a shorter response such as NDP ACK. In this NDP ACK frame, Duration Indication field is set to 0 and Duration field is set to 0, indicating there will no more frame transmission within this TXOP.

FIG. 26 shows an illustration 2600 of an example of speed frame exchange using normal frames (i.e. ACK, BA and Data). Data processing 2602 of an access point (AP) and data processing 2604 of a station STA are shown. The station (non-AP STA or simply STA) may have uplink data to transmit to AP. Firstly, STA sends its PS-Poll with the ACK_INDICATION field in SIG set to 11 and the More Data field in Frame Control field set to 1 to indicate that it has buffered frame for the AP. AP responds with Data frame with the ACK_INDICATION field in SIG set to 11 and the More Data field in Frame Control field set to 1 to indicate that it has buffered frame for the STA. After some frame exchange, the STA has no more data buffered for the AP and sends a Data frame with the ACK_INDICATION field in SIG set to 11 and the More Data field in Frame Control field set to 0. From then on, AP responds with the Data frame with the ACK_INDICATION field in SIG set to 11, which tells the STA that the AP will continue the frame transmissions without any acknowledgement from the STA. Once there is no more buffered frame for the STA, the AP sends the Data frame with the ACK_INDICATION field in SIG set to 10, which tells the STA to send an immediate BA frame.

In the following, duration and NAV setting for TXOP will be described.

Duration/NAV setting for the normal frame in current 802.11 with Duration field still can follow the convention.

When RTS/CTS or other protection mechanism for channel access protects a TXOP, even if TXOP holder transmits the frame with a short MAC header (i.e. Short Data frame), the TXOP responder can still set the Duration field in the response frame (e.g. NDP ACK) after receiving the frame because the MCS and LENGTH (number of the OFDM symbols or number of bytes, dependent on Aggregation bit in SIG field) in the SIG field of the frame can be used to determine the value of Duration field in the response frame.

If the remaining NAV before the transmission of the frame is X and the duration for the frame is Y, the Duration field should be set as ceil ((X-SIFS-Y)/TU), where TU is the time unit for Duration field when Duration Indication is 0 and ceil(x) is the ceiling function of x that is used to round up for the setting of Duration field and NAV. X, SIFS and Y are assumed with the same time unit. Otherwise, they should be converted before Duration field is set.

Y may be obtained by dividing the length of the frame by the data rate corresponding to the MCS value in the SIG field of the frame and round up the time unit used for Duration setting.

The above method can be used for TXOP with multiple frame transmissions.

In the following, TXOP truncation according to various embodiments will be described. In the following, changes to TXOP truncation according to various embodiments will be described.

If the CF-End frame is from an S1G AP STA, ACK Indication field should be set to No Response, as TXOP responder is an S1G non-AP STA, which is not allowed to respond with CF-End frame.

If the CF-End frame is from an S1G non-AP STA which is TXOP holder, ACK Indication should be set to either No Response or Long Response.
No Response indication may entice the 3^{rd} party STA to wake up and receive CF-End immediately after the frame, which wastes some energy.
Long Response indication may deprive the 3^{rd} party STA of the channel access due to early truncation of TXOP after CF-End frame is sent by S1G AP STA immediately following the CF-End frame.

According to various embodiments, S1G AP STA that is not a TXOP holder may not transmit CF-End after SIFS.

In the following, TXOP truncation for SF using NDP ACK according to various embodiments will be described.

When the TXOP responder detects that More Data bit is set to 0 in the immediate previous received frame from the TXOP holder, and has no more data to transmit to TXOP holder, if the condition (e.g. there is still a long reservation time left but not used) allows for TXOP truncation, TXOP responder shall acknowledge by setting Duration Indication=0 and Duration=a reserved case in NDP ACK to indicate there will be an immediate CF-End frame following current NDP ACK.

The Duration setting in the above suggests that the TXOP will be ended or truncated.

Whether TXOP holder will terminate TXOP with CF-End after speed frame exchange is finished or not can be setup as a rule, or negotiated during association (or other management exchange or explicit/implicit indication in speed frame exchange if possible).
If TXOP holder will terminate TXOP with CF-End after speed frame exchange is done, then the above method can be used.
If TXOP holder will not terminate TXOP with CF-End after speed frame exchange is done, then TXOP responder shall set Duration Indication is set to 0 and Duration is set to 0 (to indicate No Response).

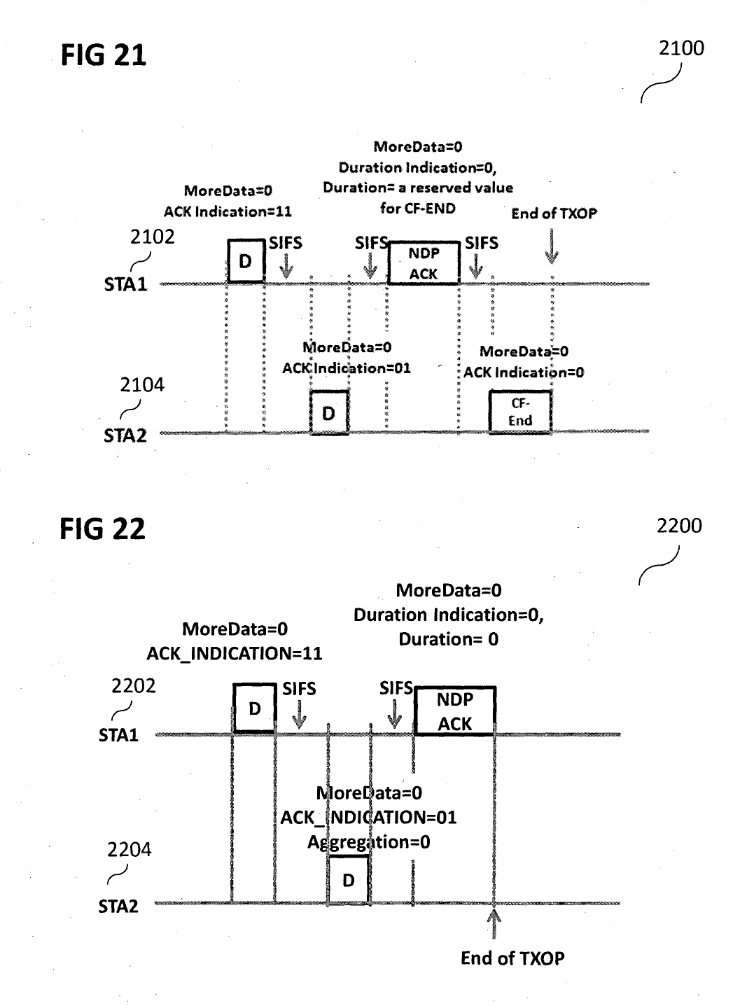

FIG. 21 shows an illustration 2100 of an example of EDCA (Enhanced Multimedia Distributed Control Access) TXOP Truncation for SF using NDP ACK and CF-End. Processing of a first station 2102 (STA1) and processing of a second station 2104 (STA2) are shown. FIG. 21 shows one example of EDCA TXOP truncation for speed frame exchange using NDP ACK. STA1 and STA2 indicate there are no more data for transmission by setting More Data field to 0. When STA1 uses NDP ACK as the response for the last data frame from STA2, it indicates there will be CF-End frame immediately follows NDP ACK and may set Duration field of NDP ACK to 0 or a value for NAV setting to protect the following frame i.e. CF-End. Thus, when STA2 receives the NDP ACK from STA1, it responds with CF-End to terminate TXOP. If STA1 is an AP STA, it can simply terminate the TXOP using NDP ACK, in which Duration Indication subfield is set 0 and Duration subfield is set to 0 to indicate there will no response. This is illustrated in the example shown in FIG. 22.

FIG. 22 shows an illustration 2200 of an example of EDCA TXOP Truncation for SF using NDP ACK. Processing of a first station 2202 (STA1) and processing of a second station 2204 (STA2) are shown.

In the following, TXOP truncation for SF using ACK according to various embodiments will be described.

When the TXOP responder detects that More Data bit is set to 0 in the immediate previous received frame from the TXOP holder, and has no more data to transmit to TXOP holder, TXOP responder shall acknowledge by setting ACK Indication to e.g. No Response or Normal Response (aggregation=1, BA=32 bytes) and Duration is set to cover the protection for CF-End i.e. CF-End+SIFS to indicate that the immediate response frame is CF-End frame that will be sent by TXOP holder.

Whether TXOP holder will terminate TXOP with CF-End after speed frame exchange is finished or not can be setup as a rule, or negotiated during association (or other management exchange or explicit/implicit indication in speed frame exchange if possible).
If TXOP holder will terminate TXOP with CF-End after speed frame exchange is done, then the above method can be used.
If TXOP holder will not terminate TXOP with CF-End after speed frame exchange is done, then TXOP responder shall set ACK Indication to No Response and Duration to 0 for the response frame ACK.

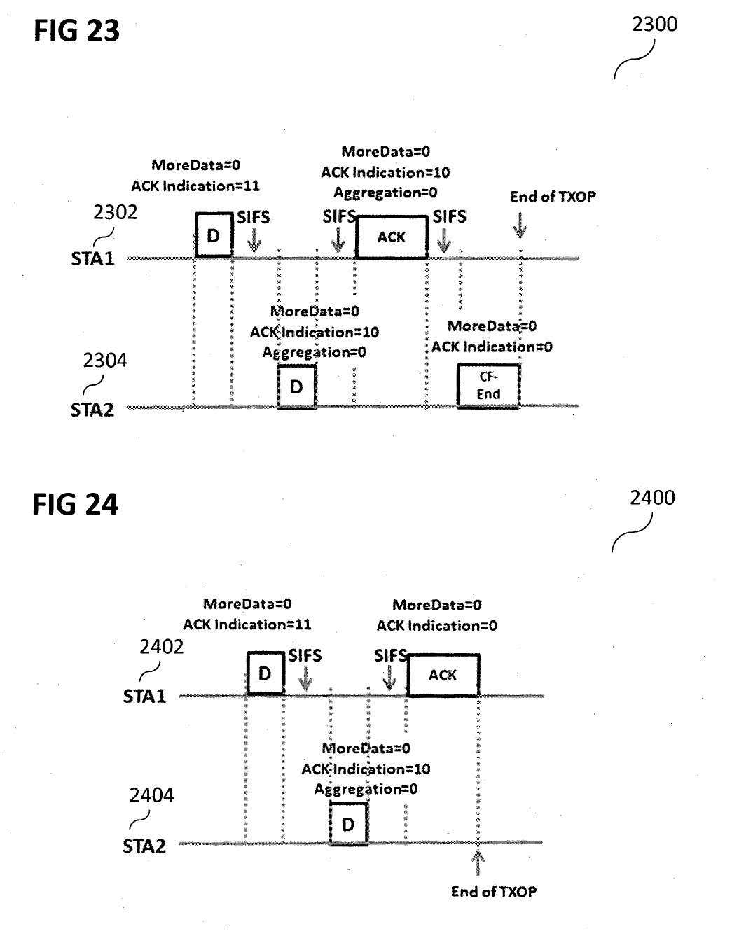

FIG. 23 shows an illustration 2300 of an example of EDCA TXOP Truncation for SF Using ACK and CF-End. Processing of a first station 2302 (STA1) and processing of a second station 2304 (STA2) are shown. FIG. 23 shows one example of EDCA TXOP truncation for speed frame exchange using ACK. When STA1 and STA2 indicate there are no more data for transmission by setting More Data field to 0. When STA1 uses ACK (in which ACK Indication subfield is set to 2 and Aggregation subfield is set to 0) as the response for the last data frame from STA2, it indicates there will be CF-End frame immediately follows ACK and may set Duration field of ACK to 0 or a value for NAV setting to protect the following frame i.e. CF-End. Thus, when STA2 receives the ACK from STA1, it responds with CF-End to terminate TXOP. If STA1 is an AP STA, it can simply terminate the TXOP using ACK, in which Duration is set 0 and ACK Indication subfield is set to 0, indicating there will no response. This is illustrated in the example shown in FIG. 24.

FIG. 24 shows an illustration 2400 of an example of EDCA TXOP Truncation for SF Using ACK. Processing of a first station 2402 (STA1) and processing of a second station 2404 (STA2) are shown.

In the following, association validation will be described.

An 802.11 AP may reset during its operation due to various reasons such as power outage, system malfunctioning etc. When an AP is reset, the associations between AP and stations associated with it become invalid. For the current IEEE 802.11-2012 standard, a station can validate the association with AP by comparing the timestamp within a beacon with the Timing Synchronization Function (TSF) counter maintained at the station. In a real implementation, if the difference between the TSF counter and the timestamp in the beacon is larger than a certain threshold, the station may consider the AP has been reset and the station may redo the authentication and association with the AP. However, in case that the difference between the timestamp in the beacon and the TSF counter within the station is not that significant, or the station does not listen to a beacon at all, the station may not be able to detect a reset of AP. In such cases, the station may still consider its association with AP valid and send data/control packets to the AP. The AP, however, can detect the MAC address provided in the station's data packet and determine that the packet is from unassociated, stations. In such situations, AP sends a De-authentication Request to the station and the station may redo authentication and association with the AP.

However, for 802.11ah networks, to improve the media efficiency, many frames have been shortened. For example, for a data frame, the station's 6-byte full MAC address can be replaced by a shorter AID. In ACK frames, the 6-byte receiver address (RA) is replaced by a shorter (between 1 to 3 bytes) ACK ID. In PS-Poll frames, 1-byte partial BSSID and 1-byte partial AID are used to replace the original 6-byte Transmitter address (TA) or RA and AID. With the short frames, the transmission time of frames can be shortened significantly, especially for the management frames.

Using the short format with partial (shorter) MAC address/AID, an AP or station may not be able to detect the state of losing association. Some low power stations, named as non-TIM stations (stations do not have traffic indication bits in the TIM bitmap), do not listen to the beacon. They may send a short PS-Poll to an AP after waking up and query whether there is downlink data pending at the AP. In such a network, if AP is reset and only short frames are exchanged among the AP and stations, both AP and station may not be aware that the association between the stations and AP are already in valid. For example, suppose Non-TIM stations STA1, STA2, . . . , STAn are associated with an AP. The AP assigned STA, with AID i (i=1 . . . n). After AP is reset, STAi is wake up and sends a PS-Poll to the AP with its AID i. Since AP is reset and no stations has been assigned with AID 1. AP sends a De-authentication message to STAi. Then STAi redoes the association with AP and is re-assigned a AID, say AID 1. After some time, the STA1 originally assigned with AID1 wakes up, it may send a data frame with a short frame header, or a short (e.g non-data packet or NDP PS-Poll with partial BSSID or PBSSID and partial AID 1. Since the AID 1 is a valid AID (now assigned to STAi), the AP may consider it is a packet from STAi and reply with a short ACK. STA1 receiving the short ACK may go to sleep if there is no data in AP's buffer (indicated in the short ACK). This example reveals that with short frames, it may happen that some associations of an AP after a reset are invalid but both AP and stations cannot detect that the associations are invalid. This may cause data delivery failure and affect the network performance.

Short frame may be a good design that may improve the protocol efficiency. However, the issue revealed previously has to be addressed when using short frames. One solution provided is that either AP or stations shall not always use short frames when exchanging information. To validate the association between an AP and an STA, with certain system configuration, frames with stations' full 6-byte MAC address must be exchanged within a given period. In the IEEE standard, a full MAC address (6 byte or 48 bits in length) are unique globally for each device.

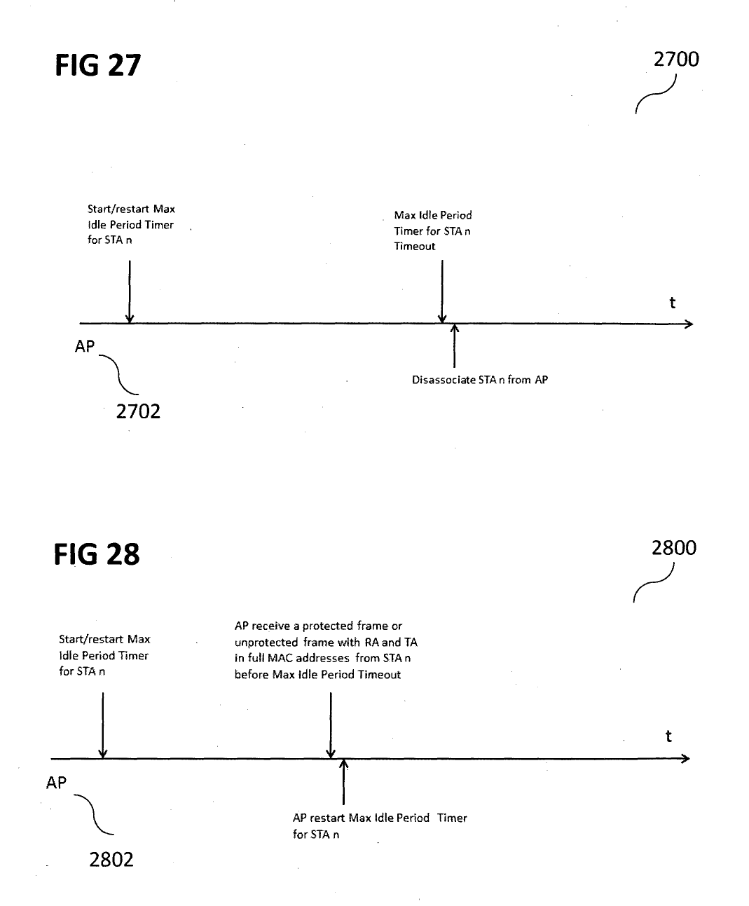

Currently, the IEEE 802.11 specification requires that a station must exchange at least one frame with its AP for a maximum idle period. Otherwise, the association is removed from the AP side. FIG. 27 shows an example. AP 2702 may start a timer for STA n with timeout value set to Max Idle Period. When the timer is timeout, this indicates that no frame has been exchanged between AP and STA n within a period equivalent to the Max Idle Period. In such situation, AP has to disassociate the STA n from its set of associated STA.

The frame exchanged between AP and STA can be either a protected frame or an unprotected frame. When a protected frame is used, protected frames here referring to frame encrypted with security keys negotiated between AP and a STA, no matter the frame is with a short MAC header or with a full MAC header, since the frame is encrypted, therefore, as well as the protected frame can be decoded correctly, that indicates the association corresponding to the transmitting station is valid. Hence, it is safe for the AP to reset the time for Max Idle Period for the STA. Therefore, when protected frame is used, it does not matter whether the frame is normal or short frame. However, when unprotected frame is used, the address information contained in the short frame may not be enough for AP to validate the association as stated in the previous example.

Since the information contained in the frame with short frame header may not be good enough for association validation, AP may use methods described in the following to validate its associations.

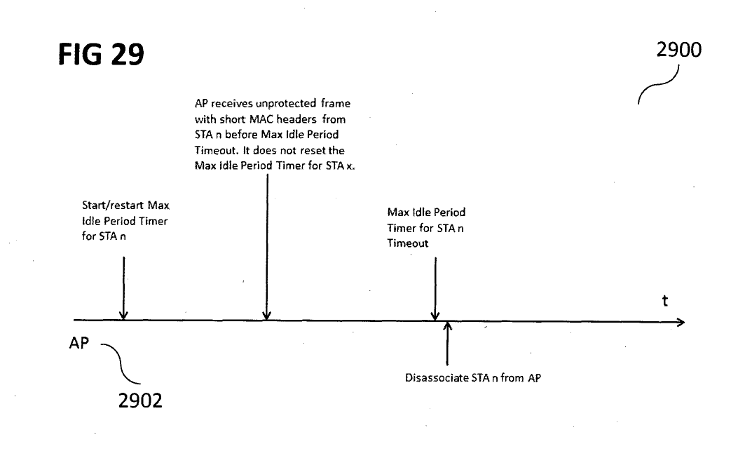

In the following, a first method (which may be referred to as “Method 1”) will be described. For a predefined period, i.e. Maximum Idle Period, station sends at least one frame with full Station address and full AP's MAC address, i.e. MAC addresses with 48 bits long. For example, a full PS-Poll as defined in the IEEE 802.11-2012 contains a full 6-byte MAC address of the station and a full 6-bye MAC address of the AP. The AP may validate the association with the full MAC address provided in the full PS-Poll. If the association becomes invalid, AP may disassociate the station. FIG. 28 shows an example. When AP 2802 receives a protected from or unprotected frame from STA n, since AP can either validate the association via decryption when protected frame is used or validate the association via full TA and RA MAC address (6 bytes in length) in frame when the frame is unprotected. In such situation, the AP restarts the timer for STA n and set the timeout value to Max Idle Period. On the other hand, if unprotected frame is used, AP shall not count on short frames for association validation. Short frame without protection shall not cause the Max Idle Period at AP side being reset. FIG. 29 shows an example. In this example, AP 2902 starts a timer for STA n by set the timeout value to Max Idle Period and before timer is timeout, AP receives an unprotected frame from STA n, which is a short MAC frame. Because it is a short frame, AP does not reset the timer previously set for association validation. If no other valid frame, either protected frame or frame with TA and RA in full MAC addresses is received before the timer timeout, AP may disassociate STA n from its association sets.

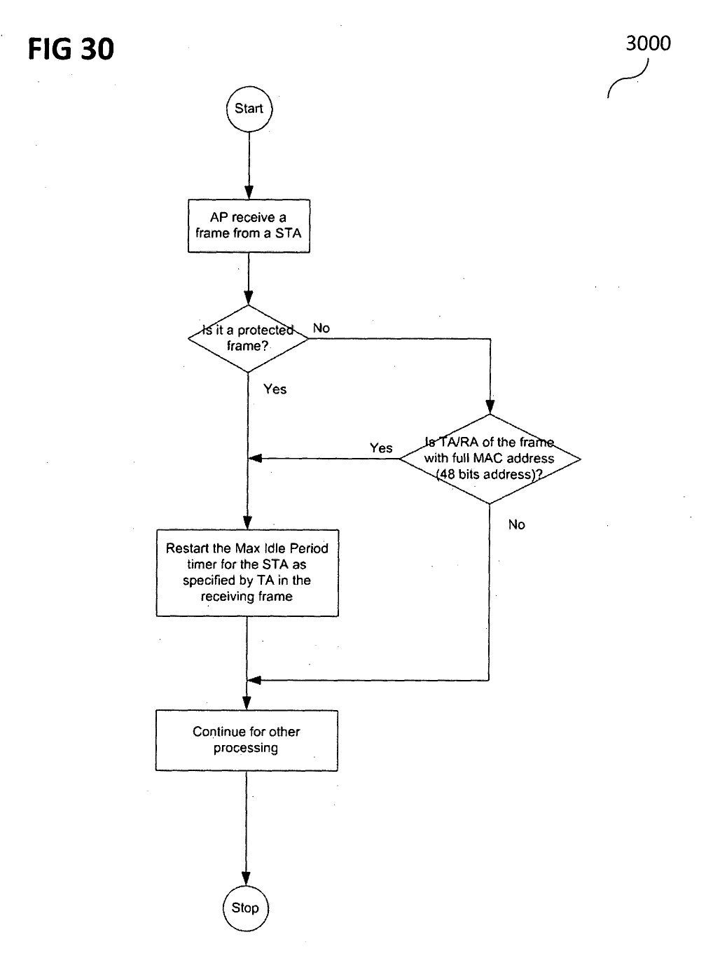

FIG. 30 shows an example procedure for AP to decide whether the timer for Max Idle Period shall be restart or not after receiving a frame from an associated STA. When AP receives frame from a STA, it first check whether it is a protected frame. If it is a protected frame and AP can decrypt the frame correctly, then it resets the timer set for association validation by setting timeout value to Max Idle Period. Else, if the frame is an unprotected frame, it further check the format for MAC headers to know whether the TA and RA addresses are in full MAC addresses or in short format, for example using partial MAC address or partial AID or AID. If both TA and RA are 48 bit full MAC addresses, then AP may reset the timer for association validation of the STA as identified by the TA address of the received frame to its maximum value, Max Idle Period. Else, AP shall not reset the timer set for association validation specified by the TA addresses of the received frame. In an case, if AP cannot find an association that matches the TA in receiving frame, it may send out deauthentication frame to disassociate the STA.

In the following, a second method (which may be referred to as “Method 2”) will be described. AP and stations maintain a reset indication at each side. This indication is changed by the AP when it is reset. When AP receives a PS-Poll from station, it may reply with a response frame that contains a reset indication. After receiving the reset indication from AP, station compares the reset indication with the one it has. If the two is different, station may redo the authentication/association with AP again.

According to various embodiments, a Short Frame Design and associated Protocol or procedures (for example NDP ACK frames designs, NDP ACK for Speed frame exchange) may be provided.

According to various embodiments, TXOP truncation/termination, flow control, NAV setting and RID update, speed frame exchange, and/or TXOP sharing for two-hop relaying may be provided, for example using a short frame design.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A communication method comprising:
at least one of sending a data unit or receiving a data unit;
wherein the data unit is a null-data packet (NDP) and comprises at least a physical layer (PHY) header;
wherein the PHY header comprises a plurality of fields; and
wherein the plurality of fields comprise at least a sub-type field with at least 3 bits indicating a NDP sub-type of the data unit.

2. The communication method of claim 1
wherein a NDP sub-type refers to one of the following: NDP CTS, NDP PS-Poll, 1st type of NDP ACK, 2nd type of NDP ACK, NDP Block ACK, NDP beamforming report poll, NDP paging, and NDP probe request.

3. The communication method of claim 1,
wherein the data unit is either 1^{st} type NDP ACK or 2^{nd} type NDP ACK and the PHY header also comprises at least one of the following fields:
ACK Identifier;
More Data;
Duration Indication;
Duration;
Relayed frame; or
Flow Control.

4. The communication method of claim 1,
wherein the data unit is a NDP ACK and the PHY header also comprises all the following fields:
ACK Identifier; More Data; Duration Indication; and Duration.

5. The communication method of claim 1,
wherein the data unit is a NDP ACK and the PHY header also comprises all the following fields:
ACK Identifier; More Data; Duration Indication; Duration; and Relayed frame.

6. The communication method of claim 3,
wherein the PHY header comprises at least an ACK identifier that is determined based on at least one of the following information:
a receiver address and/or a transmitter address;
a frame check sequence or cyclic redundancy check of the frame that elicited the null data packet acknowledgement; or
the bits of the PHY header of the received null data packet type PS-Poll frame that elicited the null data packet acknowledgement.

7. The communication method of claim 3, wherein at least one of the receiver address or the transmitter address is either a full MAC address, a partial BSSID, or a partial AID.

8. The communication method of claim 3,
wherein the PHY header comprises a field comprising duration indication information.

9. The communication method of claim 8,
wherein the PHY header comprises a field comprising duration information to indicate an inactivity period, when duration indication is a value of 0 or 1.

10. The communication method of claim 9,
wherein the inactivity period indicates the duration that there will be no transmission of the data units for the intended receiver.

11. The communication method of claim 8,
wherein the PHY header comprises a field comprising duration information to indicate a duration for NAV setting, when duration indication is a value different from the one assigned to indicate an inactivity period.

12. The communication method of claim 8,
wherein the PHY header comprises at least a field comprising the information to indicate the data unit is not a response frame for normal data unit or a null data packet type of PS-Poll.

13. The communication method of claim 11,
wherein the duration of the data unit is set to protect at least the transmission of the response data unit, indicating that the data unit is followed by at least one long response data unit.

14. The communication method of claim 3,
wherein the PHY header comprises at least one field comprising control information for flow control.

15. The communication method of claim 14,
wherein at least one field comprises the duration of no transmission of data units for flow control.

16. The communication method of claim 15,
wherein the intended receiver stops the transmission of data units to the transmitter of the data unit for a duration indicated in one field of the PHY header of the data unit.

17. The communication method of claim 1,
wherein the data is a null data packet CTS and the PHY header comprises an indication to indicate whether the data is from the access point AP.

18. The communication method of claim 1,
wherein the PHY header comprises an indication of a duration for a network allocation vector.

19. The communication method of claim 18,
wherein a nonzero valid duration of the data unit is set to protect at least the transmission of the response data unit, indicating the duration of at least one response data unit.

20. The communication method of claim 11,
wherein the response data unit is at least one of a null data packet ACK or a null data packet format of short response frame to null data type PS-Poll and its Duration field for NAV setting protects the following transmission in one TXOP.
